(19) United States
(12) Patent Application Publication
(10) Pub. No.: US 2026/0305169 A1
(43) Pub. Date: Oct. 1, 2026

(54) COMPOSITION FOR ORGANIC ELECTROLUMINESCENT DEVICE, ORGANIC ELECTROLUMINESCENT DEVICE INCLUDING THE SAME, AND BORON COMPOUND

(71) Applicant: Samsung Electronics Co., Ltd., Suwon-si (KR)

(72) Inventors: Katsunori SHIBATA, Yokohama-city (JP); Eigo MIYAZAKI, Yokohama-city (JP); Atsushi IMAMURA, Yokohama-city (JP)

(21) Appl. No.: 19/563,446

(22) Filed: Mar. 11, 2026

(30) Foreign Application Priority Data
Mar. 18, 2025 (JP) 2025-043609
Dec. 22, 2025 (KR) 10-2025-0206632

(51) Int. Cl. H10K 85/60; C07F 5/02; C09K 11/06; H10K 50/12; H10K 85/30

(52) U.S. Cl. CPC H10K 85/658; C07F 5/027; C09K 11/06; H10K 85/346; C09K 2211/1007; C09K 2211/1014; C09K 2211/1018; C09K 2211/1022; C09K 2211/1029; C09K 2211/1044; C09K 2211/185; H10K 50/12

(57) ABSTRACT

Provided are a composition for an organic electroluminescent device, the composition including a boron compound represented by Formula 1 and a phosphorescent material, an organic electroluminescent device including the composition, and a boron compound represented by Formula 1:

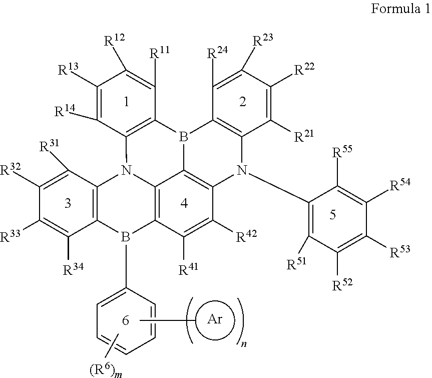

wherein, in Formula 1, R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, R⁶, Ar, m, and n are each as defined in the specification.

### CROSS-REFERENCE TO RELATED APPLICATIONS

This application is based on and claims priority to Korean Patent Application No. 10-2025-0206632, filed on Dec. 22, 2025, in the Korean Intellectual Property Office, and to Japanese Patent Application No. 2025-043609, filed on Mar. 18, 2025, in the Japanese Patent Office, and all the benefits accruing therefrom under 35 U.S.C. § 119, the contents of which are incorporated by reference herein in their entireties.

### BACKGROUND

### 1. Field

The disclosure relates to a composition for an organic electroluminescent device, an organic electroluminescent device including the same, and a boron compound.

### 2. Description of the Related Art

Organic electroluminescent devices (OLEDs) are self-emissive devices that, as compared with devices of the related art, have wide viewing angles, high contrast ratios, short response times, and excellent characteristics in terms of luminance, driving voltage, and response speed. In addition, OLEDs can produce full-color images.

In an example, an organic electroluminescent device may include an anode, a cathode, and an organic layer arranged between the anode and the cathode and including an emission layer. A hole transport region may be arranged between the anode and the emission layer, and an electron transport region may be arranged between the emission layer and the cathode. Holes provided from the anode may move toward the emission layer through the hole transport region, and electrons provided from the cathode may move toward the emission layer through the electron transport region. The holes and electrons may recombine in the emission layer to produce excitons. The excitons may transition from an excited state to a ground state, thereby generating light.

Organic electroluminescent devices may be employed as displays for smartphones or the like. In this regard, attempts have been made to improve color purity by using a resonance (micro-cavity) effect based on a top emission scheme. However, in such a scheme, while color purity is improved, luminescence efficiency is reduced.

Currently, fluorescent materials and phosphorescent materials are mainly used as luminescent materials for organic electroluminescent devices. Luminescent materials of three colors, red, green, and blue, are used in organic electroluminescent devices. Among these luminescent materials, a blue luminescent material requires further improvement in terms of luminescence efficiency, device lifespan, and color purity.

### SUMMARY

Accordingly, to improve the luminescence efficiency of top emission-type blue organic electroluminescent devices that are currently employed, development of a luminescent dopant material that imparts organic electroluminescent characteristics with a narrow full width at half maximum (FWHM) and high efficiency is desirable.

Provided is a composition for an organic electroluminescent device, wherein the composition is capable of improving the luminescence efficiency and device lifespan of an organic electroluminescent device.

Additional aspects will be set forth in part in the detailed description that follows and, in part, will be apparent from the detailed description, or may be learned by practice of the presented exemplary embodiments of the disclosure.

According to an aspect, a composition for an organic electroluminescent device includes a boron compound represented by Formula 1 and a phosphorescent material:

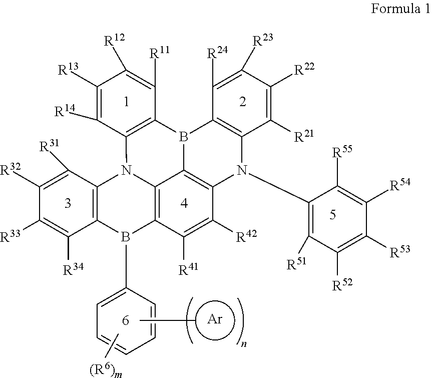

wherein, in Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino a substituted group, or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally includes a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.

According to another aspect, provided is a boron compound represented by Formula 1:

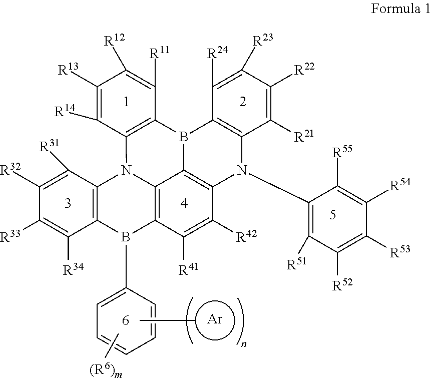

wherein, in Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally includes a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.

According to another aspect, an organic electroluminescent device includes a first electrode, a second electrode, an organic layer arranged between the first electrode and the second electrode, wherein the organic layer includes an emission layer, and wherein the organic layer further includes a composition, the composition including the boron compound represented by Formula 1 and a phosphorescent material.

According to another aspect, an electronic apparatus includes the organic electroluminescent device.

### BRIEF DESCRIPTION OF THE DRAWINGS

The above and other aspects, features, and advantages of certain exemplary embodiments will be more apparent from the following detailed description taken in conjunction with the accompanying drawings, in which:

FIG. 1 is a schematic cross-sectional view of an organic electroluminescent device according to one or more embodiments;

FIG. 2 is a schematic cross-sectional view of an organic electroluminescent device according to one or more embodiments; and

FIG. 3 is a schematic cross-sectional view of an organic electroluminescent device according to one or more embodiments.

### DETAILED DESCRIPTION

Reference will now be made in further detail to exemplary embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

The terminology used herein is for the purpose of describing one or more exemplary embodiments only and is not intended to be limiting. As used herein, the singular forms “a,” “an,” and “the” are intended to include the plural forms as well, unless the context clearly indicates otherwise. The term “or” means “and/or.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present embodiments.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

It will be understood that when an element is referred to as being “on” another element, it can be directly in contact with the other element or intervening elements may be present therebetween. In contrast, when an element is referred to as being “directly on” another element, there are no intervening elements present.

Unless otherwise defined, all terms (including technical and scientific terms) used herein have the same meaning as commonly understood by one of ordinary skill in the art to which this general inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise specified, measurements of operation and physical properties are performed at room temperature (about 20° C. to about 25° C.) and at relative humidity (RH) of about 40% RH to about 50% RH.

As used herein, the expression “X to Y” indicating a range includes the numerical values X and Y as a lower limit and an upper limit, respectively, and means “X or more and Y or less.”

As used herein, the expression “A and/or B” includes each of A and B and a combination thereof.

As used herein, the expression “X and Y may each independently be” means that X and Y may be identical to or different from each other.

As used herein, an organic electroluminescent device may also be referred to as an “organic EL device,” and a composition for an organic electroluminescent device may also be referred to as a “composition for an organic EL device” or simply as just “the composition.”

As used herein, a boron compound having a structure represented by Formula 1 may also be referred to as the “boron compound.”

As used herein, the term “group derived from a ring” refers to a group obtained by removing a hydrogen atom directly bonded to a ring-forming atom in the ring structure. In this regard, the term “ring-forming atom” refers to an atom that directly forms the ring structure. For example, in the case of a benzene ring, the ring-forming atoms are carbon atoms, and hydrogen atoms are not included in the ring-forming atoms.

As used herein, the term “number of ring-forming atoms” refers to the number of atoms constituting the ring itself of a compound (for example, a monocyclic compound, a condensed cyclic compound, a cross-linked compound, a carbocyclic compound, and a heterocyclic compound) having a structure (for example, a monocyclic ring, a condensed ring, and a ring assembly) in which atoms are bonded together in a ring-like manner. The number of ring-forming atoms excludes the number of atoms that do not constitute the ring (for example, a hydrogen atom that terminates a bond of atoms constituting the ring), and the number of atoms included in a substituent when the ring is substituted with the substituent. Unless otherwise specified, the same definition of the number of ring-forming atoms applies to descriptions provided below.

For example, a benzene ring has 6 ring-forming atoms, a naphthalene ring has 10 ring-forming atoms, a pyridine ring has 6 ring-forming atoms, and a furan ring has 5 ring-forming atoms.

When a benzene ring is substituted with, for example, an alkyl group as a substituent, the number of carbon atoms in the alkyl group is not included in the number of ring-forming atoms in the benzene ring. Accordingly, a benzene ring substituted with an alkyl group has 6 ring-forming atoms. In addition, when a naphthalene ring is substituted with, for example, an alkyl group as a substituent, the number of atoms in the alkyl group is not included in the number of ring-forming atoms in the naphthalene ring. Accordingly, a naphthalene ring substituted with an alkyl group has 10 ring-forming atoms. For example, the number of hydrogen atoms bonded to a pyridine ring or the number of atoms constituting a substituent is not included in the number of ring-forming atoms in the pyridine ring. Accordingly, a pyridine ring to which a hydrogen atom or a substituent is bonded has 6 ring-forming atoms.

Examples of an “aromatic hydrocarbon ring” having 6 to 30 ring-forming atoms are not particularly limited, but may include a benzene ring, a pentalene ring, an indene ring, a naphthalene ring, an anthracene ring, an azulene ring, a heptalene ring, an acenaphthalene ring, a phenalene ring, a fluorene ring, a phenanthrene ring, a phenyl ring, a biphenyl ring, a triphenylene ring, a pyrene ring, a chrysene ring, a picene ring, a perylene ring, a pentaphene ring, a pentacene ring, a tetraphene ring, a hexacene ring, a rubicene ring, a trinaphthylene ring, a heptaphene ring, a pyranthrene ring, or the like.

A heteroaromatic ring has one or more heteroatoms (for example, nitrogen atoms (N), oxygen atoms (O), phosphorus atoms (P), sulfur atoms(S), silicon atoms (Si), selenium atoms (Se), or germanium atoms (Ge)) as ring-forming atoms, wherein the remaining ring-forming atoms are carbon atoms (C). Examples of a heteroaromatic ring having 5 to 30 ring-forming atoms are not particularly limited, but may include a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzo ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an indolocarbazole ring, an imidazole ring, an benzimidazole ring, a pyrazole ring, an indazole ring, an oxazole ring, an isoxazole ring, a benzoxazole ring, a benzoisoxazole ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazophenanthridine ring, a benzimidazophenanthridine ring, an azadibenzofuran ring, an azacarbazole ring, an azadibenzothiophene ring, a diazadibenzofuran ring, a diazadibenzothiophene ring, a diazacarbazole ring, a xanthone ring, a thioxane ring, or the like.

As used herein, an “aryl group” is not particularly limited, but may be, for example, a monovalent group derived from one or more aromatic hydrocarbon rings. In addition, the hydrocarbon ring constituting the aryl group may be a condensed ring. When the aryl group includes two or more aromatic hydrocarbon rings, the two or more aromatic hydrocarbon rings may be bonded together through a single bond (in a form of a polycyclic aromatic hydrocarbon ring). The number of ring-forming atoms in the aryl group is not particularly limited, but may be 6 to 30. In addition, the number of ring-forming atoms in the aryl group may be 6 to 20, or 6 to 18. Examples of the aryl group are not particularly limited, but may include a phenyl group, a naphthyl group, a phenanthryl group, a biphenylenyl group, a triphenylene group, an anthryl group, a pyrenyl group, a fluorenyl group, an azulenyl group, an acenaphthyl group, a fluoranthenyl group, a naphthacenyl group, a perylenyl group, a pentacenyl group, a quaterphenyl group, a chrysenyl group, or the like. In one or more embodiments, the aryl group may be a phenyl group, a naphthyl group, a biphenylenyl group, a triphenylene group, a fluorenyl group, or the like. For example, the aryl group may be a phenyl group, a biphenylenyl group, a fluorenyl group, or the like. For example, the aryl group may be a phenyl group, a fluorenyl group, or the like. For example, the aryl group may be a phenyl group or the like.

As used herein, a “heteroaryl group” is not particularly limited, but may be, for example, a monovalent group derived from a ring including one or more heteroaromatic rings having one or more heteroatoms (e.g., nitrogen atoms (N), oxygen atoms (O), phosphorus atoms (P), sulfur atoms(S), silicon atoms (Si), selenium atoms (Se), or germanium atoms (Ge)) as ring-forming atoms, wherein the remaining ring-forming atoms are carbon atoms (C). When the heteroaryl group includes two or more heteroatoms, the heteroatoms may identical to or different from each other. In addition, the ring constituting the heteroaryl group may be a condensed ring. In addition, when the heteroaryl group includes two or more heteroaromatic rings, the two or more heteroaromatic rings may be bonded together via a single bond. As such, the heteroaryl group may be a monocyclic heteroaryl group or a polycyclic heteroaryl group. The number of ring-forming atoms in the heteroaryl group is not particularly limited, but may be 5 to 30. In addition, the number of ring-forming atoms in the heteroaryl group may be 5 to 20, or 5 to 18. Examples of the heteroaryl group are not particularly limited, but may include a thienyl group, a furanyl group, a pyrrolyl group, an imidazolyl group, a thiazolyl group, an oxazolyl group, an oxadiazolyl group, a triazolyl group, a pyridyl group, a bipyridyl group, a pyrimidyl group, a triazinyl group, a triazolyl group, an acridinyl group, a pyridazinyl group, a pyridinyl group, a quinolinyl group, a quinazolinyl group, a quinoxalinyl group, a phenoxazinyl group, a phthalazinyl group, a pyridopyrimidinyl group, a pyridopyrazinyl group, a pyrazinopyradinyl group, an isoquinolinyl group, an indolyl group, a carbazolyl group, an N-arylcarbazolyl group, an N-heteroarylcarbazolyl group, an N-alkylcarbazolyl group, a benzoxazolyl group, a benzimidazolyl group, a benzothiazolyl group, a benzocarbazolyl group, a benzothiophenyl group, a dibenzothiophenyl group, a thienothienyl group, a benzofuranyl group, a phenanthrolinyl group, a thiazolyl group, an isoxazolyl group, an oxadiazolyl group, a thiadiazolyl group, a phenothiazinyl group, a dibenzosilolyl group, a dibenzofuranyl group, or the like. In one or more embodiments, the heteroaryl group may be a monovalent group derived from a ring including one or more heteroaromatic rings having one or more nitrogen atoms as ring-forming atoms, wherein the remaining ring-forming atoms are carbon atoms (C). In one or more embodiments, the heteroaryl group may be a monovalent group derived from a ring including one or more heteroaromatic rings having one nitrogen atom as a ring-forming atom, wherein the remaining ring-forming atoms are carbon atoms (C). For example, the heteroaryl group may be a carbazolyl group or the like.

As used herein, examples of “halogen atoms” may include a fluorine atom (F), a chlorine atom (Cl), a bromine atom (Br), or an iodine atom (I).

As used herein, an “alkyl group” may be linear, branched, or cyclic. The number of carbon atoms in the alkyl group is not particularly limited, but may be, for example, 1 to 30, or 1 to 20. In addition, the number of carbon atoms in the alkyl group may be 1 to 10, 1 to 6, or 1 to 4. The number of carbon atoms in the branched alkyl group is not particularly limited, but may be, for example, 3 to 30, 3 to 20, 3 to 10, 3 to 6, or 3 to 4. In an embodiment, the number of carbon atoms in the branched alkyl group may be 4. Examples of the alkyl group are not particularly limited, but include a methyl group, an ethyl group, an n-propyl group, an isopropyl group, an n-butyl group, a sec-butyl group, a tert-butyl group, an isobutyl group, a 2-ethylbutyl group, a 3,3-dimethylbutyl group, an n-pentyl group, an isopentyl group, a neopentyl group, a tert-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-tert-butylcyclohexyl group, an n-heptyl group, a 1-methylheptyl group, a 2,2-dimethylheptyl group, a 2-ethylheptyl group, a 2-butylheptyl group, an n-octyl group, a tert-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, or the like. In one or more embodiments, the alkyl group may be an isopropyl group, a sec-butyl group, a tert-butyl group, an isobutyl group, a 2-ethylbutyl group, a 3,3-dimethylbutyl group, an isopentyl group, a neopentyl group, a tert-pentyl group, a 1-methylpentyl group, a 3-methylpentyl group, a 4-methyl-2-pentyl group, or the like. For example, the alkyl group may be a sec-butyl group, a tert-butyl group, an isobutyl group, or the like. For example, the alkyl group may be a tert-butyl group or the like.

As used herein, an “alkenyl group” has a structure including one or more carbon-carbon double bonds in the middle or at the terminus of the alkyl group, and non-limiting examples thereof include an ethenyl group, a propenyl group, a butenyl group, or the like.

As used herein, an “alkynyl group” has a structure including one or more carbon-carbon triple bonds in the middle or at the terminus of the alkyl group, and non-limiting examples thereof include an ethynyl group, a propynyl group, or the like.

As used herein, an “alkoxy group” may be linear, branched, or cyclic. The alkyl group constituting the alkoxy group is not particularly limited, but examples thereof may be the same as those mentioned in the above description of the alkyl group as a substituent. The number of carbon atoms in the alkoxy group is not particularly limited, but may be 1 or more. In addition, the number of carbon atoms in the alkoxy group may be 20 or less, 10 or less, or 4 or less. Examples of the alkoxy group are not particularly limited, but may include a methoxy group, an ethoxy group, an n-propyloxy group, an isopropyloxy group, an n-butyloxy group, a sec-butyloxy group, a tert-butyloxy group, an isobutyloxy group, a 2-ethylbutyloxy group, a 3,3-dimethylbutyloxy group, an n-pentyloxy group, an isopentyloxy group, a neopentyloxy group, a tert-pentyloxy group, a cyclopentyloxy group, a 1-methylpentyloxy group, a 3-methylpentyloxy group, a 2-ethylpentyloxy group, a 4-methyl-2-pentyloxy group, an n-hexyloxy group, a 1-methylhexyloxy group, a 2-ethylhexyloxy group, a 2-butylhexyloxy group, a cyclohexyloxy group, a 4-methylcyclohexyloxy group, a 4-tert-butylcyclohexyloxy group, an n-heptyloxy group, a 1-methylheptyloxy group, a 2,2-dimethylheptyloxy group, a 2-ethylheptyloxy group, a 2-butylheptyloxy group, an n-octyloxy group, a tert-octyloxy group, a 2-ethyloctyloxy group, a 2-butyloctyloxy group, a 2-hexyloctyloxy group, a 3,7-dimethyloctyloxy group, a cyclooctyloxy group, an n-nonyloxy group, an n-decyloxy group, an adamantyloxy group, or the like.

As used herein, an “aryloxy group” is not particularly limited. The number of carbon atoms in the aryloxy group is not particularly limited, but may be 6 to 30. The number of carbon atoms in the aryloxy group may be 6 to 12, or 6. Examples of the aryloxy group are not particularly limited, but may include a phenyloxy group, a biphenyloxy group, a terphenyloxy group, a naphthyloxy group, a fluorenyloxy group, an anthracenyloxy group, a quaterphenyloxy group, a quinquephenyloxy group, a triphenylenyloxy group, a pyrenyloxy group, a benzofluorenyloxy group, a chrysenyloxy group, or the like.

As used herein, a “heteroaryloxy group” is not particularly limited. The heteroaryl group constituting the heteroaryloxy group is not particularly limited, and examples thereof may be the same as those mentioned in the above description of the heteroaryl group. The number of ring-forming atoms in the heteroaryloxy group is not particularly limited, but may be 5 to 30. In addition, the number of ring-forming atoms in the heteroaryloxy group may be 5 to 14, or 5 to 13. The number of heteroatoms as ring-forming atoms in the heteroaryloxy group is not particularly limited, but may be 1 to 3. In addition, the number of heteroatoms as ring-forming atoms in the heteroaryloxy group may be 1 to 2, or 1. Examples of the heteroaryloxy group are not particularly limited, but may include a thienyloxy group, a furanyloxy group, a pyrrolyloxy group, an imidazolyloxy group, a thiazolyloxy group, an oxazolyloxy group, an oxadiazolyloxy group, a triazolyloxy group, a pyridyloxy group, a bipyridyloxy group, a pyrimidyloxy group, a triazinyloxy group, a triazolyloxy group, a acridinyloxy group, a pyridazinyloxy group, a pyridinyloxy group, a quinolinyloxy group, a quinazolinyloxy group, a quinoxalinyloxy group, a phenoxazinyloxy group, a phthalazinyloxy group, a pyridopyrimidinyloxy group, a pyridopyrazinyloxy group, a pyrazinopyrazinyloxy group, an isoquinolinyloxy group, an indolyloxy group, a carbazolyloxy group, a benzoxazolyloxy group, a benzimidazolyloxy group, a benzothiazolyloxy group, a benzocarbazolyloxy group, a benzothiophenyloxy group, a dibenzothienyloxy group, a thienothienyloxy group, a benzofuranyloxy group, a phenanthrolinyloxy group, a thiazolyloxy group, an isoxazolyloxy group, an oxadiazolyloxy group, a thiadiazolyloxy group, a phenothiazinyloxy group, a dibenzosilolyloxy group, a dibenzofuranyloxy group, a xanthonyloxy group, or the like.

As used herein, an “arylthio group” is not particularly limited. The number of carbon atoms in the arylthio group is not particularly limited, but may be 6 to 30. The number of carbon atoms in the arylthio group may be 6 to 12, or 6. Examples of the arylthio group are not particularly limited, but may include a phenylthio group, a biphenylthio group, a terphenylthio group, a naphthylthio group, a fluorenylthio group, an anthracenylthio group, a quarterphenylthio group, a quinquephenylthio group, a triphenylenylthio group, a pyrenylthio group, a benzofluorenylthio group, a chrysenylthio group, or the like.

As used herein, a “heteroarylthio group” is not particularly limited. The heteroaryl group constituting the heteroarylthio group is not particularly limited, and examples thereof may be the same as those mentioned in the above description of the heteroaryl group. The number of ring-forming atoms in the heteroarylthio group is not particularly limited, but may be 5 to 30. In addition, the number of ring-forming atoms in the heteroarylthio group may be 5 to 14, or 5 to 13. The number of heteroatoms as ring-forming atoms in the heteroarylthio group is not particularly limited, but may be 1 to 3. In addition, the number of heteroatoms as ring-forming atoms in the heteroarylthio group may be 1 to 2, or 1. Examples of the heteroarylthio group are not particularly limited, but may include a thienylthio group, a furanylthio group, a pyrrolylthio group, an imidazolylthio group, a thiazolylthio group, an oxazolylthio group, an oxadiazolylthio group, a triazolylthio group, a pyridylthio group, a bipyridylthio group, a pyrimidylthio group, a triazinylthio group, a triazolylthio group, an acridinylthio group, a pyridazinylthio group, a pyridinylthio group, a quinolinylthio group, a quinazolinylthio group, a quinoxalinylthio group, a phenoxazinylthio group, a phthalazinylthio group, a pyridopyrimidinylthio group, a pyridopyrazinylthio group, a pyrazinopyrazinylthio group, an isoquinolinylthio group, an indolylthio group, a carbazolylthio group, a benzoxazolylthio group, a benzimidazolylthio group, a benzothiazolylthio group, a benzocarbazolylthio group, a benzothiophenylthio group, a dibenzothiophenylthio group, a thienothiophenylthio group, a benzofuranylthio group, a phenanthrolinylthio group, a thiazolylthio group, an isoxazolylthio group, an oxadiazolylthio group, a thiadiazolylthio group, a phenothiazinylthio group, a dibenzosilolylthio group, a dibenzofuranylthio group, a xanthonylthio group, or the like.

As used herein, a “diarylamino group”, a “diheteroarylamino group”, and an “arylheteroarylamino group” are not particularly limited. Examples of the aryl group and the heteroaryl group that constitute the diarylamino group, the diheteroarylamino group, and the arylheteroarylamino group may be the same as those described in the above descriptions of the aryl group and the heteroaryl group, respectively. Examples of the diarylamino group are not particularly limited, but may include a diphenylamino group, a bis(4-tert-butylphenyl)amino group, a phenyl(naphthyl)amino group, a di(biphenyl)amino group, a di(p-terphenyl)amino group, or the like. Examples of the arylheteroarylamino group are not particularly limited, but may include a phenyl(2-pyridyl)amino group or the like. Examples of the diheteroarylamino group are not particularly limited, but may include a di(2-pyridyl)amino group or the like.

As used herein, a “cycloalkyl group” is not particularly limited. The number of carbon atoms in the cycloalkyl group may be 3 to 18, for example, 3 to 12, or for example, 3 to 6. Examples of the cycloalkyl group may include a cyclopropyl group, a cyclobutyl group, a cyclopentyl group, a cyclohexyl group, or the like.

As used herein, a “heterocycloalkyl group” refers to a ring group further including at least one heteroatom selected from N, O, P, Si, S, Se, and Ge as a ring-forming atom, and non-limiting examples thereof include a tetrahydrofuranyl group, a tetrahydrothiophenyl group, or the like.

As used herein, the type of a substituent is not particularly limited, but may include a deuterium atom, a halogen atom, a substituted or unsubstituted alkyl group, a substituted or unsubstituted aryl group, a substituted or unsubstituted heteroaryl group, a substituted or unsubstituted alkoxy group, a substituted or unsubstituted aryloxy group, a substituted or unsubstituted heteroaryloxy group, a substituted or unsubstituted diarylamino group, a substituted or unsubstituted diheteroarylamino group, or a substituted or unsubstituted arylheteroarylamino group. When two or more hydrogen atoms are substituted, the types of substituents may be identical to or different from each other.

As used herein, a “carbocyclic group” refers to a monocyclic or polycyclic group that does not include a heteroatom. For example, the carbocyclic group may be a cyclopentane group, a cyclohexane group, a cyclohexene group, a benzene group, a naphthalene group, an anthracene group, a phenanthrene group, a triphenylene group, a pyrene group, a chrysene group, a 1,2,3,4-tetrahydronaphthalene group, a cyclopentadiene group, an indene group, a fluorene group, a 5,6,7,8-tetrahydroisoquinoline group, a 5,6,7,8-tetrahydroquinoline group, an adamantane group, a norbornane group, a norbornene group, or the like.

As used herein, a “heterocyclic group” refers to a monocyclic or polycyclic group including at least one heteroatom as a ring-forming member. For example, the heterocyclic group may be a thiophene group, a furan group, a pyrrole group, a cyclopentadiene group, a silole group, a borole group, a phosphole group, a selenophene group, a germole group, a benzothiophene group, a benzofuran group, an indole group, an indene group, a benzosilole group, a benzoborole group, a benzophosphole group, a benzoselenophene group, a benzogermole group, a dibenzothiophene group, a dibenzofuran group, a carbazole group, a dibenzosilole group, a dibenzoborole group, a dibenzophosphole group, a dibenzoselenophene group, a dibenzogermole group, a dibenzothiophene 5-oxide group, a 9H-fluoren-9-one group, a dibenzothiophene 5,5-dioxide group, an azabenzothiophene group, an azabenzofuran group, an azaindole group, an azaindene group, an azabenzosilole group, an azabenzoborole group, an azabenzophosphole group, an azabenzoselenophene group, an azabenzogermole group, an azadibenzothiophene group, an azadibenzofuran group, an azacarbazole group, an azafluorene group, an azadibenzosilole group, an azadibenzoborole group, an azadibenzophosphole group, an azadibenzoselenophene group, an azadibenzogermole group, an azadibenzothiophene 5-oxide group, an aza-9H-fluoren-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, or the like.

As used herein, the term “linker” refers to a portion that is bonded to one or more other portions within the same molecule. The linker may be a portion that links two or more different rings to each other, or may be a portion that links two or more portions on the same ring to each other. For example, the linker may be a single bond or a linking group.

As used herein, a “linking group” may be a group including a substituted or unsubstituted aromatic hydrocarbon ring. When the linking group includes two or more aromatic hydrocarbon rings, the two or more aromatic hydrocarbon rings may be bonded together via a single bond (in a form of a polycyclic aromatic hydrocarbon ring).

As used herein, the linking group may be a group including a substituted or unsubstituted aromatic hydrocarbon ring, or may be a divalent group including a substituted or unsubstituted aromatic hydrocarbon ring. In an embodiment, the linking group may be a group derived from a substituted or unsubstituted aromatic hydrocarbon ring or a substituted or unsubstituted polycyclic aromatic hydrocarbon ring. For example, the linking group may be a divalent group derived from a substituted or unsubstituted aromatic hydrocarbon ring or a substituted or unsubstituted polycyclic aromatic hydrocarbon ring. For example, the linking group may be a divalent group derived from a substituted or unsubstituted aromatic hydrocarbon ring. For example, the linking group may be a divalent group derived from an aromatic hydrocarbon ring (unsubstituted aromatic hydrocarbon ring).

The aromatic hydrocarbon ring included in the linking group may be a monocyclic ring or a condensed ring. The number of ring-forming atoms in the aromatic hydrocarbon ring may be 6 to 30, or 6 to 10. Examples of the aromatic hydrocarbon ring having 6 to 30 ring-forming atoms are not particularly limited, but may include, a benzene ring, a pentalene ring, an indene ring, a naphthalene ring, an anthracene ring, an azulene ring, a heptalene ring, an acenaphthalene ring, a phenalene ring, a fluorene ring, a phenanthrene ring, a biphenyl ring, a terphenyl ring, a triphenylene ring, a pyrene ring, a chrysene ring, a picene ring, a perylene ring, a pentaphene ring, a pentacene ring, a tetraphene ring, a hexaphene ring, a hexacene ring, a rubicene ring, a trinaphthylene ring, a heptaphene ring, a pyranthrene ring, or the like.

The linking group may be a divalent group derived from a substituted or unsubstituted benzene ring, a divalent group derived from a substituted or unsubstituted fluorene ring, or a divalent group derived from a polycyclic aromatic hydrocarbon ring having a structure in which a substituted or unsubstituted benzene ring and a substituted or unsubstituted fluorene ring are bonded together. The linking group may be a divalent group derived from a substituted or unsubstituted fluorene ring, or a divalent group derived from a polycyclic aromatic hydrocarbon ring having a structure in which a substituted or unsubstituted benzene ring and a substituted or unsubstituted fluorene ring are bonded together. The linking group may be a divalent group derived from a fluorene ring (unsubstituted fluorene ring), or a divalent group derived from a polycyclic aromatic hydrocarbon ring having a structure in which a benzene ring (unsubstituted benzene ring) and a fluorene ring (unsubstituted fluorene ring) are bonded together. For example, the linking group may be a divalent group derived from a fluorene ring.

The linker linking two or more different rings together may be a single bond or a divalent group derived from a substituted or unsubstituted fluorene ring. For example, the linker may be a single bond or a divalent group derived from a fluorene ring. For example, the linker may be a single bond.

### Composition for Organic Electroluminescent Device

An aspect provides a composition for an organic electroluminescent device, the composition including a boron compound represented by Formula 1 and a phosphorescent material.

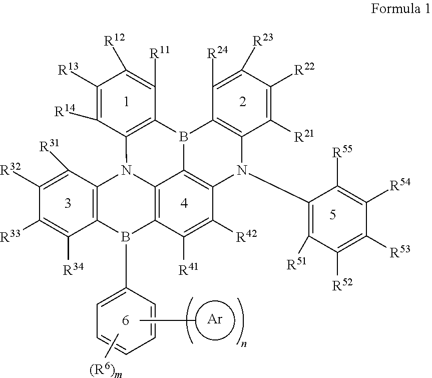

In Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally includes a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.

The composition for an organic EL device may improve the luminescence efficiency and device lifespan of an organic EL device. In addition, the organic EL device may exhibit blue luminescence.

Recently, as a method of improving the luminescence efficiency of organic EL devices while extending the lifespan thereof, an organic EL device employing an emission scheme that combines a luminescent material and a phosphor sensitizer has been proposed. In the case of an organic EL device including a host material and a luminescent material in an emission layer, excitons generated on host molecules in the emission layer transfer energy to the luminescent material, thereby emitting light. In this case, when a fluorescent material is used as the luminescent material, luminescence efficiency is at most 5%. However, it is known that when a phosphor sensitizer is added to the emission layer, luminescence efficiency increases as compared with a case in which no phosphor sensitizer is used. This is considered to be because triplet energy of the fluorescent material may also be used for light emission, and the luminescence efficiency of the organic EL device is improved to 10% or more. The emission scheme that combines a luminescent material and a phosphor sensitizer has attracted attention as a candidate emission scheme for next-generation organic EL devices. However, in such an emission scheme combining a luminescent material and a phosphor sensitizer, the device lifespan tends to be short.

In addition, a new international standard, ITU-R Recommendation BT.2020, has been announced, and accordingly, there is a demand to further improve the color purity of organic EL devices. It is known that by introducing a microcavity structure into an organic EL device using a luminescent material of the related art, the color purity of the organic EL device may be improved, and the emission spectral width of the organic EL device may be narrowed. However, when a luminescent material having a relatively broad emission spectral width is still used, light deviating from the desired wavelength is not used, and thus, the luminescence efficiency of the organic EL device is reduced. Accordingly, there is a continued demand for a luminescent material having a narrower emission spectral width.

It has been reported that compounds including boron atoms, such as Compounds K1 to K3, exhibit blue luminescence, and exhibit high luminescence efficiency in organic EL devices.

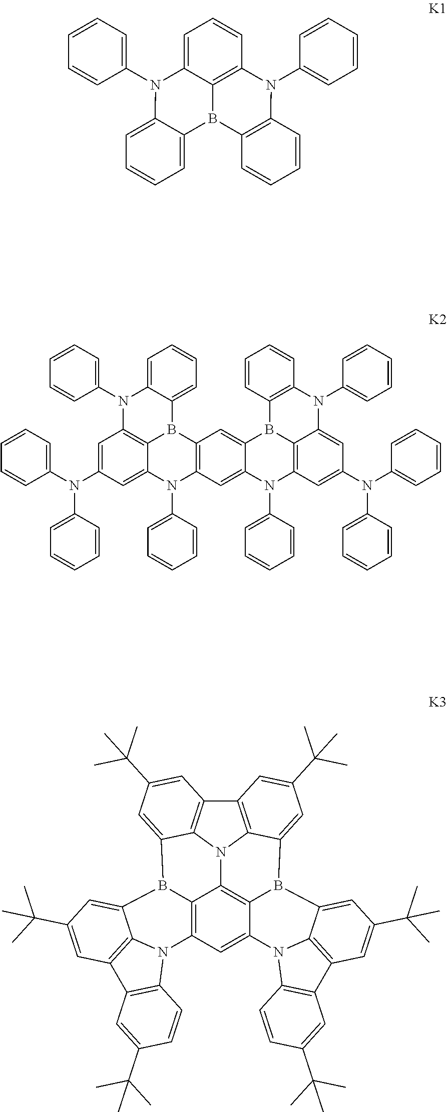 [SMILES: c1ccc(N2c3ccccc3B3c4ccccc4N(c4ccccc4)c4cccc2c43)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; CC(C)(C)c1ccc2c(c1)c1cc(C(C)(C)C)cc3c1n2-c1cc2c4c5c1B3c1cc(C(C)(C)C)cc3c6cc(C(C)(C)C)cc(c6n-5c13)B4c1cc(C(C)(C)C)cc3c4cc(C(C)(C)C)ccc4n-2c13]

However, such compounds relatively exhibit a broad emission spectral width (full width at half maximum (FWHM) of the emission peak) in a solid-film state and in organic EL devices, and thus exhibit insufficient color purity. Accordingly, organic EL devices using such compounds have low luminescence efficiency and/or short lifespan, and thus require further improvement for commercialization.

The process of energy transfer from a host molecule to a guest molecule (luminescent material) in an emission layer of an organic EL device is known as Dexter energy transfer or Forster energy transfer. In Forster energy transfer, when the host molecule is excited, the luminescent material enters an excited singlet state, emits light, and then returns to a ground singlet state. In contrast, when Dexter energy transfer occurs, the luminescent material enters an excited triplet state. However, this state does not contribute to light emission, and the luminescent material returns to the ground singlet state after thermal deactivation. Since a spin inversion is required to return from the excited triplet state to the ground singlet state, deactivation of the excited triplet state takes longer than that of the excited singlet state. Accordingly, such an unstable high-energy state is more susceptible to chemical reactions, which may lead to deterioration of device performance. Therefore, to achieve high efficiency and long lifespan of an organic EL device, it is necessary to suppress Dexter energy transfer. The likelihood of Dexter energy transfer depends on the intermolecular distance, and one method of suppressing Dexter energy transfer is to increase the intermolecular distance (proximity suppression).

The present inventors have found that, by introducing a bulky substituent into a boron compound represented by Formula 1 to suppress Dexter energy transfer, the intermolecular distance between a phosphorescent material (a phosphorescent complex or a sensitizer) and the boron compound may be increased, thereby improving luminescence efficiency.

In detail, in addition to a molecular skeleton including ring 1 to ring 5, a bulky substituent including ring 6 and at least one Ar ring is provided at a position close to the center of the molecular skeleton. As a result, in the boron compound represented by Formula 1, the overall molecular bulk may be increased, thereby suppressing proximity between the phosphorescent material and the portion of the compound into which a boron atom is introduced. Accordingly, it is considered that the composition for an organic EL device according to the disclosure may improve the luminescence efficiency and device lifespan of an organic EL device.

In addition, polycyclic compounds of the related art, which include boron and have aromaticity, exhibit a narrow FWHM of the emission peak and high color purity in a solution state, but the FWHM of the emission peak tends to increase in emission in a solid-film state and in emission from organic EL devices. However, since the boron compound represented by Formula 1 according to one or more embodiments has a bulky substituent group, intermolecular aggregation may be reduced, and a narrow FWHM of the emission peak may be maintained in emission in a solid-film state and in emission from an organic EL device.

The above mechanism is based on speculation, and does not affect the technical scope of the disclosure. In addition, other speculations made herein likewise do not affect the technical scope of the disclosure.

Hereinafter, the composition of the organic EL device composition according to the disclosure is described in further detail.

### Boron Compound Represented by Formula 1

The composition for an organic EL device according to the disclosure includes a boron compound represented by Formula 1. The composition for an organic EL device may use the boron compound alone or in combination of two or more thereof.

In Formula 1, R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker.

In one or more embodiments, in Formula 1, each R⁶ may independently be a hydrogen atom, a cyano group, a halogen atom, a deuterium atom, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 1, each R⁶ may independently be a hydrogen atom, a cyano group, a halogen atom, a deuterium atom, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 1, each R⁶ may independently be a hydrogen atom, a cyano group, a halogen atom, a deuterium atom, a heteroaryl group (unsubstituted heteroaryl group), a diarylamino group (unsubstituted diarylamino group), a diheteroarylamino group (unsubstituted diheteroarylamino group), an arylheteroarylamino group (unsubstituted arylheteroarylamino group), an alkyl group (unsubstituted alkyl group), an aryloxy group (unsubstituted aryloxy group), a heteroaryloxy group (unsubstituted heteroaryloxy group), an arylthio group (unsubstituted arylthio group), or a heteroarylthio group (unsubstituted heteroarylthio group).

In one or more embodiments, in Formula 1, each R⁶ may independently be a hydrogen atom or a substituted or unsubstituted alkyl group.

In one or more embodiments, in Formula 1, each Ar may independently be a benzene ring, a pyridine ring, a pyrazine ring, a pyridazine ring, a pyrimidine ring, a triazine ring, a furan ring, a thiophene ring, a triazine ring, a pyrrole ring, an imidazole ring, a pyrazole ring, an imidazoline ring, a triazole ring, a tetrazole ring, an oxazole ring, an isoxazole ring, a thiazole ring, or an isothiazole ring.

In one or more embodiments, in Formula 1, each Ar may independently be a substituted or unsubstituted benzene ring. For example, each Ar may independently be an unsubstituted benzene ring.

When the Ar ring is substituted, a substituent substituted on the Ar ring is not particularly limited, but may be a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group. Two or more substituents may be present on the Ar ring, and the types of the substituents may be identical to or different from each other.

When the Ar ring has a linker, the linker in the Ar ring may be a single bond or a linking group. In this regard, the linking group is not particularly limited, but may be a divalent group. For example, the linking group may not be a boron atom, a nitrogen atom, a P═O group, or a P═S group.

In Formula 1, m is 0, 1, 2, 3, or 4, n is 1, 2, 3, 4, or 5, and a sum of m and n is 5. In one or more embodiments, in Formula 1, m may be an integer from 1 to 4, n may be an integer from 1 to 4, and the sum of m and n may be 5. For example, in Formula 1, m may be 2, 3, or 4, n may be 1, 2, or 3, and the sum of m and n may be 5. For example, in Formula 1, m may be 2 or 3, n may be 2 or 3, and the sum of m and n may be 5. For example, in Formula 1, m may be 3, and n may be 2.

In one or more embodiments, in Formula 1, a combination of ring 1 and ring 2, a combination of ring 1 and ring 3, a combination of ring 2 and ring 5, a combination of ring 4 and ring 5, a combination of ring 6 and one or more Ar rings, and a combination of two or more Ar rings may each independently be bonded together via the linker, or may not be bonded together via the linker.

In one or more embodiments, in Formula 1, a combination of ring 1 and ring 3 and a combination of ring 2 and ring 5 may each independently be bonded together via the linker.

In one or more embodiments, in Formula 1, ring 5 and ring 6 may not be bonded together via the linker, and ring 5 and the Ar ring may not be bonded together via the linker.

In one or more embodiments, among combinations of two rings selected from ring 1, ring 2, ring 3, ring 4, ring 5, ring 6 and two or more Ar rings, a combination other than a combination selected from a combination of ring 1 and ring 2, a combination of ring 1 and ring 3, a combination of ring 2 and ring 5, a combination of ring 4 and ring 5, a combination of ring 6 and one or more Ar rings, and a combination of two or more Ar rings may not be bonded together via the linker.

In Formula 1, when two or more Ar rings are present, the Ar rings may be identical to or different from each other. In Formula 1, when two or more R⁶(s) are present, R⁶(s) may be identical to or different from each other.

In the composition for an organic EL device according to the disclosure, the boron compound having a structure represented by Formula 1 may be a boron compound represented by Formula 2.

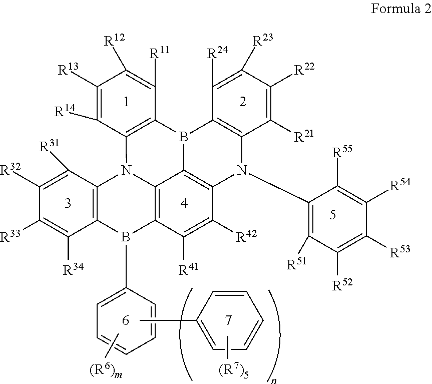

In Formula 2,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, R⁶, m, and n may each be as described in Formula 1,
each R⁷ may independently be a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
the linker may be a single bond or a linking group, and
ring 3 and ring 6 may not be bonded together via the linker, ring 3 and ring 7 may not be bonded together via the linker, ring 4 and ring 6 may not be bonded together via the linker, and ring 4 and ring 7 may not be bonded together via the linker.

In one or more embodiments, in Formula 2, a combination of ring 1 and ring 2, a combination of ring 1 and ring 3, a combination of ring 2 and ring 5, a combination of ring 4 and ring 5, a combination of ring 6 and one or more ring 7 (s), and a combination of two or more ring 7 (s) may each independently be bonded together via the linker, or may not be bonded together via the linker. In one or more embodiments, a combination of ring 1 and ring 3 and a combination of ring 2 and ring 5 may each independently be bonded together via the linker. In one or more embodiments, ring 1 and ring 3 may be bonded together via the linker, and ring 2 and ring 5 may be bonded together via the linker. In one or more embodiments, ring 5 and ring 6 may not be bonded together via the linker, and ring 5 and ring 7 may not be bonded together via the linker. Among combinations of two rings selected from ring 1, ring 2, ring 3, ring 4, ring 5, ring 6 and two or more ring 7(s), a combination other than a combination selected from a combination of ring 1 and ring 2, a combination of ring 1 and ring 3, a combination of ring 2 and ring 5, a combination of ring 4 and ring 5, a combination of ring 6 and one or more ring 7(s), and a combination of two or more ring 7(s) may not be bonded together via the linker.

In Formula 2, when two or more R⁶(s) are present, R⁶(s) may be identical to or different from each other. In Formula 2, when two or more R⁷(s) are present, R⁷(s) may be identical to or different from each other.

In one or more embodiments, in Formula 2, m may be an integer from 1 to 4, n may be an integer from 1 to 4, and the sum of m and n may be 5.

In one or more embodiments, in Formula 2, R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, R⁶, and R⁷ may each independently be a hydrogen atom, a cyano group, a halogen atom, a deuterium atom, an aryl group (unsubstituted aryl group), a heteroaryl group (unsubstituted heteroaryl group), a diarylamino group (unsubstituted diarylamino group), a diheteroarylamino group (unsubstituted diheteroarylamino group), an arylheteroarylamino group (unsubstituted arylheteroarylamino group), an alkyl group (unsubstituted alkyl group), an aryloxy group (unsubstituted aryloxy group), a heteroaryloxy group (unsubstituted heteroaryloxy group), an arylthio group (unsubstituted arylthio group), a heteroarylthio group (unsubstituted heteroarylthio group), or a linker.

In this regard, R⁶ and R⁷ may each independently be a hydrogen atom, a cyano group, a halogen atom, a deuterium atom, a heteroaryl group (unsubstituted heteroaryl group), a diarylamino group (unsubstituted diarylamino group), a diheteroarylamino group (unsubstituted diheteroarylamino group), an arylheteroarylamino group (unsubstituted arylheteroarylamino group), an alkyl group (unsubstituted alkyl group), an aryloxy group (unsubstituted aryloxy group), a heteroaryloxy group (unsubstituted heteroaryloxy group), an arylthio group (unsubstituted arylthio group), or a heteroarylthio group (unsubstituted heteroarylthio group).

In one or more embodiments, in Formula 2, each R⁶ may independently be a hydrogen atom, a cyano group, a halogen atom, a deuterium atom, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 2, each R⁶ may independently be a hydrogen atom, a cyano group, a halogen atom, a deuterium atom, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 2, each R⁶ may independently be a hydrogen atom or a substituted or unsubstituted alkyl group.

In one or more embodiments, in Formula 2, each R⁷ may independently be a hydrogen atom, a cyano group, a halogen atom, a deuterium atom, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 2, each R⁷ may independently be a hydrogen atom, a cyano group, a halogen atom, a deuterium atom, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 2, each R⁷ may independently be a hydrogen atom or a substituted or unsubstituted alkyl group. For example, each R⁷ may independently be a hydrogen atom or an alkyl group. For example, each R⁷ may independently be a hydrogen atom, a linear alkyl group, or a branched alkyl group.

In one or more embodiments, in Formula 2, each R⁷ may independently be a hydrogen atom or a branched alkyl group. For example, each R⁷ may independently be a hydrogen atom or a tert-butyl group. For example, each R⁷ may be a hydrogen atom.

In the composition for an organic EL device according to the disclosure, the boron compound having a structure represented by Formula 1 may be a boron compound represented by Formula 3.

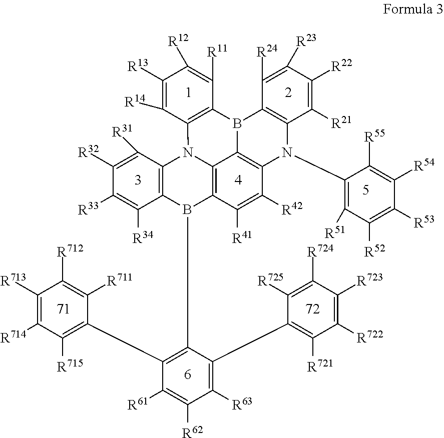

In Formula 3,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, and R⁵⁵ may each be as described in Formula 1,
R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
the linker may be a single bond or a linking group, and
ring 3 and ring 6 may not be bonded together via the linker, ring 3 and ring 71 may not be bonded together via the linker, ring 3 and ring 72 may not be bonded together via the linker, ring 4 and ring 6 may not be bonded together via the linker, ring 4 and ring 71 may not be bonded together via the linker, and ring 4 and ring 72 may not be bonded together via the linker.

In one or more embodiments, in Formula 3, a combination of ring 1 and ring 2, a combination of ring 1 and ring 3, a combination of ring 2 and ring 5, a combination of ring 4 and ring 5, a combination of ring 6 and ring 71, a combination of ring 6 and ring 72, and a combination of ring 71 and ring 72 may each independently be bonded together via the linker, or may not be bonded together via the linker.

In one or more embodiments, in Formula 3, a combination of ring 1 and ring 3 and a combination of ring 2 and ring 5 may each independently be bonded together via the linker.

In one or more embodiments, in Formula 3, ring 1 and ring 3 may be bonded together via the linker, and ring 2 and ring 5 may be bonded together via the linker.

In one or more embodiments, in Formula 3, ring 5 and ring 6 may not be bonded together via the linker, ring 5 and ring 71 may not be bonded together via the linker, and ring 5 and ring 71 may not be bonded together via the linker.

In one or more embodiments, in Formula 3, among combinations of two rings selected from ring 1, ring 2, ring 3, ring 4, ring 5, ring 6, ring 71, and ring 72, a combination other than a combination selected from a combination of ring 1 and ring 2, a combination of ring 1 and ring 3, a combination of ring 2 and ring 5, a combination of ring 4 and ring 5, a combination of ring 6 and ring 71, a combination of ring 6 and ring 72, and a combination of ring 71 and ring 72 may not be bonded together via the linker.

In one or more embodiments, in Formula 3, ring 1 and ring 2 may not be bonded together via the linker, ring 4 and ring 5 may not be bonded together via the linker, ring 6 and ring 71 may not be bonded together via the linker, ring 6 and ring 72 may not be bonded together via the linker, and ring 71 and ring 72 may not be bonded together via the linker.

In one or more embodiments, in Formula 3, R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a cyano group, a halogen atom, a deuterium atom, an aryl group (unsubstituted aryl group), a heteroaryl group (unsubstituted heteroaryl group), a diarylamino group (unsubstituted diarylamino group), a diheteroarylamino group (unsubstituted diheteroarylamino group), an arylheteroarylamino group (unsubstituted arylheteroarylamino group), an alkyl group (unsubstituted alkyl group), an aryloxy group (unsubstituted aryloxy group), a heteroaryloxy group (unsubstituted heteroaryloxy group), an arylthio group (unsubstituted arylthio group), a heteroarylthio group (unsubstituted heteroarylthio group), or a linker.

In this regard, R⁶¹, R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a cyano group, a halogen atom, a deuterium atom, a heteroaryl group (unsubstituted heteroaryl group), a diarylamino group (unsubstituted diarylamino group), a diheteroarylamino group (unsubstituted diheteroarylamino group), an arylheteroarylamino group (unsubstituted arylheteroarylamino group), an alkyl group (unsubstituted alkyl group), an aryloxy group (unsubstituted aryloxy group), a heteroaryloxy group (unsubstituted heteroaryloxy group), an arylthio group (unsubstituted arylthio group), or a heteroarylthio group (unsubstituted heteroarylthio group), and R⁶² may be a hydrogen atom, an aryl group (unsubstituted aryl group), a heteroaryl group (unsubstituted heteroaryl group), a diarylamino group (unsubstituted diarylamino group), a diheteroarylamino group (unsubstituted diheteroarylamino group), an arylheteroarylamino group (unsubstituted arylheteroarylamino group), an alkyl group (unsubstituted alkyl group), an aryloxy group (unsubstituted aryloxy group), a heteroaryloxy group (unsubstituted heteroaryloxy group), an arylthio group (unsubstituted arylthio group), or a heteroarylthio group (unsubstituted heteroarylthio group).

In one or more embodiments, in Formula 3, R⁶¹ may be a hydrogen atom, a cyano group, a halogen atom, a deuterium atom, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 3, R⁶¹ may be a hydrogen atom, a cyano group, a halogen atom, a deuterium atom, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 3, R⁶¹ may be a hydrogen atom or a substituted or unsubstituted alkyl group, or may be a hydrogen atom.

In one or more embodiments, in Formula 3, R⁶³ may be a hydrogen atom, a cyano group, a halogen atom, a deuterium atom, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 3, R⁶³ may be a hydrogen atom, a cyano group, a halogen atom, a deuterium atom, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 3, R⁶³ may be a hydrogen atom or a substituted or unsubstituted alkyl group. For example, R⁶³ may be a hydrogen atom.

In one or more embodiments, in Formula 3, R⁶¹ and R⁶³ may each be a hydrogen atom.

In one or more embodiments, in Formula 3, R⁶² may be a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 3, R⁶² may be a hydrogen atom, a cyano group, a halogen atom, a deuterium atom, a substituted or unsubstituted aryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group.

In one or more embodiments, in Formula 3, R⁶² may be a hydrogen atom, a substituted or unsubstituted aryl group, or a substituted or unsubstituted alkyl group. For example, R⁶² may be a hydrogen atom or a substituted or unsubstituted alkyl group. For example, R⁶² may be a hydrogen atom or an alkyl group.

In one or more embodiments, in Formula 3, R⁶² may be a hydrogen atom, a linear alkyl group, or a branched alkyl group. For example, R⁶² may be a hydrogen atom or a branched alkyl group. For example, R⁶² may be a hydrogen atom or a tert-butyl group. For example, R⁶² may be a hydrogen atom.

In one or more embodiments, in Formula 3, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a cyano group, a halogen atom, a deuterium atom, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group. In one or more embodiments, in Formula 3, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a cyano group, a halogen atom, a deuterium atom, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group. In one or more embodiments, in Formula 3, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom or a substituted or unsubstituted alkyl group.

In one or more embodiments, in Formula 3, R⁷¹¹, R⁷¹², R⁷¹³, R⁷¹⁵, R⁷²¹, R⁷²³, R⁷²⁴ and R⁷²⁵ may each be a hydrogen atom.

In one or more embodiments, in Formula 3, R⁷¹⁴ may be a hydrogen atom or a substituted or unsubstituted alkyl group, may be a hydrogen atom or an alkyl group, or may be a hydrogen atom, a linear alkyl group, or a branched alkyl group. In one or more embodiments, in Formula 3, R⁷¹⁴ may be a hydrogen atom or a branched alkyl group. For example, R⁷¹⁴ may be a hydrogen atom or a tert-butyl group. For example, R⁷¹⁴ may be a hydrogen atom.

In one or more embodiments, in Formula 3, R⁷²² may be a hydrogen atom or a substituted or unsubstituted alkyl group. For example, R⁷²² may be a hydrogen atom or an alkyl group. For example, R⁷²² may be a hydrogen atom, a linear alkyl group, or a branched alkyl group. In one or more embodiments, in Formula 3, R⁷²² may be a hydrogen atom or a branched alkyl group. For example, R⁷²² may be a hydrogen atom or a tert-butyl group. For example, R⁷²² may be a hydrogen atom.

In one or more embodiments, in Formula 3, R⁷¹⁴ and R⁷²² may each be a hydrogen atom.

In one or more embodiments, in Formula 3, R⁷¹¹, R⁷¹², R⁷¹³, R⁷¹⁴, R⁷¹⁵, R⁷²¹, R⁷²², R⁷²³, R⁷²⁴, and R⁷²⁵ may each be a hydrogen atom.

In one or more embodiments, in Formula 3, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a substituted or unsubstituted aryl group, or a substituted or unsubstituted alkyl group. In one or more embodiments, in Formula 3, R⁶¹, R⁶², and R⁶³ may each independently be a hydrogen atom, a substituted or unsubstituted aryl group, or a substituted or unsubstituted alkyl group, and R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom or a substituted or unsubstituted alkyl group. In one or more embodiments, in Formula 3, R⁶¹, R⁶³, R⁷¹¹, R⁷¹², R⁷¹³, R⁷¹⁵, R⁷²¹, R⁷²³, R⁷²⁴, and R⁷²⁵ may each be a hydrogen atom, R⁶² may be a hydrogen atom, a substituted or unsubstituted aryl group, or a substituted or unsubstituted alkyl group, and R⁷¹⁴ and R⁷²² may each independently be a hydrogen atom or a substituted or unsubstituted alkyl group. In one or more embodiments, in Formula 3, R⁶² may be a hydrogen atom, an aryl group, or an alkyl group, may be a hydrogen atom, a phenyl group, or an alkyl group, or may be a hydrogen atom, a linear alkyl group, or a branched alkyl group. In one or more embodiments, in Formula 3, R⁶² may be a hydrogen atom or a branched alkyl group, may be a hydrogen atom or a tert-butyl group, or may be a hydrogen atom. In one or more embodiments, in Formula 3, R⁷¹⁴ and R⁷²² may each independently be a hydrogen atom or an alkyl group, or may each independently be a hydrogen atom, a linear alkyl group, or a branched alkyl group. In one or more embodiments, in Formula 3, R⁷¹⁴ and R⁷²² may each independently be a hydrogen atom or a branched alkyl group. In one or more embodiments, in Formula 3, R⁷¹⁴ and R⁷²² may each independently be a hydrogen atom or a tert-butyl group. In one or more embodiments, in Formula 3, R⁷¹⁴ and R⁷²² may each be a hydrogen atom. In one or more embodiments, in Formula 3, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each be a hydrogen atom.

In one or more embodiments, in Formulae 1 to 3, the linker linking two or more portions on the same ring together may include at least two selected from R¹¹, R¹², R¹³ or R¹⁴, at least two selected from R²¹, R²², R²³, or R²⁴, or at least two selected from R³¹, R³², R³³, or R³⁴, wherein R⁴¹ and R⁴² may be linked together, and at least two selected from R⁵¹, R⁵², R⁵³, R⁵⁴, or R⁵⁵ may be linked together. The linker linking two or more portions on the same ring together may include at least two selected from two or more R⁶(s). The linker linking two or more portions on the same ring together may include, for example, at least two selected from two or more R⁷(s) bonded to the same ring 7. The linker linking two or more portions on the same ring together may include, for example, at least two selected from R⁶¹, R⁶², or R⁶³, or at least two selected from R⁷¹¹, R⁷¹², R⁷¹³, R⁷¹⁴, R⁷¹⁵, R⁷²¹, R⁷²², R⁷²³, R⁷²⁴, or R⁷²⁵.

In Formulae 1 to 3, the linker linking two or more portions on the same ring together may be a divalent group derived from a polycyclic aromatic hydrocarbon ring having a structure in which a substituted or unsubstituted benzene ring and a substituted or unsubstituted fluorene ring are bonded together. For example, the linker may be a group formed by combining divalent groups derived from in the form of a polycyclic aromatic hydrocarbon ring having a structure in which a benzene ring and a fluorene ring are bonded together.

In Formulae 1 to 3, when the linking group is a substituted group, a substituent of the linking group is not particularly limited, but may be a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group. When two or more substituents are present on the linking group, the types of the substituents of the linking group may be identical to or different from each other.

In one or more embodiments, in Formulae 1 to 3, when the aryl group, the heteroaryl group, the diarylamino group, the diheteroarylamino group, the arylheteroarylamino group, the alkyl group, the aryloxy group, the heteroaryloxy group, the arylthio group, the heteroarylthio group, or the linker is a substituted group, the type of a substituent that substitutes these groups or portions (hereinafter, also referred to as “substituent (a)” in this paragraph) is not particularly limited. Examples of substituent (a) may include a cyano group, a halogen atom, a deuterium atom, an aryl group, a heteroaryl group, a diarylamino group, a diheteroarylamino group, an arylheteroarylamino group, an alkyl group, an aryloxy group, a heteroaryloxy group, an arylthio group, or a heteroarylthio group. In one or more embodiments, substituent (a) may be an aryl group, a heteroaryl group, a diarylamino group, a diheteroarylamino group, an arylheteroarylamino group, an alkyl group, an aryloxy group, a heteroaryloxy group, an arylthio group, or a heteroarylthio group, each substituted with at least one group that is a cyano group, a halogen atom, or a deuterium atom. When two or more substituents (a) are present, the types of substituents (a) may be identical to or different from each other. In addition, substituent (a) may not substitute a group of the same type. For example, substituent (a) that substitutes an aryl group may not include an aryl group.

In one or more embodiments, in Formulae 1 to 3, R¹¹, R¹³, R²⁴, R³², R³⁴, R⁴¹, R⁴², R⁵², and R⁵⁴ may each independently be a hydrogen atom, a cyano group, a halogen atom, or a deuterium atom. In one or more embodiments, in Formulae 1 to 3, R¹¹, R¹³, R²⁴, R³², R³⁴, R⁴¹, R⁴², R⁵², and R⁵⁴ may each be a hydrogen atom.

In one or more embodiments, in Formulae 1 to 3, R¹² may be a hydrogen atom, a cyano group, a halogen atom, a deuterium atom, a substituted or unsubstituted aryl group, or a substituted or unsubstituted alkyl group. In one or more embodiments, in Formulae 1 to 3, R¹² may be a hydrogen atom, a substituted or unsubstituted aryl group, or a substituted or unsubstituted alkyl group. In one or more embodiments, in Formulae 1 to 3, R¹² may be a hydrogen atom or a substituted or unsubstituted alkyl group. For example, R¹² may be a substituted or unsubstituted alkyl group. For example, R¹² may be an alkyl group (unsubstituted alkyl group). In one or more embodiments, in Formulae 1 to 3, R¹² may be a linear alkyl group (unsubstituted linear alkyl group) or a branched alkyl group (unsubstituted branched alkyl group). For example, R¹² may be a tert-butyl group.

In one or more embodiments, in Formulae 1 to 3, R³³ may be a hydrogen atom, a cyano group, a halogen atom, a deuterium atom, a substituted or unsubstituted aryl group, or a substituted or unsubstituted alkyl group. In one or more embodiments, in Formulae 1 to 3, R³³ may be a hydrogen atom, a substituted or unsubstituted aryl group, or a substituted or unsubstituted alkyl group. For example, R³³ may be a hydrogen atom or a substituted or unsubstituted alkyl group. In one or more embodiments, in Formulae 1 to 3, R³³ may be a substituted or unsubstituted alkyl group, for example, an alkyl group (unsubstituted alkyl group). In Formulae 1 to 3, R³³ may be a linear alkyl group (unsubstituted linear alkyl group) or a branched alkyl group (unsubstituted branched alkyl group). For example, R³³ may be a tert-butyl group.

In one or more embodiments, in Formulae 1 to 3, R²³ may be a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker. In one or more embodiments, in Formulae 1 to 3, R²³ may be a substituted or unsubstituted aryl group, a substituted or unsubstituted heteroaryl group, a substituted or unsubstituted alkyl group, or a linker. In one or more embodiments, in Formulae 1 to 3, R²³ may be a substituted or unsubstituted alkyl group or a linker. For example, R²³ may be an alkyl group. In one or more embodiments, in Formulae 1 to 3, R²³ may be a linear alkyl group or a branched alkyl group. For example, R²³ may be a tert-butyl group.

In one or more embodiments, in Formulae 1 to 3, R⁵⁵ may be a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker. In one or more embodiments, in Formulae 1 to 3, R⁵⁵ may be a substituted or unsubstituted aryl group, a substituted or unsubstituted heteroaryl group, a substituted or unsubstituted alkyl group, or a linker. In one or more embodiments, in Formulae 1 to 3, R⁵⁵ may be a substituted or unsubstituted alkyl group or a linker. For example, R⁵⁵ may be a linker.

In one or more embodiments, in Formulae 1 to 3, R¹⁴ may be a hydrogen atom, a cyano group, a halogen atom, a deuterium atom, or a linker. For example, R¹⁴ may be a hydrogen atom or a linker. In one or more embodiments, in Formulae 1 to 3, R¹⁴ may be a linker.

In one or more embodiments, in Formulae 1 to 3, R²¹ may be a hydrogen atom, a cyano group, a halogen atom, a deuterium atom, or a linker. For example, R²¹ may be a hydrogen atom or a linker. In one or more embodiments, in Formulae 1 to 3, R²¹ may be a linker.

In one or more embodiments, in Formulae 1 to 3, R³¹ may be a hydrogen atom, a cyano group, a halogen atom, a deuterium atom, or a linker. For example, R³¹ may be a hydrogen atom or a linker. In one or more embodiments, in Formulae 1 to 3, R³¹ may be a linker.

In one or more embodiments, in Formulae 1 to 3, R¹⁴, R²¹, R³¹, and R⁵⁵ may each be a linker.

In one or more embodiments, in Formulae 1 to 3, R²² may be a hydrogen atom, a cyano group, a halogen atom, a deuterium atom, or a linker. For example, R²² may be a hydrogen atom or a linker. In one or more embodiments, in Formulae 1 to 3, R²² may be a hydrogen atom.

In one or more embodiments, in Formulae 1 to 3, R⁵¹ may be a hydrogen atom, a cyano group, a halogen atom, a deuterium atom, or a substituted or unsubstituted aryl group. In one or more embodiments, in Formulae 1 to 3, R⁵¹ may be a hydrogen atom or a substituted or unsubstituted aryl group. For example, R⁵¹ may be a hydrogen atom.

In one or more embodiments, in Formulae 1 to 3, R⁵³ may be a hydrogen atom, a cyano group, a halogen atom, a deuterium atom, a substituted or unsubstituted aryl group, or a substituted or unsubstituted alkyl group. In one or more embodiments, in Formulae 1 to 3, R⁵³ may be a hydrogen atom, a substituted or unsubstituted aryl group, or a substituted or unsubstituted alkyl group. In one or more embodiments, in Formulae 1 to 3, R⁵³ may be a hydrogen atom or a substituted or unsubstituted alkyl group. For example, R⁵³ may be a substituted or unsubstituted alkyl group. For example, R⁵³ may be an alkyl group. For example, R⁵³ may be a linear alkyl group or a branched alkyl group. In one or more embodiments, in Formulae 1 to 3, R⁵³ may be an alkyl group. For example, R⁵³ may be a tert-butyl group.

In one or more embodiments, in Formulae 1 to 3, R¹¹, R¹³, R²², R²⁴, R³², R³⁴, R⁴¹, R⁴², R⁵¹, R⁵², and R⁵⁴ may each be a hydrogen atom.

In one or more embodiments, in Formulae 1 and 2, m may be 3, n may be 2, and each R⁶ may independently be a hydrogen atom or an alkyl group. In this regard, each R⁶ may independently be a hydrogen atom, a linear alkyl group, or a branched alkyl group. For example, each R⁶ may independently be a hydrogen atom or a branched alkyl group. For example, each R⁶ may independently be a hydrogen atom or a tert-butyl group. For example, each R⁶ may be a hydrogen atom.

In one or more embodiments, in Formulae 1 to 3, R¹¹, R¹³, R²⁴, R³², R³⁴, R⁴¹, R⁴², R⁵², and R⁵⁴ may each independently be a hydrogen atom, a cyano group, a halogen atom, a deuterium atom, or a substituted or unsubstituted alkyl group. In this regard, in Formula 3, R⁶² may be a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group, and R⁶¹, R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a cyano group, a halogen atom, a deuterium atom, or a substituted or unsubstituted alkyl group.

In one or more embodiments, in Formulae 1 to 3, R¹⁴, R²¹, R²², R²³, R³¹, and R⁵⁵ may each independently be a hydrogen atom, a cyano group, a halogen atom, a deuterium atom, a substituted or unsubstituted aryl group, a substituted or unsubstituted heteroaryl group, a substituted or unsubstituted alkyl group, or a linker, R¹², R³³, R⁵¹, and R⁵³ may each independently be a hydrogen atom, a cyano group, a halogen atom, a deuterium atom, a substituted or unsubstituted aryl group, or a substituted or unsubstituted alkyl group, and R¹¹, R¹³, R²⁴, R³², R³⁴, R⁴¹, R⁴², R⁵², and R⁵⁴ may each independently be a hydrogen atom, a cyano group, a halogen atom, or a deuterium atom. In this regard, in Formula 3, R⁶² may be a hydrogen atom, a cyano group, a halogen atom, a deuterium atom, a substituted or unsubstituted aryl group, or a substituted or unsubstituted alkyl group, and R⁶¹, R⁶³, R⁷¹¹, R⁷¹², R⁷¹³, R⁷¹⁴, R⁷¹⁵, R⁷²¹, R⁷²², R⁷²³, R⁷²⁴ and R⁷²⁵ may each independently be a hydrogen atom, a cyano group, a halogen atom, a deuterium atom, or a substituted or unsubstituted alkyl group.

In one or more embodiments, in Formulae 1 to 3, R¹¹, R¹³, R²⁴, R³², R³⁴, R⁴¹, R⁴², R⁵², and R⁵⁴ may each independently be a hydrogen atom or a substituted or unsubstituted alkyl group. In this regard, in Formula 3, R⁶² may be a hydrogen atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, or a substituted or unsubstituted heteroarylthio group, and R⁶¹, R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom or a substituted or unsubstituted alkyl group.

In one or more embodiments, in Formulae 1 to 3, R¹⁴, R²¹, R²², R²³, R³¹, and R⁵⁵ may each independently be a hydrogen atom, a substituted or unsubstituted aryl group, a substituted or unsubstituted heteroaryl group, a substituted or unsubstituted alkyl group, or a linker, R¹², R³³, R⁵¹, and R⁵³ may each independently be a hydrogen atom, a substituted or unsubstituted aryl group, or a substituted or unsubstituted alkyl group, and R¹¹, R¹³, R²⁴, R³², R³⁴, R⁴¹, R⁴², R⁵², and R⁵⁴ may each be a hydrogen atom. In this regard, in Formula 3, R⁶² may be a hydrogen atom, a substituted or unsubstituted aryl group, or a substituted or unsubstituted alkyl group, and R⁶¹, R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom or a substituted or unsubstituted alkyl group. In one or more embodiments, R⁶² may be a hydrogen atom or a substituted or unsubstituted alkyl group, and R⁶¹, R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each be a hydrogen atom. Among the above-described groups, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each be a hydrogen atom. In the above embodiments, the substituted or unsubstituted aryl group may be an aryl group (unsubstituted aryl group), the substituted or unsubstituted heteroaryl group may be a heteroaryl group (unsubstituted heteroaryl group), and the substituted or unsubstituted alkyl group may be an alkyl group (unsubstituted alkyl group). In the above embodiments, the substituted or unsubstituted aryl group may be a phenyl group, the substituted or unsubstituted heteroaryl group may be a carbazolyl group, the substituted or unsubstituted alkyl group may be a linear alkyl group or a branched alkyl group (for example, a branched alkyl group, such as a tert-butyl group), but embodiments are not limited thereto.

In one or more embodiments, in Formulae 1 to 3, R²³ may be a phenyl group, a carbazolyl group, a branched alkyl group (for example, a tert-butyl group), or a linker, R⁵⁵ may be a hydrogen atom, a phenyl group, a carbazolyl group, a branched alkyl group (for example, a tert-butyl group), or a linker, R¹² and R³³ may each independently be a hydrogen atom, a phenyl group, or a branched alkyl group (for example, a tert-butyl group), R¹⁴, R²¹, R²², and R³¹ may each independently be a hydrogen atom or a linker, R⁵¹ may be a hydrogen atom or a phenyl group, R⁵³ may be a hydrogen atom, a phenyl group, or a branched alkyl group (for example, a tert-butyl group), and R¹¹, R¹³, R²⁴, R³², R³⁴, R⁴¹, R⁴², R⁵², and R⁵⁴ may each be a hydrogen atom. In this regard, in Formula 3, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom, a phenyl group, or a branched alkyl group (for example, a tert-butyl group). In addition, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each independently be a hydrogen atom or a branched alkyl group (for example, a tert-butyl group). In addition, R⁶², R⁷¹⁴, and R⁷²² may each independently be a hydrogen atom or a branched alkyl group (for example, a tert-butyl group), and R⁶¹, R⁶³, R⁷¹¹, R⁷¹², R⁷¹³, R⁷¹⁵, R⁷²¹, R⁷²³, R⁷²⁴, and R⁷²⁵ may each be a hydrogen atom. Among the above-described groups, R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ may each be a hydrogen atom.

In one or more embodiments, the boron compound represented by Formula 1 may be selected from Group I, but embodiments are not limited thereto:

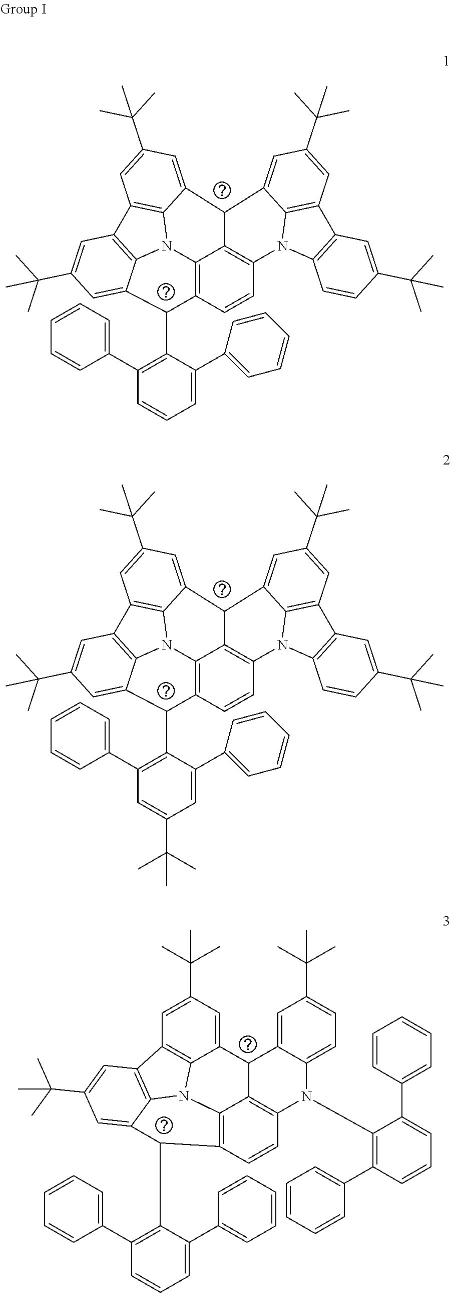

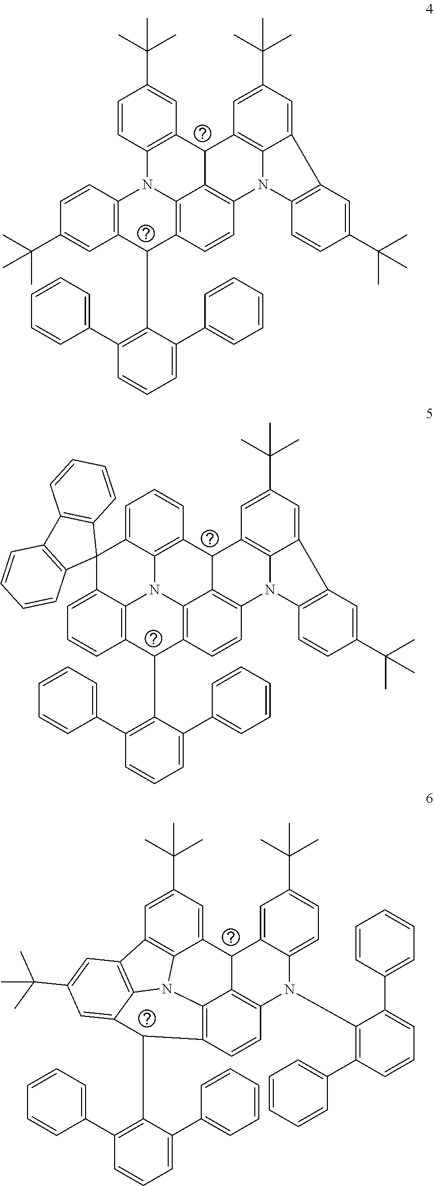

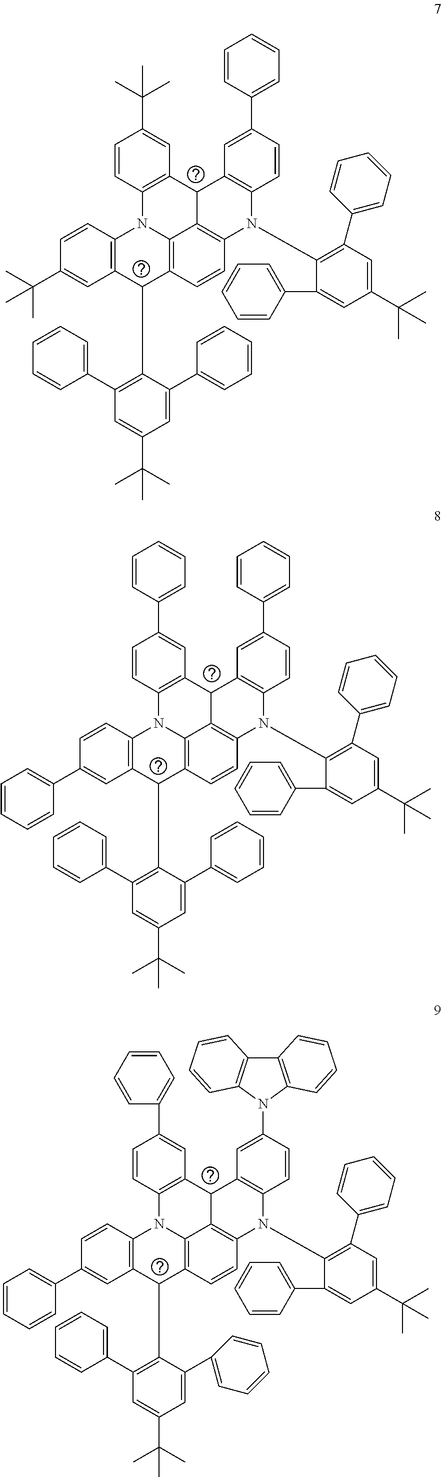 [SMILES: CC(C)(C)c1cc(-c2ccccc2)c(C2c3cc(C(C)(C)C)ccc3N3c4ccc(C(C)(C)C)cc4C4c5cc(-c6ccccc6)ccc5N(c5c(-c6ccccc6)cc(C(C)(C)C)cc5-c5ccccc5)c5ccc2c3c54)c(-c2ccccc2)c1 ; CC(C)(C)c1cc(-c2ccccc2)c(C2c3cc(-c4ccccc4)ccc3N3c4ccc(-c5ccccc5)cc4C4c5cc(-c6ccccc6)ccc5N(c5c(-c6ccccc6)cc(C(C)(C)C)cc5-c5ccccc5)c5ccc2c3c54)c(-c2ccccc2)c1 ; CC(C)(C)c1cc(-c2ccccc2)c(C2c3cc(-c4ccccc4)ccc3N3c4ccc(-c5ccccc5)cc4C4c5cc(-n6c7ccccc7c7ccccc76)ccc5N(c5c(-c6ccccc6)cc(C(C)(C)C)cc5-c5ccccc5)c5ccc2c3c54)c(-c2ccccc2)c1]

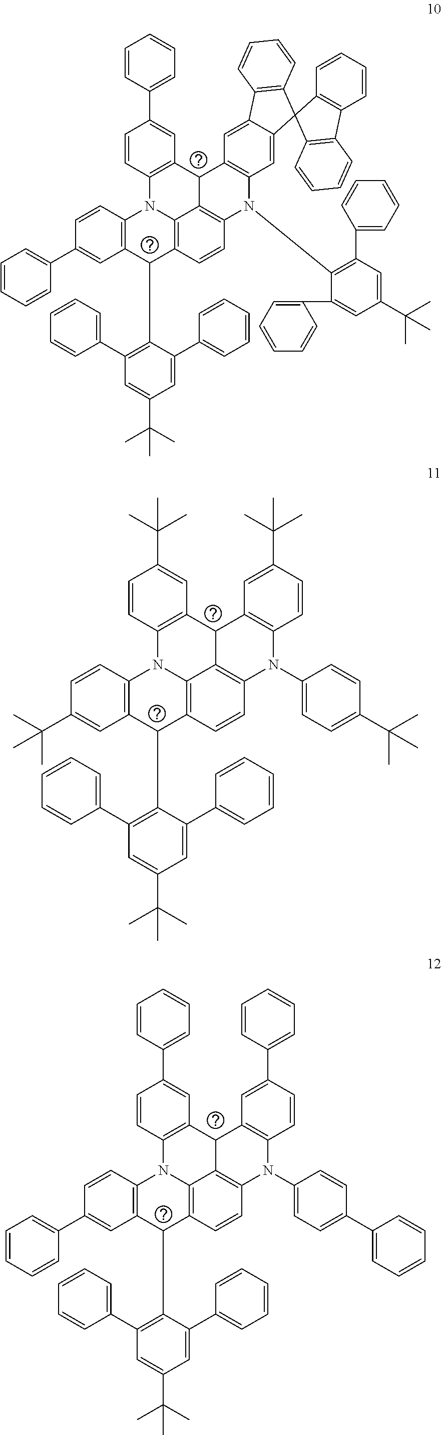

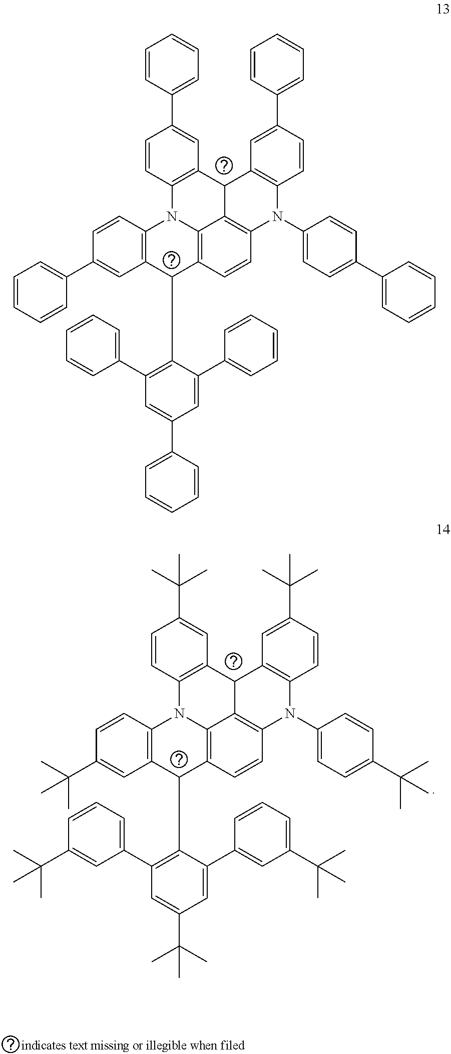

In one or more embodiments, the boron compound represented by Formula 1 may be selected from Compounds 1 and 2. For example, the boron compound represented by Formula 1 may be Compound 1.

The amount of the boron compound represented by Formula 1 in the composition for an organic EL device is not particularly limited, but may be about 0.1 weight percent (wt %) or more, about 0.5 wt or more, or about 1.0 wt or more, based on the total weight of the composition for an organic EL device. The amount of the boron compound represented by Formula 1 in the composition for an organic EL device is not particularly limited, but may be about 10.0 wt % or less, about 5.0 wt % or less, or about 2.0 wt % or less, based on the total weight of the composition for an organic EL device. For example, the amount of the boron compound represented by Formula 1 in the composition for an organic EL device may be about 0.1 wt % to about 10.0 wt %, about 0.5 wt % to about 5.0 wt %, or about 1.0 wt % to about 2.0 wt %, based on the total weight of the composition for an organic EL device. When two or more boron compounds are used, the amount of the boron compound represents the total amount of the two or more boron compounds. When the amount of the boron compound represented by Formula 1 is within the above ranges, an organic EL device having superior color purity of luminescence, higher luminescence efficiency, and longer lifespan may be obtained.

The peak wavelength (λ^{PL}) of fluorescence emission in photoluminescence (PL) of a toluene solution of the boron compound represented by Formula 1 at a concentration of 1×10⁻⁷ molar (M) is not particularly limited. APL may be within the blue wavelength range. λ^{PL} may be about 360 nm to about 515 nm, about 380 nm to about 505 nm, about 400 nm to about 500 nm, about 420 nm to about 490 nm, about 430 nm to about 480 nm, or about 455 nm to about 475 nm. For example, λ^{PL} may be about 440 nm to about 470 nm, or greater than about 455 nm and less than or equal to about 470 nm. The unit of concentration, M, represents mol/dm³ (=mol/L). When λ^{PL} is within the above ranges, excellent luminescence may be obtained.

The spectral width (FWHM of the emission peak) of fluorescence emission in PL of the toluene solution of the boron compound represented by Formula 1 at a concentration of 1×10⁻⁷ M is not particularly limited. The spectral width of fluorescence emission in PL (FWHM in PL) of the toluene solution of the boron compound represented by Formula 1 at a concentration of 1×10⁻⁷ M may be about 30 nm or less, about 25 nm or less, about 24 nm or less, less than about 24 nm, about 23 nm or less, about 22 nm or less, about 21 nm or less, about 20 nm or less, about 19 nm or less, about 18 nm or less, or about 17 nm or less (wherein the lower limit is greater than 0 nm). The unit of concentration, M, represents mol/dm³ (=mol/L). When the FWHM in PL of the toluene solution is within the above ranges, luminescence with higher color purity may be obtained.

The range of the peak wavelength of emission in PL of a 50 nm-thick thin film including the boron compound represented by Formula 1 in a weight ratio of 1 part by weight based on 100 parts by weight of the total weight of 1,3-bis(N-carbazolyl)benzene (mCP) and the boron compound is the same as the above range of λ^{PL}.

The FWHM in PL of the 50 nm-thick thin film including the boron compound represented by Formula 1 in a weight ratio of 1 part by weight based on 100 parts by weight of the total weight of mCP and the boron compound represented by Formula 1 is defined as Wf (nm). In addition, the FWHM in PL of the toluene solution of the boron compound represented by Formula 1 at a concentration of 1×10⁻⁷ M is defined as Ws (nm). In addition, the value obtained by subtracting Ws from Wf is defined as ΔW1 (nm) (that is, ΔW1=Wf−Ws). When ΔW1 is 0 nm or more, ΔW1 is not particularly limited, but a smaller value thereof is desirable. When ΔW1 is 0 nm or more, ΔW1 may be 5 nm or less, 4 nm or less, or 3 nm or less.

The peak wavelength (λ^{PL}) and spectral width (FWHM of the emission peak) of fluorescence emission of the toluene solution, and the peak wavelength and spectral width (FWHM of the emission peak) of emission of the thin film may be measured using a spectrofluorometer. Detailed measurement methods are as described in Examples.

The absolute PL quantum yield (PLQY) of the 50 nm-thick thin film including the boron compound represented by Formula 1 in a weight ratio of 1 part by weight based on 100 parts by weight of the total weight of mCP and the boron compound represented by Formula 1 is not particularly limited, but may be greater than about 90% and less than or equal to about 100%, about 92% to about 100%, or about 95% to about 100%. The PLQY of the thin film may be measured using an absolute PL quantum yield measuring device. A detailed measurement method is as described in the Examples.

A method of synthesizing the boron compound represented by Formula 1 is not particularly limited, and the boron compound represented by Formula 1 may be synthesized based on a known synthesis method. In detail, the boron compound represented by Formula 1 may be synthesized according to or in view of the method described in the Examples. For example, the boron compound represented by Formula 1 may be synthesized by changing the raw materials or reaction conditions in the method described in the Examples, by adding or excluding some procedures to or from the method described in the Examples, and/or by appropriately combining the method described in the Examples with a known synthesis method.

For example, Compounds 1 and 2 may be synthesized according to the method described in the Examples.

A method of identifying the structure of the boron compound represented by Formula 1 is not particularly limited. The structure of the boron compound represented by Formula 1 may be identified, for example, by a known method (for example, NMR or liquid chromatography-mass spectrometry (LC-MS)).

### Phosphorescent Material

The composition for an organic EL device includes a phosphorescent material. The phosphorescent material may function as a phosphor sensitizer. When the composition for an organic EL device, for example, a material for an emission layer, includes the phosphorescent material in addition to the boron compound represented by Formula 1, the luminescence efficiency and device lifespan of an organic EL device may be significantly improved. The phosphorescent material (phosphorescent compound) is not particularly limited, and a known compound exhibiting phosphorescence may be used. The phosphorescent material may be a phosphorescent complex, and may be an iridium complex or a platinum complex. In one or more embodiments, the phosphorescent material may be a platinum complex.

In one or more embodiments, the phosphorescent material may include at least one metal (M₁₁) selected from a fourth-row transition metal of the Periodic Table of Elements, a fifth-row transition metal of the Periodic Table of Elements, a sixth-row transition metal of the Periodic Table of Elements, or a seventh-row transition metal of the Periodic Table of Elements, and an organic ligand (L₁₁), wherein L₁₁ and M₁₁ may form 1, 2, 3, or 4 cyclometallated rings.

In one or more embodiments, the phosphorescent material may include a phosphorescent complex represented by Formula 101:

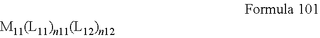

wherein, in Formula 101,
M₁₁ may be a fourth-row transition metal of the Periodic Table of Elements, a fifth-row transition metal of the Periodic Table of Elements, a sixth-row transition metal of the Periodic Table of Elements, or a seventh-row transition metal of the Periodic Table of Elements,
L₁₁ may be a ligand represented by one of Formulae 1-1 to 1-4,
L₁₂ may be a monodentate ligand or a bidentate ligand,
n11 may be 1, and
n12 may be 0, 1, or 2,

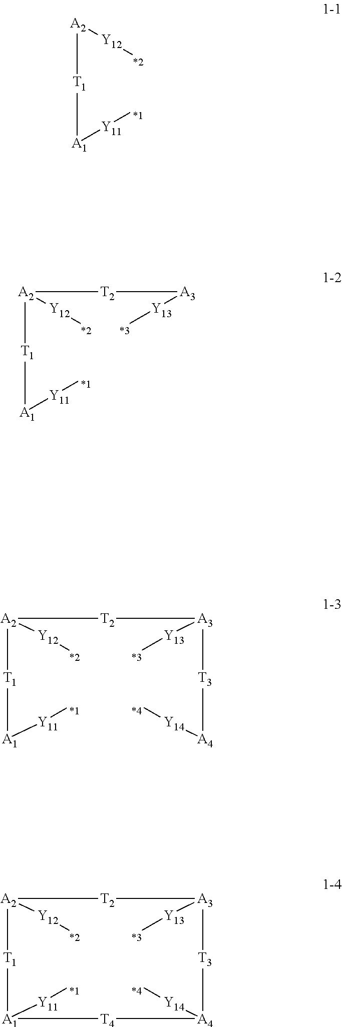

wherein, in Formulae 1-1 to 1-4,
A₁ to A₄ may each independently be a substituted or unsubstituted carbocyclic group, a substituted or unsubstituted heterocyclic group, or a non-cyclic group,
Y₁₁ to Y₁₄ may each independently be a chemical bond, O, S, N(R₉₁), B(R₉₁), P(R₉₁), or C(R₉₁)(R₉₂),
T₁ to T₄ may each independently be a single bond, a double bond, *—N(R₉₃)—*′, *—B(R₉₃)—*, *—P(R₉₃)—*, *—C(R₉₃)(R₉₄)—*′, *—Si(R₉₃)(R₉₄)—*, *—Ge(R₉₃)(R₉₄)—*, *—S—*′, *—Se—*, *—O—*, *—C(═O)—*, *—S(═O)—*, *—S(═O)₂—*, *—C(R₉₃)═*, *═C(R₉₃)—*′, *—C(R₉₃)═C(R₉₄)—*, *—C(═S)—*′, or *—C≡C—*′,
a substituent of the substituted C₅-C₃₀ carbocyclic group, a substituent of the substituted C₁-C₃₀ heterocyclic group, and R₉₁ to R₉₄ may each independently be hydrogen, deuterium, —F, —Cl, —Br, —I, —SF₅, a hydroxyl group, a cyano group, a nitro group, an amidino group, a hydrazine group, a hydrazone group, a carboxylic acid group or a salt thereof, a sulfonic acid group or a salt thereof, a phosphoric acid group or a salt thereof, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted heterocycloalkyl group, a substituted or unsubstituted cycloalkenyl group, a substituted or unsubstituted heterocycloalkenyl group, a substituted or unsubstituted aryl group, a substituted or unsubstituted aryloxy group, a substituted or unsubstituted arylthio group, a substituted or unsubstituted heteroaryl group, a substituted or unsubstituted monovalent aromatic condensed polycyclic group, a substituted or unsubstituted monovalent aromatic condensed heteropolycyclic group, a substituted or unsubstituted monovalent non-aromatic condensed polycyclic group, a substituted or unsubstituted monovalent non-aromatic condensed heteropolycyclic group, —Si(Q₁)(Q₂)(Q₃), —Ge(Q₁)(Q₂)(Q₃), —C(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), and —P(═S)(Q₁)(Q₂),
*₁, *₂, *₃, and *₄ each indicate a binding site to M₁₁, and
Q₁ to Q₃ may each independently be hydrogen; deuterium; —F; —Cl; —Br; —I; a hydroxyl group; a cyano group; a nitro group; an amidino group; a hydrazino group; a hydrazono group; an alkyl group; an alkenyl group; an alkynyl group; an alkoxy group; a cycloalkyl group; a heterocycloalkyl group, a cycloalkenyl group; a heterocycloalkenyl group; an aryl group; an alkylaryl group; an aryloxy group; an arylthio group; a heteroaryl group; an alkylheteroaryl group; a heteroaryloxy group; a heteroarylthio group; a monovalent aromatic condensed polycyclic group; a monovalent aromatic condensed heteropolycyclic group; a monovalent non-aromatic condensed polycyclic group; a monovalent non-aromatic condensed heteropolycyclic group; an alkyl group substituted with at least one of deuterium, —F, a cyano group, an alkyl group, or an aryl group; or an aryl group substituted with at least one of deuterium, —F, a cyano group, an alkyl group, or an aryl group.

For example, in Formula 101, M₁₁ may be Ir or Pt, for example, Pt.

In one or more embodiments, the phosphorescent material (phosphorescent compound) may include, for example, one or more of the following compounds.

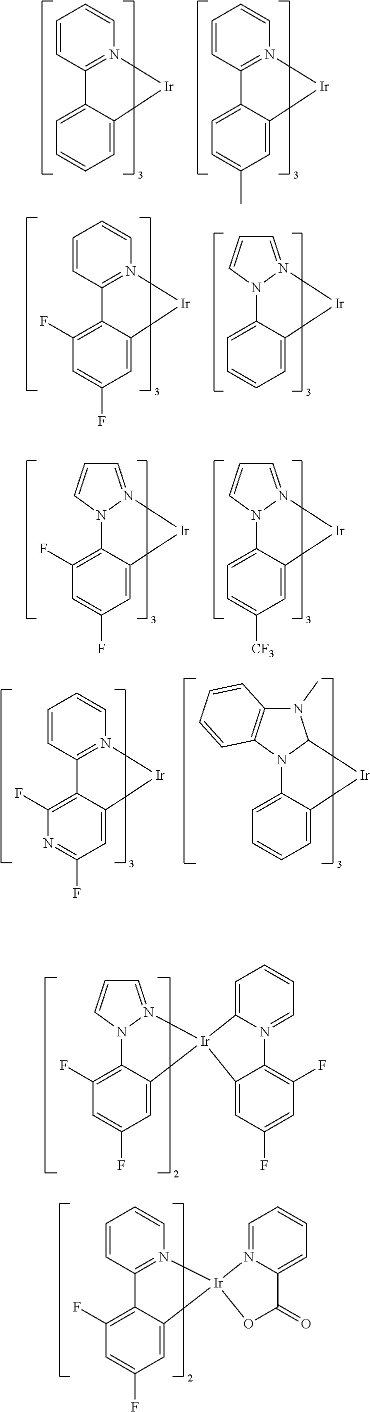

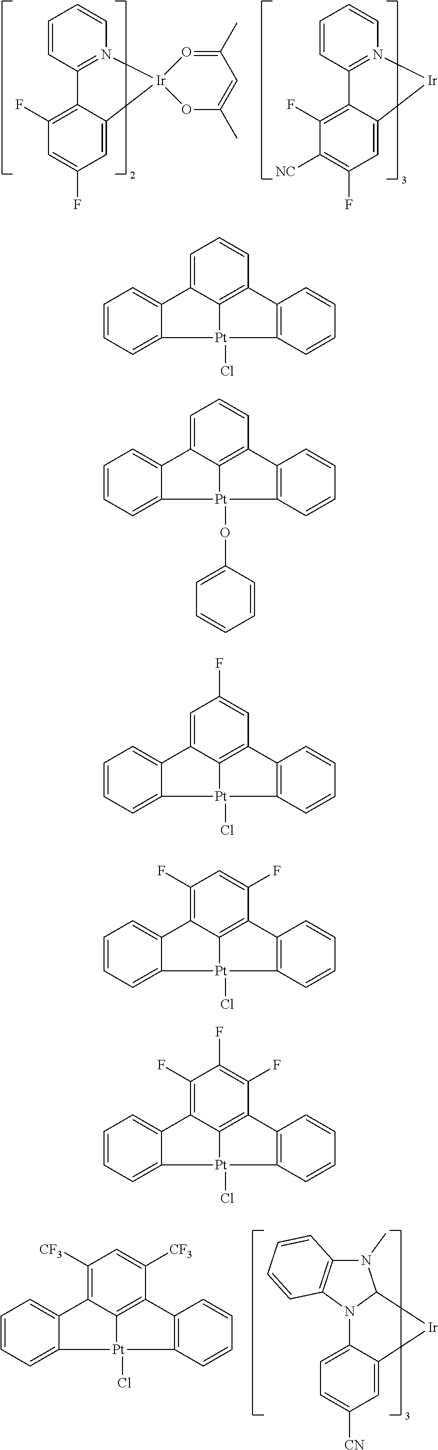

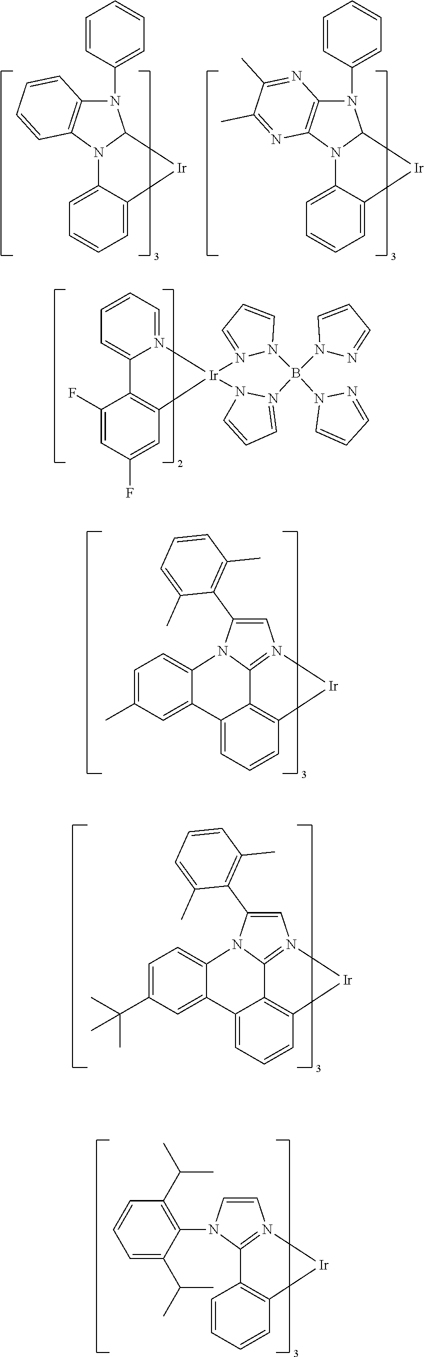

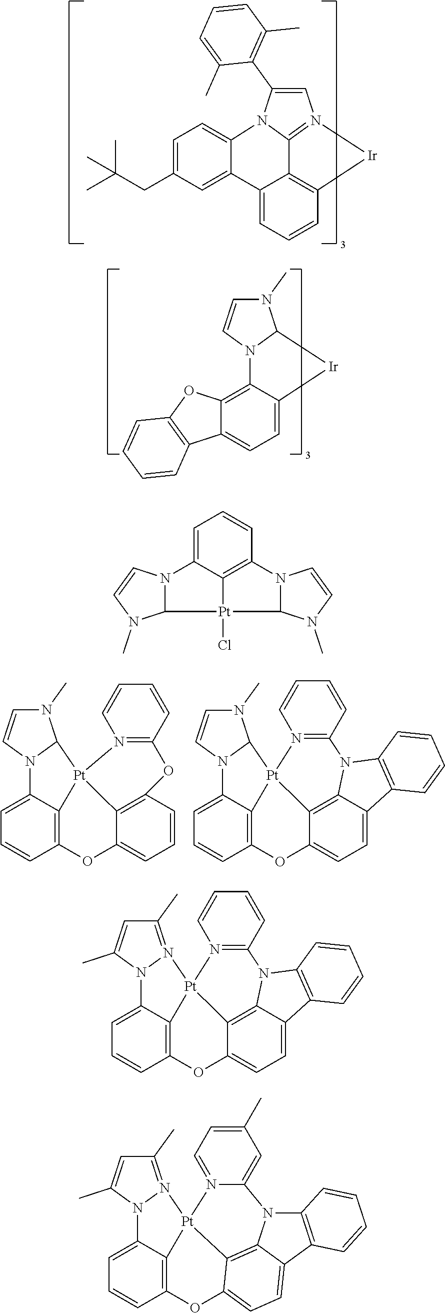

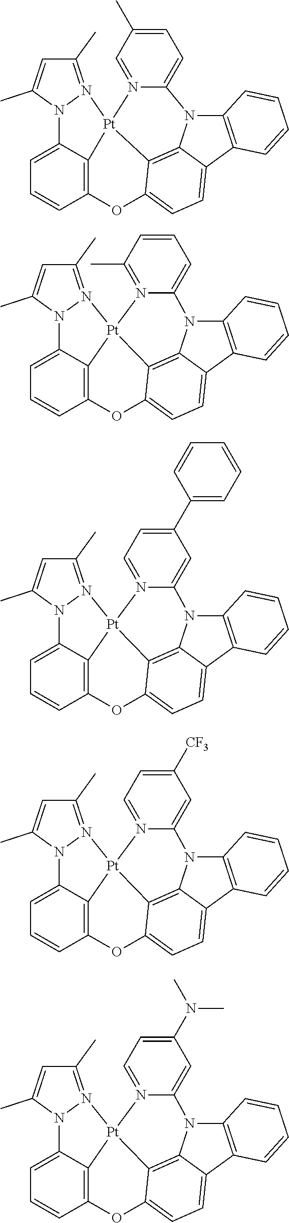

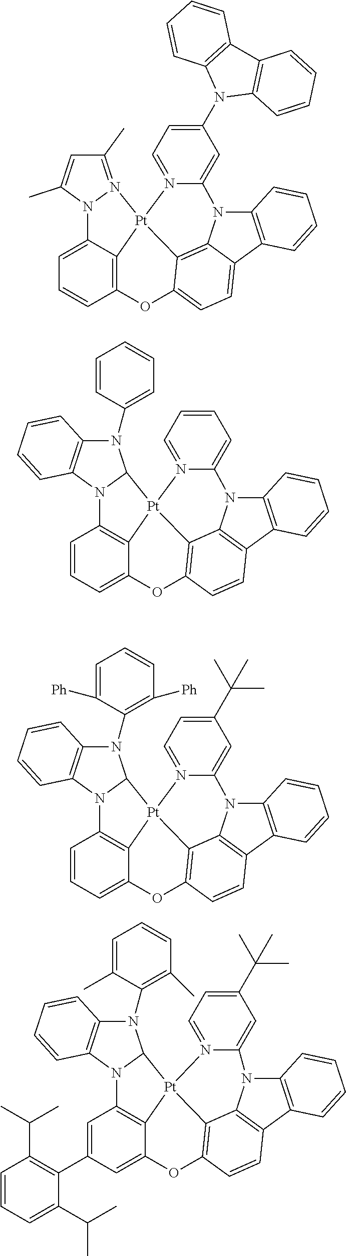

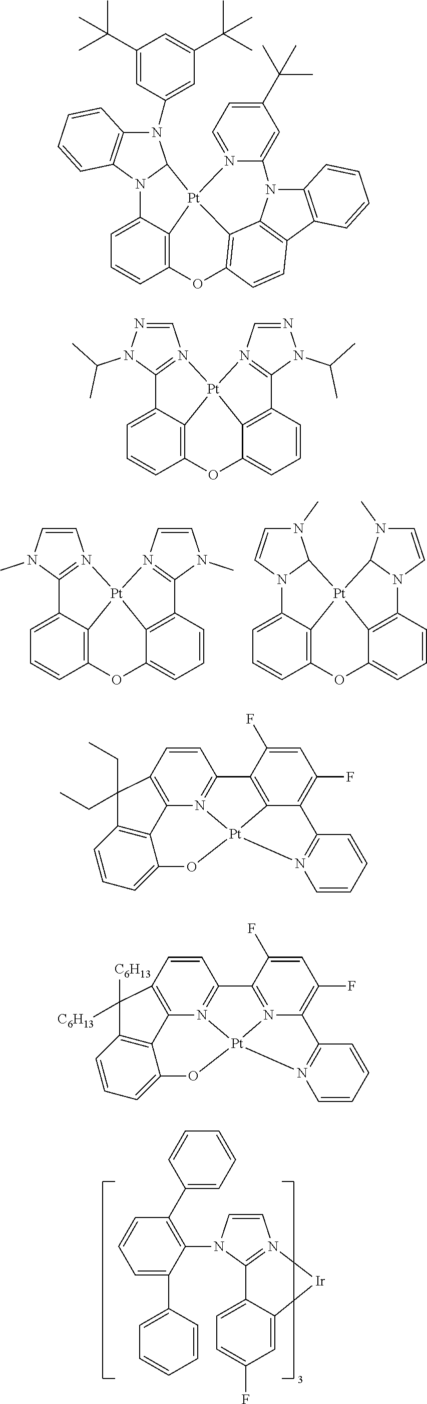

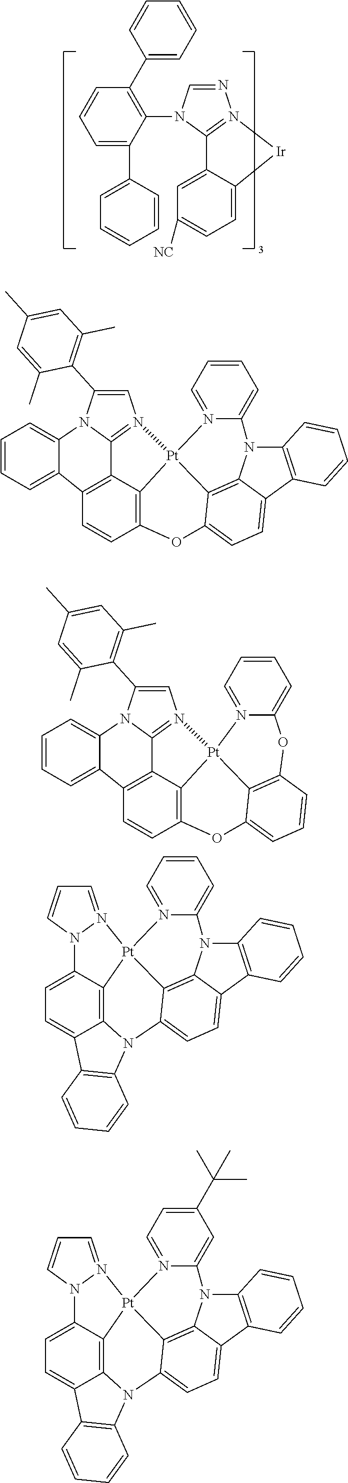

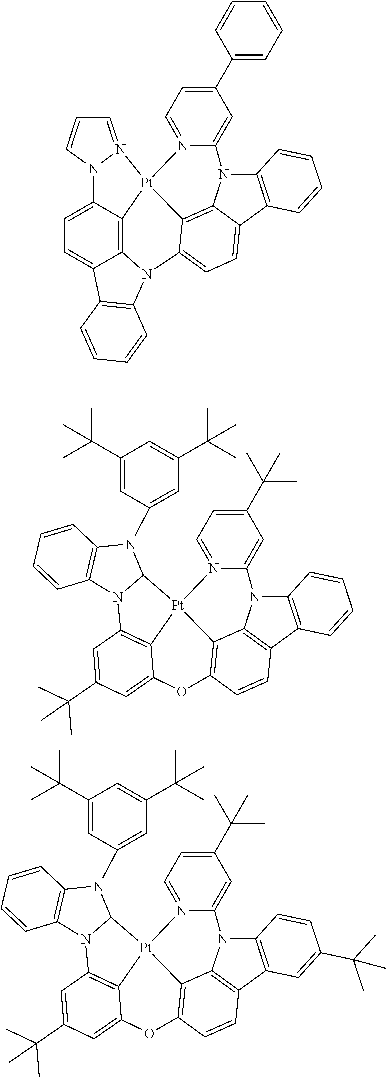

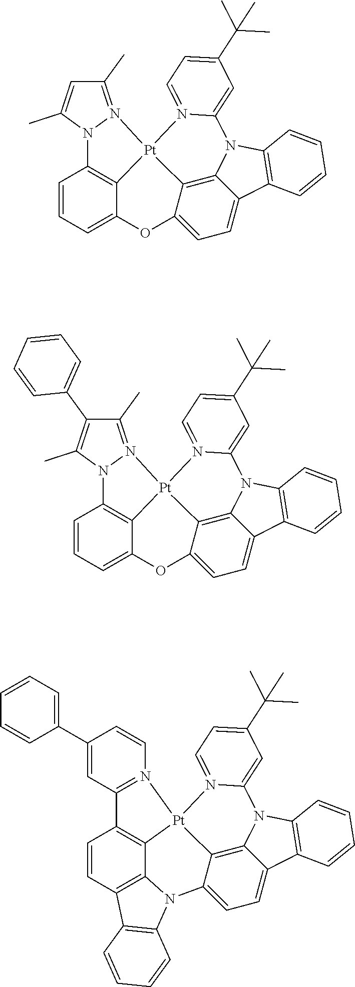

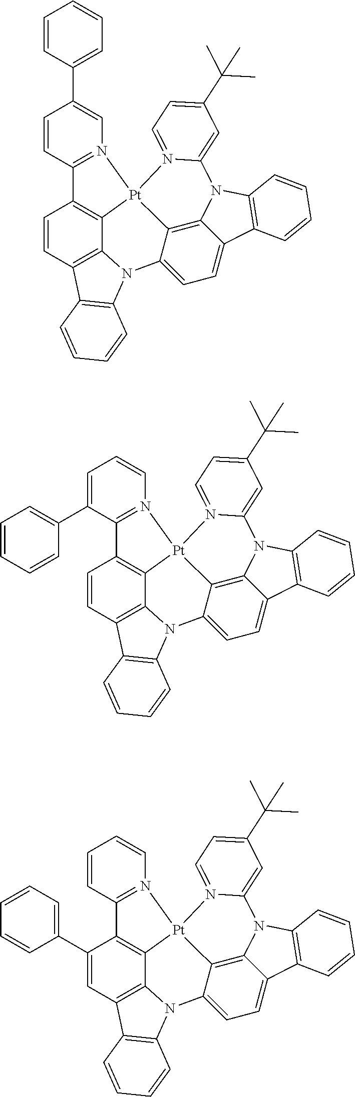

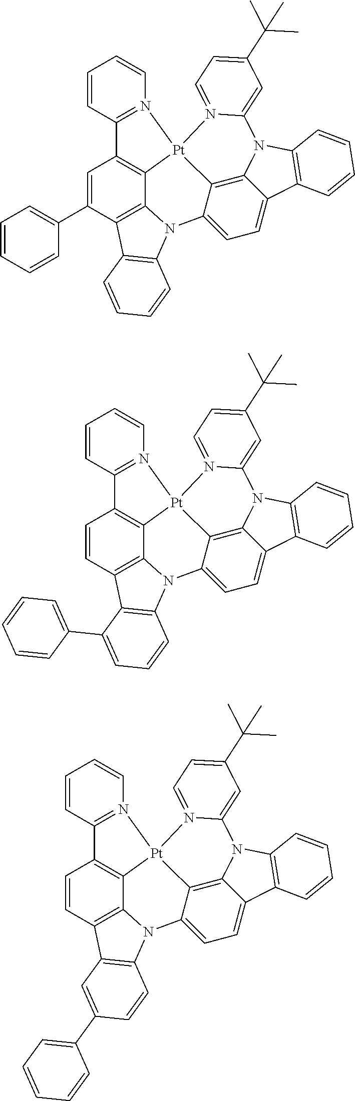

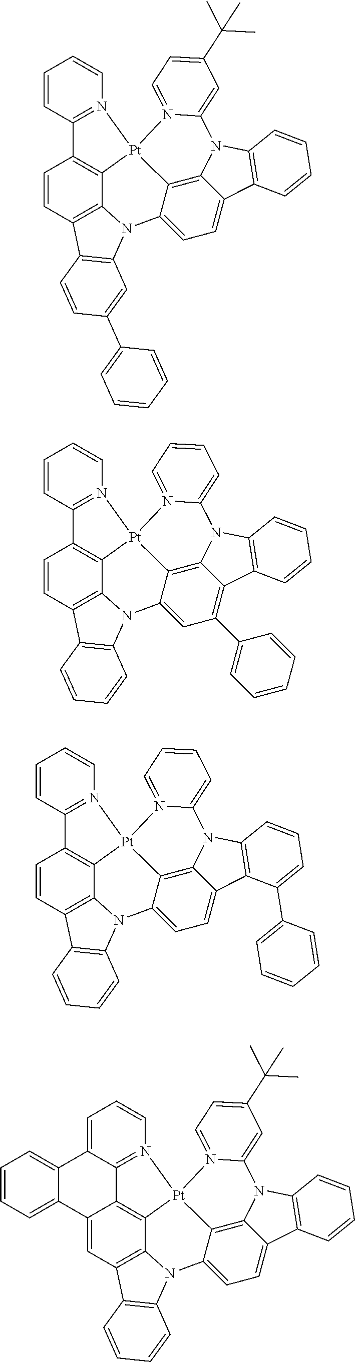

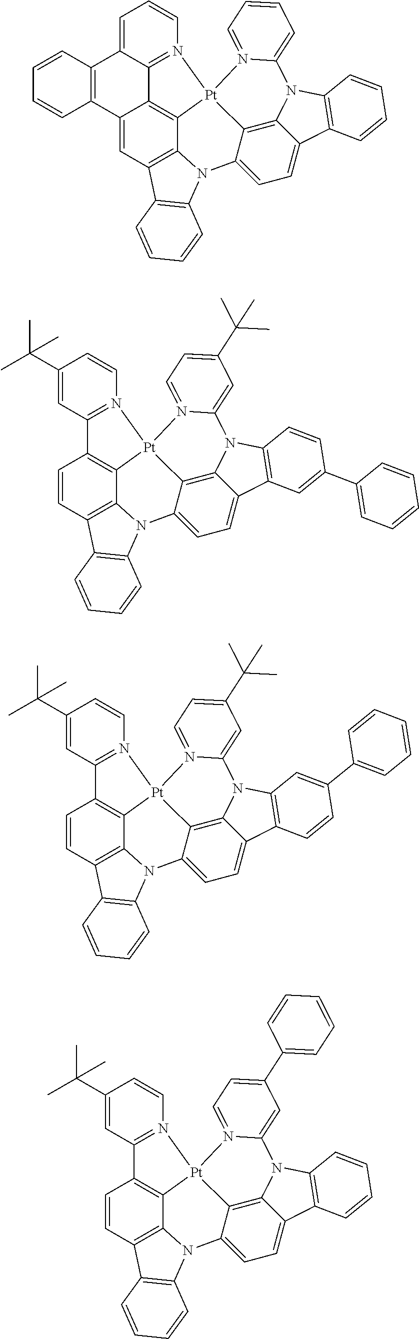

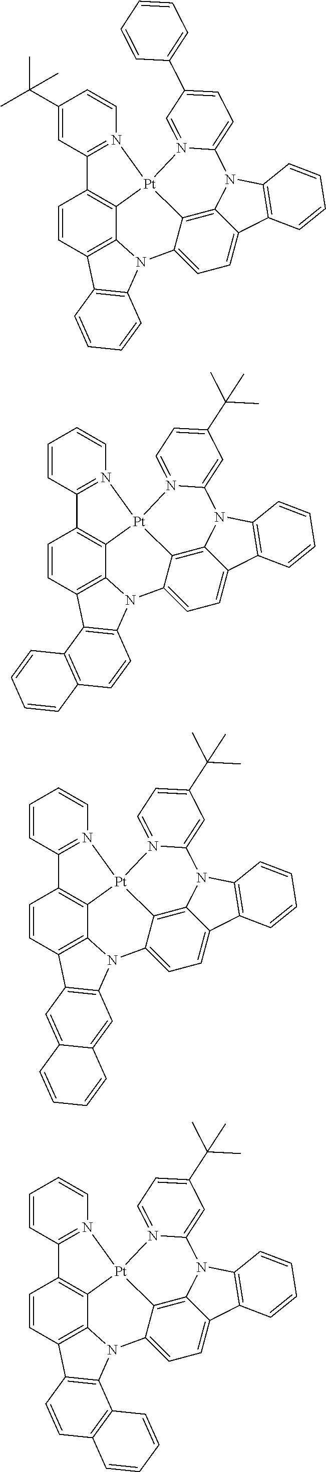

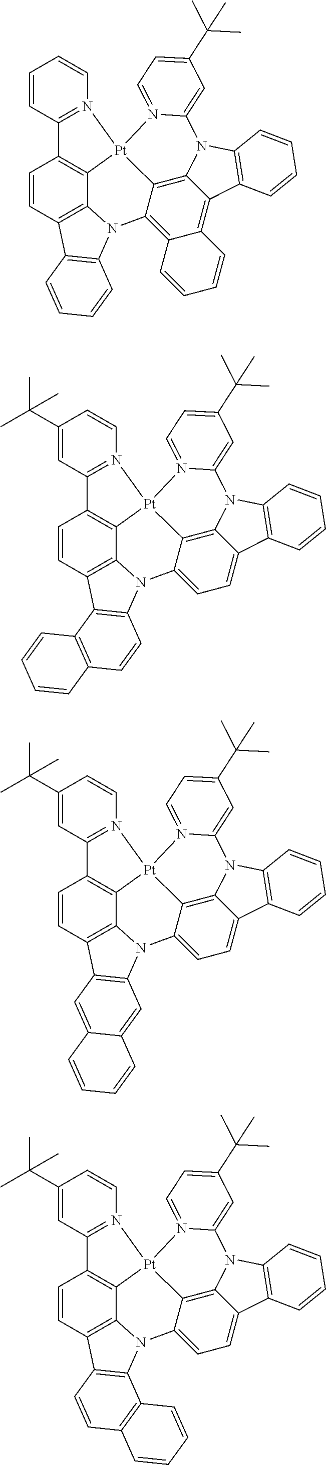

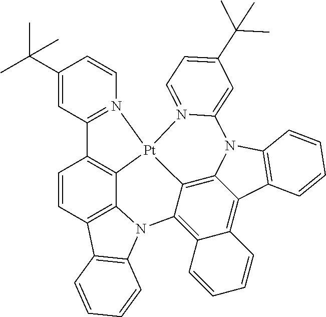

The above phosphorescent materials (phosphorescent compounds) may be used alone or in combination of two or more thereof.

The phosphorescent material may include at least one selected from the above phosphorescent materials (phosphorescent compounds). In one or more embodiments, the phosphorescent material may be at least one compound selected from the above phosphorescent materials (phosphorescent compounds).

The relationship between the amount of the boron compound represented by Formula 1 and the amount of the phosphorescent material is not particularly limited. The amount of the phosphorescent material in the composition for an organic EL device may be about 100 parts by weight or more, about 300 parts by weight or more, or about 500 parts by weight or more, based on 100 parts by weight of the boron compound represented by Formula 1. The amount of the phosphorescent material in the composition for an organic EL device may be about 10,000 parts by weight or less, about 5,000 parts by weight or less, or about 2,000 parts by weight or less, based on 100 parts by weight of the boron compound represented by Formula 1. The amount of the phosphorescent material in the composition for an organic EL device is not particularly limited, but may be about 100 parts by weight to about 10,000 parts by weight, about 300 parts by weight to about 5,000 parts by weight, or about 500 parts by weight to about 2,000 parts by weight, based on 100 parts by weight of the boron compound represented by Formula 1. When two or more boron compounds are used, the amount of the boron compound represents the total amount of the two or more boron compounds represented by Formula 1. When two or more phosphorescent materials are used, the amount of the phosphorescent material represents the total amount of the two or more phosphorescent materials. When the amount of the phosphorescent material is within the above ranges, the color purity of luminescence may be further improved, and an organic EL device having higher luminescence efficiency and longer lifespan may be obtained.

The amount of the phosphorescent material in the composition for an organic EL device is not particularly limited, but may be about 1.0 wt % or more, about 5.0 wt % or more, or about 10.0 wt % or more, based on the total weight of the composition for an organic EL device. The amount of the phosphorescent material in the composition for an organic EL device is not particularly limited, but may be about 50.0 wt % or less, about 30.0 wt % or less, or about 20.0 wt % or less, based on the total weight of the composition for an organic EL device. The amount of the phosphorescent material in the composition for an organic EL device may be about 1.0 wt % to about 50.0 wt %, about 5.0 wt % to about 30.0 wt %, or about 10.0 wt % to about 20.0 wt %, based on the total weight of the composition for an organic EL device. When two or more phosphorescent materials are used, the amount of the phosphorescent material represents the total amount of the two or more phosphorescent materials. When the amount of the phosphorescent material is within the above ranges, the color purity of luminescence may be further improved, and an organic EL device having higher luminescence efficiency and longer lifespan may be obtained.

### Optional Component

The composition for an organic EL device according to one or more embodiments may or may not further include an optional component. In this regard, the term “optional component” refers to a component other than the boron-based compound described above and the phosphorescent material described herein. The optional component is not particularly limited, but may be a known material. For example, as other materials used in an organic EL device, materials constituting each layer in the below description of the organic EL device may be used. The optional component may include, among the materials constituting each layer, at least one of a dopant material or a host material mentioned in the below description of the emission layer of the organic EL device. In addition, the optional component may be at least one material that is a thermally activated delayed fluorescence (TADF) material (TADF compound) or a host material mentioned in the below description of the emission layer of the organic EL device. In addition, the optional component may include a host material, or a TADF material and a host material. In addition, the optional component may include a TADF material and a host material. In addition, the optional component may be a host material. In one or more embodiments, the composition for an organic EL device may include the boron compound represented by Formula 1, the phosphorescent material, and the host material.

The composition for an organic EL device according to one or more embodiments may further include a host material. The composition for an organic EL device according to one or more embodiments may consist of the boron compound represented by Formula 1, the phosphorescent material, and the host material. The host material may be used alone or in combination of two or more thereof. The host material is not particularly limited, and a known host material may be used. The host material may include at least one selected from host materials mentioned in the below description of the emission layer. In one or more embodiments, the host material may be at least one compound selected from host materials mentioned in the below description of the emission layer. The host material may include at least one compound selected from Compound HT1 and Compound HT2 described below. For example, the host material may include may include Compound HT1 and Compound HT2. In one or more embodiments, the host material may include at least one compound selected from Compound HT1 or Compound HT2, or may include Compound HT1 and Compound HT2.

When the composition for an organic EL device includes a host material, the relationship between the amount of the host material and the amount of the boron compound represented by Formula 1 is not particularly limited. The amount of the boron compound represented by Formula 1 in the composition for an organic EL device may be about 0.1 parts by weight or more, about 0.5 parts by weight or more, or about 1.0 parts by weight or more, based on 100 parts by weight of the host material. The amount of the boron compound represented by Formula 1 in the composition for an organic EL device may be about 10.0 parts by weight or less, about 5.0 parts by weight or less, or about 2.0 parts by weight or less, based on 100 parts by weight of the host material. For example, the amount of the boron compound represented by Formula 1 in the composition for an organic EL device may be about 0.1 parts by weight to about 10.0 parts by weight, about 0.5 parts by weight to about 10.0 parts by weight, or about 1.0 parts by weight to about 2.0 parts by weight, based on 100 parts by weight of the host material. When two or more host materials are used, the amount of the host material represents the total amount of the two or more host materials. When two or more boron compounds are used, the amount of the boron compound represents the total amount of the two or more boron compounds represented by Formula 1. When the amount of the boron compound represented by Formula 1 is within the above ranges, an organic EL device having superior color purity of luminescence, higher luminescence efficiency, and/or longer lifespan may be obtained.

When the composition for an organic EL device includes a host material, the relationship between the amount of the host material and the amount of the phosphorescent material is not particularly limited. The amount of the phosphorescent material in the composition for an organic EL device may be about 1.0 parts by weight or more, about 5.0 parts by weight or more, or about 10.0 parts by weight or more, based on 100 parts by weight of the host material. The amount of the phosphorescent material in the composition for an organic EL device may be about 50.0 parts by weight or less, about 30.0 parts by weight or less, or about 20.0 parts by weight or less, based on 100 parts by weight of the host material. For example, the amount of the phosphorescent material in the composition for an organic EL device may be about 1.0 parts by weight to about 50.0 parts by weight, about 5.0 parts by weight to about 30.0 parts by weight, or about 10.0 parts by weight to about 20.0 parts by weight, based on 100 parts by weight of the host material. When two or more host materials are used, the amount of the host material represents the total amount of the two or more host materials. When two or more phosphorescent materials are used, the amount of the phosphorescent material represents the total amount of the two or more phosphorescent materials. When the amount of the phosphorescent material is within the above ranges, an organic EL device having superior color purity of luminescence, higher luminescence efficiency, and/or longer lifespan may be obtained.

The amount of the host material in the composition for an organic EL device is not particularly limited, but may be about 10 parts by weight or more, about 100 parts by weight or more, or about 500 parts by weight or more, based on 100 parts by weight of the total weight of the boron compound represented by Formula 1 and the phosphorescent material. The amount of the host material in the composition for an organic EL device is not particularly limited, but may be about 10,000 parts by weight or less, about 5,000 parts by weight or less, or about 1,000 parts by weight or less, based on 100 parts by weight of the total weight of the boron compound represented by Formula 1 and the phosphorescent material. For example, the amount of the host material in the composition for an organic EL device may be about 10 parts by weight to about 10,000 parts by weight, about 100 parts by weight to about 5,000 parts by weight, or about 500 parts by weight to about 1,000 parts by weight, based on 100 parts by weight of the total weight of the boron compound represented by Formula 1 and the phosphorescent material. When two or more host materials are used, the amount of the host material represents the total amount of the two or more host materials. When two or more boron compounds are used, the amount of the boron compound represents the total amount of the two or more boron compounds represented by Formula 1. When two or more phosphorescent materials are used, the amount of the phosphorescent material represents the total amount of the two or more phosphorescent materials. When the amount of the host material is within the above ranges, an organic EL device having superior color purity of luminescence, higher luminescence efficiency, and/or longer lifespan may be obtained.

The amount of the host material in the composition for an organic EL device is not particularly limited, but may be about 10 wt % or more, about 50 wt % or more, or about 70 wt % or more, based on the total weight of the composition for an organic EL device. The amount of the host material in the composition for an organic EL device is not particularly limited, but may be about 99 wt % or less, about 95 wt % or less, or about 90 wt % or less, based on the total weight of the composition for an organic EL device. For example, the amount of the host material in the composition for an organic EL device may be about 10 wt % to about 99 wt %, about 50 wt % to about 95 wt %, or about 70 wt % to about 90 wt %, based on the total weight of the composition for an organic EL device. When two or more host materials are used, the amount of the host material represents the total amount of the two or more host materials. When the amount of the host material is within the above ranges, an organic EL device having superior color purity of luminescence, higher luminescence efficiency, and/or longer lifespan may be obtained.

The composition for an organic EL device may or may not further include at least one material selected from a dopant material or a TADF material. As the dopant material, a known material may be used. The dopant material may be used alone or in combination of two or more thereof. The composition for an organic EL device according to one or more embodiments may include at least one compound selected from dopant materials mentioned in the below description of the emission layer. As the TADF material, a known material may be used. The TADF material may be used alone or in combination of two or more thereof. The composition for an organic EL device according to one or more embodiments may include at least one compound selected from TADF materials mentioned in the below description of the emission layer.

The composition for an organic EL device may or may not further include a solvent. In one or more embodiments, the composition for an organic EL device may be a solution-phase material further including a solvent. The composition for an organic EL device may be substantially free of a solvent. In this regard, the expression “substantially free of a solvent” means that the amount of the solvent in the composition for an organic EL device is less than about 1 wt % based on the total weight of the composition for an organic EL device (wherein the lower limit is 0 wt %). In one or more embodiments, the composition for an organic EL device may be free of a solvent. That is, the amount of the solvent in the composition for an organic EL device may be 0 wt % based on the total weight of the composition for an organic EL device.

The use of the composition for an organic EL device is not particularly limited, but the composition may be a material for an emission layer.

### Organic EL Device

Another aspect provides an organic EL device having an organic layer including the composition for an organic EL device. Such an organic EL device may achieve high luminescence efficiency and long lifespan.

The layer including the composition for an organic EL device may include one or more layers including an emission layer. In one or more embodiments, the layer including the composition for an organic EL device may be an emission layer. The organic EL device according to one or more embodiments may also be referred to as an organic EL device having a layer including the boron compound represented by Formula 1 as described herein and the phosphorescent material as described herein. The layer including the boron compound represented by Formula 1 and the phosphorescent material may include one or more layers including an emission layer. In one or more embodiments, the layer including the boron compound represented by Formula 1 and the phosphorescent material may be an emission layer.

In one or more embodiments, a means for realizing a narrow FWHM of the emission peak in an organic EL device and improving the luminescence efficiency and lifespan of the organic EL device may be provided. In addition, the organic EL device may exhibit a blue luminescence.

Hereinafter, exemplary embodiments are described with reference to the accompanying drawings to explain certain aspects and features. In addition, in the description of the drawings, the same components are denoted by the same reference numerals, and redundant descriptions thereof are omitted. In addition, the dimension ratio in the drawings may be exaggerated for convenience of description, and may differ from the actual ratio.

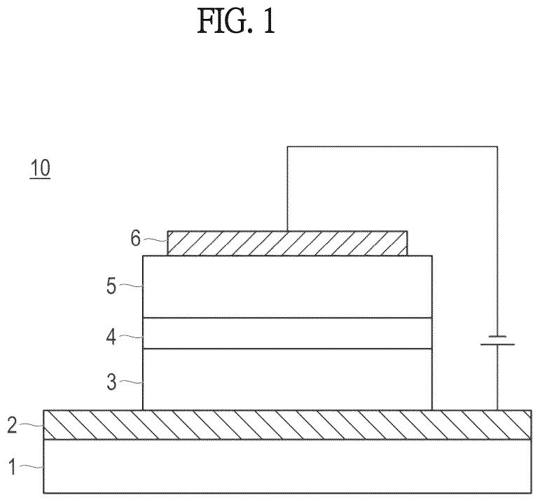

Hereinafter, an organic EL device according to one or more embodiments is described in further detail with reference to the drawings. FIGS. 1 to 3 are each a schematic view of the organic EL device according one or more embodiments. However, the structure of the organic EL device according to the disclosure is not limited to the embodiments illustrated in FIGS. 1 to 3.

FIG. 1 is a schematic cross-sectional view of an organic EL device 10 according to one or more embodiments. The organic EL device 10 according to one or more embodiments may include a substrate 1, a first electrode 2, a hole transport region 3, an emission layer 4, an electron transport region 5, and a second electrode 6, which are sequentially stacked in the stated order.

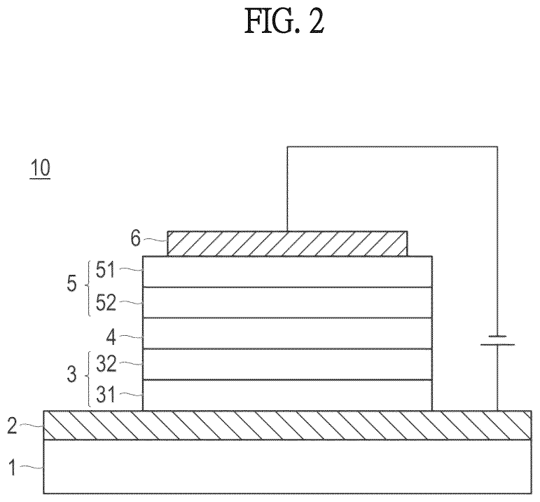

FIG. 2 is a schematic cross-sectional view of the organic EL device 10 according to another exemplary embodiment. The organic EL device 10 according to one or more embodiments may include the substrate 1, the first electrode 2, the hole transport region 3, the emission layer 4, the electron transport region 5, and the second electrode 6, which are sequentially stacked in the stated order. In FIG. 2, the hole transport region 3 may include a hole injection layer 31 and a hole transport layer 32, which are sequentially stacked in the stated order. In addition, in FIG. 2, the electron transport region 5 may include an electron transport layer 52 and an electron injection layer 51, which are sequentially stacked in the stated order.

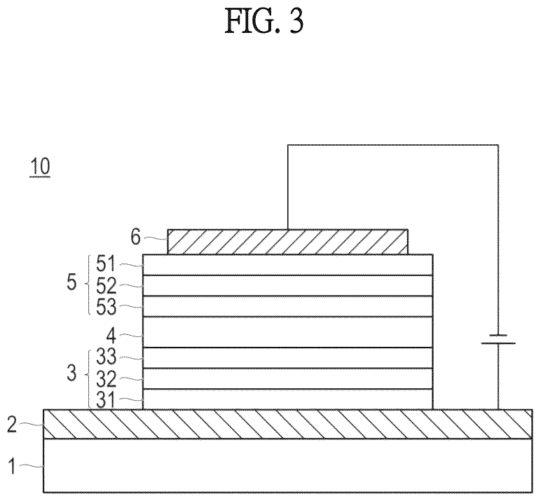

FIG. 3 is a schematic cross-sectional view of the organic EL device 10 according to another exemplary embodiment. The organic EL device 10 according to one or more embodiments may include the substrate 1, the first electrode 2, the hole transport region 3, the emission layer 4, the electron transport region 5, and the second electrode 6, which are sequentially stacked in the stated order. In FIG. 3, the hole transport region 3 may include the hole injection layer 31, the hole transport layer 32, and an electron-blocking layer 33, which are sequentially stacked in the stated order. In addition, in FIG. 3, the electron transport region 5 may include a hole-blocking layer 53, the electron transport layer 52, and the electron injection layer 51, which are sequentially stacked in the stated order.

The composition for an organic EL device may be included in, for example, an organic layer arranged between the first electrode 2 and the second electrode 6. Examples of the layer including the composition for an organic EL device are not particularly limited, but may include the hole injection layer 31, the hole transport layer 32, the emission layer 4, the electron transport layer 52, and the electron injection layer 51. In one or more embodiments, the composition for an organic EL device may be included in the emission layer 4.

One or more embodiments may include, for example, an organic EL device including a first electrode, a second electrode, and a single emission layer or a plurality of emission layers. The second electrode may be arranged on the first electrode.

As used herein, when a portion of a layer, film, region, or plate is referred to as being “on” or “above” another portion, this includes not only a case where the portion is “directly on” the other portion, but also a case where an intervening layer is present therebetween. In contrast, when a portion of a layer, film, region, or plate is referred to as being “under” or “below” another portion, this includes not only a case where the portion is “directly under” the other portion, but also a case where an intervening layer is present therebetween. In addition, as used herein, the term “arranged on” includes not only being arranged on an upper surface but also being arranged on a lower or bottom surface.

As described above, the composition for an organic EL device according to the disclosure may be included in an emission layer. That is, the organic layer may be an emission layer. Hereinafter, embodiments in which the composition for an organic EL device of the disclosure is included in the emission layer are described. However, the disclosure is not limited to the following exemplary embodiments.

### Emission Layer

The configuration of the emission layer is not particularly limited. The emission layer may be a single layer including a single material, or a single layer including a plurality of different materials. In addition, the emission layer may have: a multi-layer structure including two or more layers including a single material; a multi-layer structure including two or more layers including a plurality of different materials; or a multi-layer structure including one or more layers including a single material and one or more layers including a plurality of different materials.

The emission layer may consist of the composition for an organic EL device. In one or more embodiments, the emission layer may consist only of a boron compound represented by Formula 1, a phosphorescent material, and a host material.

The amount of the boron compound represented by Formula 1 in the emission layer is not particularly limited, but may be about 0.1 wt % or more, about 0.5 wt % or more, or about 1.0 wt % or more, based on the total weight of the emission layer. The amount of the boron compound represented by Formula 1 in the emission layer is not particularly limited, but may be about 10.0 wt % or less, about 5.0 wt % or less, or about 2.0 wt % or less, based on the total weight of the emission layer. For example, the amount of the boron compound represented by Formula 1 in the emission layer may be about 0.1 wt % to about 10.0 wt %, about 0.5 wt % to about 5.0 wt %, or about 1.0 wt % to about 2.0 wt %, based on the total weight of the emission layer. When two or more boron compounds represented by Formula 1 are used, the amount of the boron compound represents the total amount of the two or more boron compounds represented by Formula 1. When the amount of the boron compound represented by Formula 1 is within the above ranges, an organic EL device having superior color purity of luminescence, higher luminescence efficiency, and/or longer lifespan may be obtained.

The relationship between the amount of the boron compound represented by Formula 1 and the amount of the phosphorescent material is not particularly limited. The amount of the phosphorescent material in the emission layer may be about 100 parts by weight or more, about 300 parts by weight or more, or about 500 parts by weight or more, based on 100 parts by weight of the boron compound represented by Formula 1. The amount of the phosphorescent material in the emission layer may be about 10,000 parts by weight or less, about 5,000 parts by weight or less, or about 2,000 parts by weight or less, based on 100 parts by weight of the boron compound represented by Formula 1. The amount of the phosphorescent material in the emission layer is not particularly limited, but may be about 100 parts by weight to about 10,000 parts by weight, about 300 parts by weight to about 5,000 parts by weight, or about 500 parts by weight to about 2,000 parts by weight, based on 100 parts by weight of the boron compound represented by Formula 1. When two or more boron compounds represented by Formula 1 are used, the amount of the boron compound represents the total amount of the two or more boron compounds represented by Formula 1. When two or more phosphorescent materials are used, the amount of the phosphorescent material represents the total amount of the two or more phosphorescent materials. When the amount of the phosphorescent material is within the above ranges, an organic EL device having superior color purity of luminescence, higher luminescence efficiency, and/or longer lifespan may be obtained.

The amount of the phosphorescent material in the emission layer is not particularly limited, but may be about 1.0 wt % or more, about 5.0 wt % or more, or about 10.0 wt % or more, based on the total weight of the emission layer. The amount of the phosphorescent material in the emission layer is not particularly limited, but may be about 50.0 wt % or less, about 30.0 wt % or less, or about 20.0 wt % or less, based on the total weight of the emission layer. For example, the amount of the phosphorescent material in the emission layer may be about 1.0 wt % to about 50.0 wt %, about 5.0 wt % to about 30.0 wt %, or about 10.0 wt % to about 20.0 wt %, based on the total weight of the emission layer. When two or more phosphorescent materials are used, the amount of the phosphorescent material represents the total amount of the two or more phosphorescent materials. When the amount of the phosphorescent material is within the above ranges, an organic EL device having superior color purity of luminescence, higher luminescence efficiency, and/or longer lifespan may be obtained.

The emission layer may or may not further include an optional component. In this regard, the term “optional component” refers to a component other than the boron compound represented by Formula 1 described herein and the phosphorescent material described herein. The optional component is not particularly limited, but may be a known material. Examples of the optional component may include a host material, a dopant material, and/or a TADF material (a TADF compound). The optional component may be used alone or in combination of two or more thereof. The optional component may include at least one material that is a host material, a dopant material, or a TADF material. For example, the optional component may include a host material. In one or more embodiments, the optional component may be at least one material that is a host material, a dopant material, or a TADF material. For example, the optional component may be a host material.

The emission layer is not particularly limited, but may include, for example, a known material used in an emission layer, in addition to the boron compound represented by Formula 1 and the phosphorescent material. The emission layer may include, for example, an anthracene derivative, a pyrene derivative, a fluoranthene derivative, a chrysene derivative, a dihydrobenzanthracene derivative, or a triphenylene derivative, in addition to the boron compound represented by Formula 1 and the phosphorescent material. In some embodiments, the emission layer may not include at least one compound that is, for example, an anthracene derivative, a pyrene derivative, a fluoranthene derivative, a chrysene derivative, a dihydrobenzanthracene derivative, or a triphenylene derivative.

The emission layer may or may not include a TADF material. The term “thermally activated delayed fluorescence” (TADF) refers to a phenomenon in which reverse intersystem crossing occurs from a triplet exciton to a singlet exciton in a compound having a small energy difference (ΔEst) between a singlet level and a triplet level. The term “TADF material” refers to a material in which such a phenomenon occurs. As the TADF material, a known material may be used.

Non-limiting examples of the TADF material may include the following compounds.

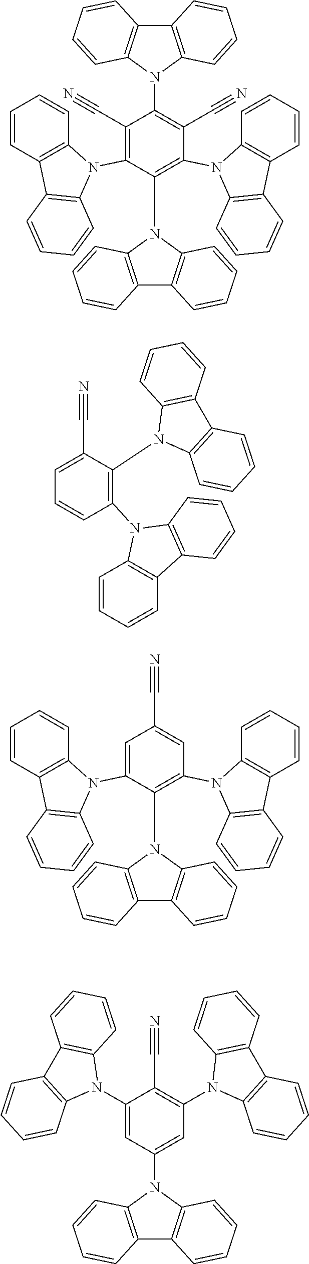

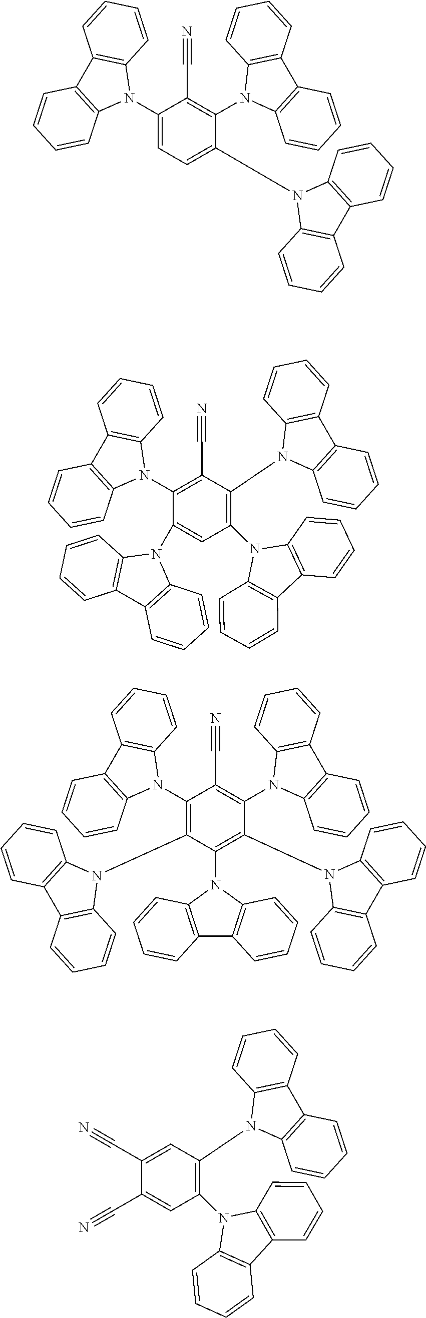 [SMILES: N#Cc1c(-n2c3ccccc3c3ccccc32)ccc(-n2c3ccccc3c3ccccc32)c1-n1c2ccccc2c2ccccc21 ; N#Cc1c(-n2c3ccccc3c3ccccc32)c(-n2c3ccccc3c3ccccc32)cc(-n2c3ccccc3c3ccccc32)c1-n1c2ccccc2c2ccccc21 ; N#Cc1c(-n2c3ccccc3c3ccccc32)c(-n2c3ccccc3c3ccccc32)c(-n2c3ccccc3c3ccccc32)c(-n2c3ccccc3c3ccccc32)c1-n1c2ccccc2c2ccccc21 ; N#Cc1cc(-n2c3ccccc3c3ccccc32)c(-n2c3ccccc3c3ccccc32)cc1C#N]

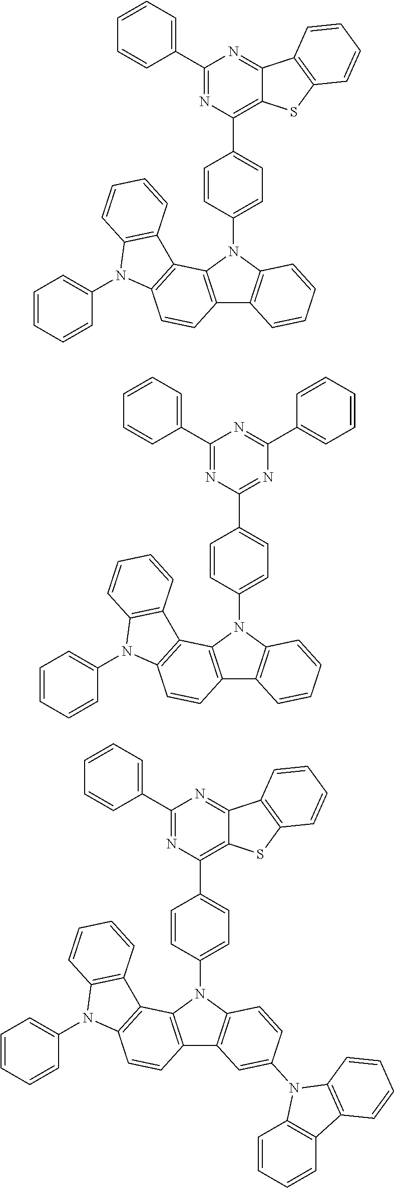

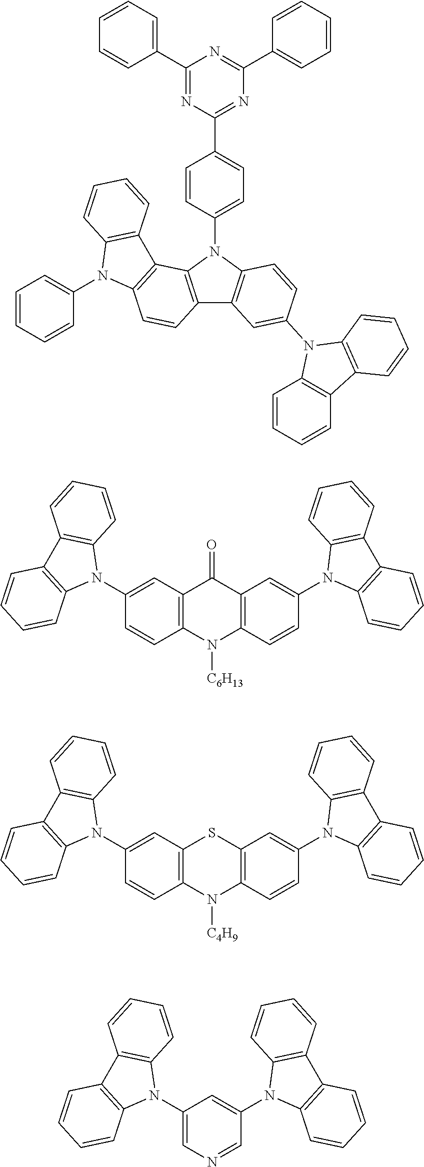

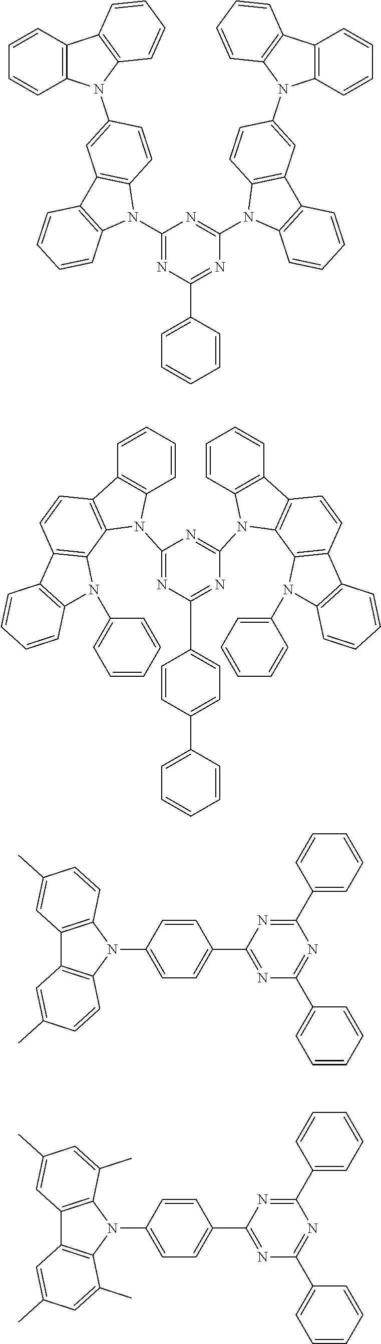 [SMILES: c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; Cc1ccc2c(c1)c1cc(C)ccc1n2-c1ccc(-c2nc(-c3ccccc3)nc(-c3ccccc3)n2)cc1 ; Cc1cc(C)c2c(c1)c1cc(C)cc(C)c1n2-c1ccc(-c2nc(-c3ccccc3)nc(-c3ccccc3)n2)cc1]

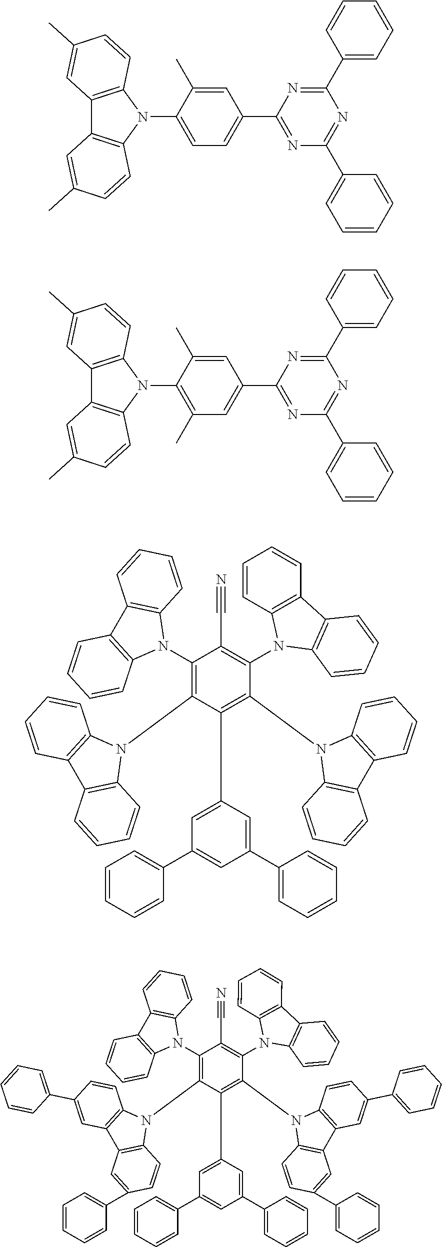

The above TADF materials may be used alone or in combination of two or more thereof.

The amount of the TADF material based on the total weight of the emission layer is not particularly limited, but may be about 0.1 wt % or more. In addition, the amount of the TADF material may be about 0.5 wt % or more, or about 1 wt % or more. In addition, the amount of the TADF material may be about 3 wt % or more, or about 5 wt % or more.

In addition, the amount of the TADF material based on the total weight of the emission layer may be about 50 wt % or less. In addition, the amount may be about 40 wt % or less, or about 30 wt % or less. In addition, when the emission layer includes both a TADF material and a phosphorescent material, the total amount of the TADF material and the phosphorescent material may be within the above ranges. When the amount of the TADF material is within the above ranges, an organic EL device having superior color purity of luminescence, higher luminescence efficiency, and/or longer lifespan may be obtained.

When the emission layer includes a TADF material, the amount of the TADF material is not particularly limited, but may be about 100 parts by weight or more based on 100 parts by weight of the boron compound represented by Formula 1. In addition, the amount may be about 150 parts by weight or more, or about 200 parts by weight or more, based on 100 parts by weight of the boron compound represented by Formula 1. In addition, the amount of the TADF material may be about 10,000 parts by weight or less based on 100 parts by weight of the boron compound represented by Formula 1. In addition, the amount of the TADF material may be about 7,500 parts by weight or less, or about 5,000 parts by weight or less, based on 100 parts by weight of the boron compound represented by Formula 1. In addition, when the emission layer includes both a TADF material and a phosphorescent material, the total amount of the TADF material and the phosphorescent material combined may be within the above ranges. When the amount of the TADF material is within the above ranges, an organic EL device having superior color purity of luminescence, higher luminescence efficiency, and/or longer lifespan may be obtained.

The emission layer may or may not include a host material. For example, the emission layer may include a host material.

Examples of the host material are not particularly limited, but may include at least one of bis[2-(diphenylphosphino)phenyl]etheroxide (DPEPO), 4,4′-bis(carbazol-9-yl)biphenyl (CBP), 3,3′-bis(carbazol-9-yl)biphenyl (mCBP), 1,3-bis(carbazol-9-yl)benzene (mCP), 2,8-bis(diphenylphosphoryl)dibenzo[b,d]furan (PPF), 4,4′,4″-tris(carbazol-9-yl)triphenylamine (TcTa), or 1,3,5-tris(N-phenylbenzimidazol-2-yl)benzene (TPBi). However, embodiments are not limited thereto, and the emission layer may include, for example, tris(8-hydroxyquinolino)aluminum (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazol-2-yl)benzene (TPBi), 3-tert-butyl-9,10-di(naphtho-2-yl)anthracene (TBADN), distyrylarylene (DSA), 4,4′-bis(9-carbazolyl)-2,2′-dimethyl-biphenyl(CDBP), 2-methyl-9,10-bis(naphthalene-2-yl)anthracene (MADN), bis[2-(diphenylphosphino)phenyl]etheroxide (DPEPO), hexaphenylcyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), or 2,8-bis(diphenylphosphoryl)dibenzofuran (PPF).

In addition, the emission layer may include, as the host material, a material having a highest occupied molecular orbital (HOMO) of about −5.2 electron volts (eV) or less. In addition, the emission layer may include, as the host material, a material having a lowest unoccupied molecular orbital (LUMO) of about −1.4 eV or less. By using a host material having low HOMO and LUMO and high electron transport properties, the driving durability in an organic EL device (for example, a blue organic EL device) may be improved. Such a material is not particularly limited, but an example thereof may be a compound represented by Formula A, which is disclosed in “An Alternative Host Material for Long-Lifespan Blue Organic Light-Emitting Diodes Using Thermally Activated Delayed Fluorescence,” Soo-Ghang Ihn, Namheon Lee, Soon Ok Jeon, Myungsun Sim, Hosuk Kang, Yongsik Jung, Dal Ho Huh, Young Mok Son, Sae Youn Lee, Masaki Numata, Hiroshi Miyazaki, Rafael Gómez-Bombarelli, Jorge Aguilera-Iparraguirre, Timothy Hirzel, Alan Aspuru-Guzik, Sunghan Kim, and Sangyoon Lee, Advanced Science News 2017, 4, 1600502. When the emission layer is formed in combination with such a host material, a blue luminescent material in the related art may become a deep hole trap, thereby causing undesirable effects such as an increase in driving voltage. Meanwhile, and without wishing to be bound to theory, the boron compound represented by Formula 1 has weak hole-trapping properties, and thus is expected to suppress the occurrence of an increase in driving voltage.

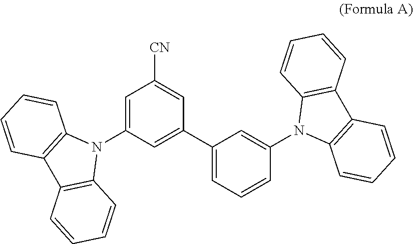 [SMILES: N#Cc1cc(-c2cccc(-n3c4ccccc4c4ccccc43)c2)cc(-n2c3ccccc3c3ccccc32)c1]

In addition, the emission layer may include, as the host material, at least one of the following compounds, but embodiments are not limited thereto.

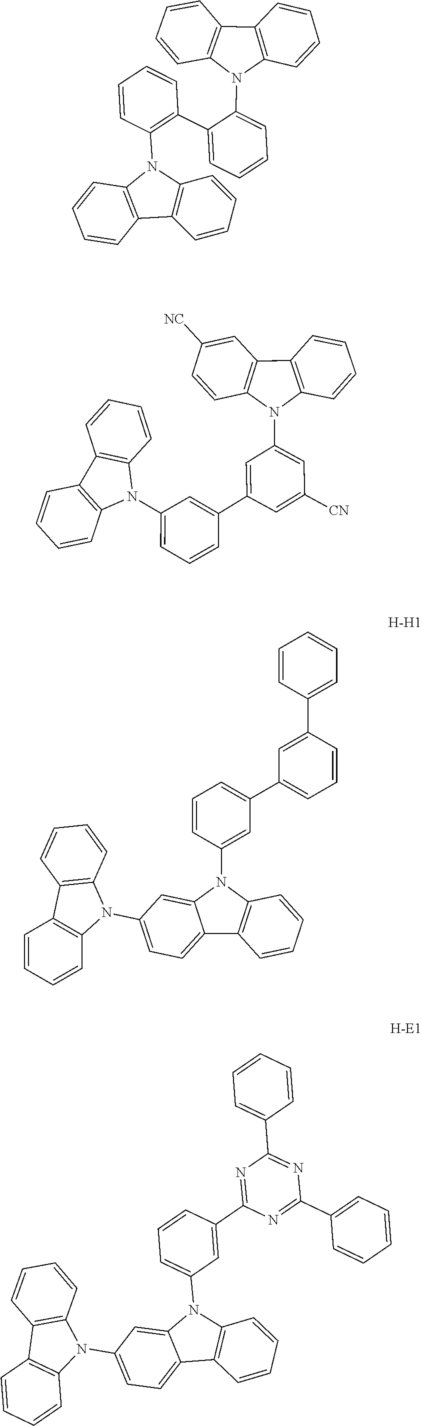 [SMILES: c1ccc(-n2c3ccccc3c3ccccc32)c(-c2ccccc2-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; c1ccc(-c2cccc(-c3cccc(-n4c5ccccc5c5ccc(-n6c7ccccc7c7ccccc76)cc54)c3)c2)cc1 ; c1ccc(-c2nc(-c3ccccc3)nc(-c3cccc(-n4c5ccccc5c5ccc(-n6c7ccccc7c7ccccc76)cc54)c3)n2)cc1]

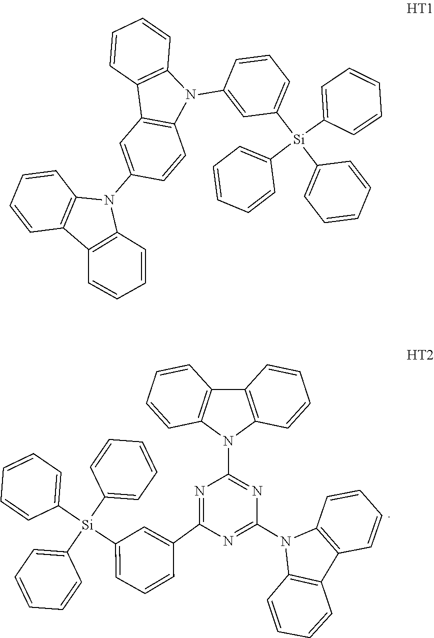 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

In one or more embodiments, among the above compounds, the emission layer may include, as the host material, at least one of Compound HT1 or Compound HT2. For example, the emission layer may include, as the host material, both Compound HT1 and Compound HT2.

When the emission layer includes a host material, the relationship between the amount of the host material and the amount of the boron compound represented by Formula 1 is not particularly limited. The amount of the boron compound represented by Formula 1 in the emission layer may be about 0.1 parts by weight or more, about 0.5 parts by weight or more, or about 1.0 parts by weight or more, based on 100 parts by weight of the host material. The amount of the boron compound represented by Formula 1 in the emission layer may be about 10.0 parts by weight or less, about 5.0 parts by weight or less, or about 2.0 parts by weight or less, based on 100 parts by weight of the host material. For example, the amount of the boron compound represented by Formula 1 in the emission layer may be about 0.1 parts by weight to about 10.0 parts by weight, about 0.5 parts by weight to about 10.0 parts by weight, or about 1.0 parts by weight to about 2.0 parts by weight, based on 100 parts by weight of the host material. When two or more host materials are used, the amount of the host material represents the total amount of the two or more host materials. When two or more boron compounds represented by Formula 1 are used, the amount of the boron compound represents the total amount of the two or more boron compounds represented by Formula 1. When the amount of the boron compound represented by Formula 1 is within the above ranges, an organic EL device having superior color purity of luminescence, higher luminescence efficiency, and/or longer lifespan may be obtained.

When the emission layer includes a host material, the relationship between the amount of the host material and the amount of the phosphorescent material is not particularly limited. The amount of the phosphorescent material in the emission layer may be about 1.0 parts by weight or more, about 5.0 parts by weight or more, or about 10.0 parts by weight or more, based on 100 parts by weight of the host material. The amount of the phosphorescent material in the emission layer may be about 50.0 parts by weight or less, about 30.0 parts by weight or less, or about 20.0 parts by weight or less, based on 100 parts by weight of the host material. For example, the amount of the phosphorescent material in the emission layer may be about 1.0 parts by weight to about 100.0 parts by weight, about 5.0 parts by weight to about 50.0 parts by weight, or about 10.0 parts by weight to about 20.0 parts by weight, based on 100 parts by weight of the host material. When two or more host materials are used, the amount of the host material represents the total amount of the two or more host materials. When two or more phosphorescent materials are used, the amount of the phosphorescent material represents the total amount of the two or more phosphorescent materials. When the amount of the phosphorescent material is within the above ranges, an organic EL device having superior color purity of luminescence, higher luminescence efficiency, and/or longer lifespan may be obtained.

The amount of the host material in the emission layer is not particularly limited, but may be about 10 parts by weight or more, about 100 parts by weight or more, or about 500 parts by weight or more, based on 100 parts by weight of the total weight of the boron compound represented by Formula 1 and the phosphorescent material in the emission layer. The amount of the host material in the emission layer is not particularly limited, but may be about 10,000 parts by weight or less, about 5,000 parts by weight or less, or about 1,000 parts by weight or less, based on 100 parts by weight of the total weight of the boron compound represented by Formula 1 and the phosphorescent material in the emission layer. For example, the amount of the host material in the emission layer may be about 10 parts by weight to about 10,000 parts by weight, about 100 parts by weight to about 5,000 parts by weight, or about 500 parts by weight to about 1,000 parts by weight, based on 100 parts by weight of the total weight of the boron compound represented by Formula 1 and the phosphorescent material in the emission layer. When two or more host materials are used, the amount of the host material represents the total amount of the two or more host materials. When two or more boron compounds represented by Formula 1 are used, the amount of the boron compound represents the total amount of the two or more boron compounds represented by Formula 1. When two or more phosphorescent materials are used, the amount of the phosphorescent material represents the total amount of the two or more phosphorescent materials. When the amount of the host material is within the above ranges, an organic EL device having superior color purity of luminescence, higher luminescence efficiency, and/or longer lifespan may be obtained.

The amount of the host material in the emission layer is not particularly limited, but may be about 10 wt % or more, about 50 wt % or more, or about 70 wt % or more, based on the total weight of the emission layer. The amount of the host material in the emission layer is not particularly limited, but may be about 99 wt % or less, about 95 wt % or less, or about 90 wt % or less, based on the total weight of the emission layer. For example, the amount of the host material in the emission layer may be about 10 wt % to about 99 wt %, about 50 wt % to about 95 wt %, or about 70 wt % to about 90 wt %, based on the total weight of the emission layer. When two or more host materials are used, the amount of the host material represents the total amount of the two or more host materials. When the amount of the host material is within the above ranges, an organic EL device having superior color purity of luminescence, higher luminescence efficiency, and/or longer lifespan may be obtained.

The emission layer may or may not include a known dopant material. Examples of the known dopant material are not particularly limited, but may include at least one of a styryl derivative (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), or N-(4-((E)-2-(6-((E)-4-(diphenylamino)styryl) naphthalen-2-yl)vinyl)phenyl)-N-phenylbenzenamine (N-BDAVBi)), perylene, a perylene derivative (for example, 2,5,8,11-tetra-tert-butylperylene (TBP)), pyrene, or a pyrene derivative (for example, 1,1-dipyrene, 1,4-dipyrenylbenzene, or 1,4-bis(N,N-diphenylamino)pyrene).

When the emission layer includes the boron compound represented by Formula 1 and the phosphorescent material, the luminescence efficiency and device lifespan of the organic EL device may be significantly improved. Without wishing to be limited to theory, the reason is speculated as below.

In an emission layer of an organic EL device, singlet excitons and triplet excitons are generated at a ratio of 1:3 by recombination of holes and electrons. In addition, in a device including only a fluorescent material as a luminescent material, only singlet excitons are involved in light emission, whereas in a device including a phosphorescent material as a luminescent material, both singlet excitons and triplet excitons may be used for light emission. Accordingly, the luminescence efficiency of the device including the phosphorescent material as a luminescent material may be significantly improved. Meanwhile, excitons generated on the phosphorescent material generally have a long lifespan of 1 μs or more. The excitons are in an unstable state with high energy. Accordingly, while the excitons are present, material deterioration may occur, resulting in a decrease in device lifespan. When a phosphorescent material is present in addition to the boron compound represented by Formula 1 in the emission layer, excitons are generated with high efficiency on the phosphorescent material. In addition, energy is transferred from the excitons to the boron compound represented by Formula 1 through Forster energy transfer. As a result, highly efficient fluorescence may be obtained from the boron compound represented by Formula 1, and the time for which excitons are present on the phosphorescent material may be shortened. Accordingly, the possibility of material deterioration may be significantly reduced, and the device lifespan may be significantly improved.

The emission layer may be a single layer including a single material, or a single layer including a plurality of different materials. In addition, the emission layer may have a multi-layer structure including a plurality of layers including a plurality of different materials.

The thickness of the emission layer is not particularly limited, but may be about 1 nanometer (nm) to about 100 nm, about 10 nm to about 60 nm, or about 30 nm to about 50 nm.

The emission wavelength of the emission layer (that is, the emission wavelength of the organic EL device including the emission layer) is not particularly limited. However, the peak wavelength of emission of the organic EL device may be about 360 nm to about 515 nm, about 380 nm to about 505 nm, about 400 nm to about 500 nm, about 420 nm to about 490 nm, about 430 nm to about 480 nm, or about 455 nm to about 475 nm. For example, the peak wavelength of emission of the organic EL device may be about 440 nm to about 470 nm, or greater than about 455 nm and less than or equal to about 470 nm. When the emission wavelength is within the above ranges, excellent luminescence, for example, excellent blue luminescence, may be obtained.

In addition, the FWHM of the emission spectrum of the organic EL device may be about 30 nm or less, about 25 nm or less, about 24 nm or less, about 23 nm or less, about 22 nm or less, about 22 nm or less, about 21 nm or less, or about 20 nm or less (wherein the lower limit is greater than 0 nm). When the FWHM is within the above ranges, luminescence with higher color purity may be obtained.

The FWHM of the organic EL device is defined as Wd (nm). In addition, the FWHM in PL of the toluene solution of the boron compound represented by Formula 1 at a concentration of 1×10⁻⁷ M is defined as Ws (nm). In addition, the value obtained by subtracting Ws from Wd is defined as ΔW2 (nm) (that is, ΔW2=Wd−Ws). When ΔW2 is 0 nm or more, ΔW2 is not particularly limited, but a smaller value thereof is desirable. When ΔW2 is 0 nm or more, ΔW2 may be 5 nm or less, 4 nm or less, 3 nm or less, or 2 nm or less.

The peak wavelength and spectral width (FWHM of the emission peak) of emission of the organic EL device may be measured using a luminance measuring device. Detailed measurement methods are as described in Examples.

Hereinafter, each region and each layer other than the emission layer 4 are described in further detail.

### Substrate 1

The organic EL device 10 may include the substrate 1. As the substrate 1, a substrate used in a general organic EL device may be used. For example, the substrate 1 may be a glass substrate, a silicon substrate, or a transparent plastic substrate, each having excellent mechanical strength, thermal stability, transparency, surface smoothness, ease of handling, and/or water repellency, but embodiments are not limited thereto.

### First Electrode 2

The first electrode 2 may be arranged on the substrate 1. The first electrode 2 may be an anode, and may include a material with a relatively high work function selected from a metal, an alloy, a conductive compound, or a combination thereof, for facilitating hole injection. The first electrode 2 may be a pixel electrode. The first electrode 2 may be a reflective electrode, a transflective electrode, or a transmissive electrode.

Materials for forming the first electrode 2 are not particularly limited. For example, when the first electrode 2 is a transparent electrode, the first electrode 2 may include indium tin oxide (ITO), indium zinc oxide (IZO), tin oxide (SnO₂), zinc oxide (ZnO), indium tin zinc oxide (ITZO), or a combination thereof, each having excellent transparency and conductivity. When the first electrode 2 is a transflective electrode or a reflective electrode, the first electrode 2 may include Ag, Mg, Cu, Al, Pt, Pd, Au, Ni, Nd, Ir, Cr, Li, Ca, In, LiF/Ca, LiF/Al, Mo, Ti, or a combination thereof (for example, a combination of Ag and Mg, or a combination of Mg and In).

The first electrode 2 may be a single layer including a single material, or a single layer including a plurality of different materials. In one or more embodiments, the first electrode 2 may have a multi-layer structure including a plurality of layers including various different materials.

The thickness of the first electrode 2 is not particularly limited, but may be about 10 nm to about 1,000 nm, or about 100 nm to about 300 nm.

### Hole Transport Region 3

The hole transport region 3 may be arranged on the first electrode 2.

The hole transport region 3 may include at least one of the hole injection layer 31, the hole transport layer 32, the electron-blocking layer 33, or a hole buffer layer (not shown).

The configuration of the hole transport region 3 is not particularly limited. The hole transport region 3 may be a single layer including a single material, or a single layer including a plurality of different materials. In addition, the hole transport region 3 may have a multi-layer structure including two or more layers including a single material; a multi-layer structure including two or more layers including a plurality of different materials; or a multi-layer structure including one or more layers including a single material and one or more layers including a plurality of different materials.

The hole transport region 3 may include only the hole injection layer 31 or only the hole transport layer 32. In one or more embodiments, the hole transport region 3 may be a single layer including a hole injection material and a hole transport material. The hole transport region 3 may have a hole injection layer/hole transport layer structure, a hole injection layer/hole buffer layer structure, a hole injection layer/hole transport layer/hole buffer layer structure, or a hole injection layer/hole transport layer/electron-blocking layer structure, wherein constituent layers of each structure are sequentially stacked from the first electrode 2 in the stated order.

For example, the hole transport region 3 may have a hole injection layer 31/hole transport layer 32/hole buffer layer (not shown) structure. For example, the hole transport region 3 may have a hole injection layer 31/hole buffer layer (not shown) structure, wherein constituent layers are sequentially stacked from the first electrode 2 in the stated order. For example, the hole transport region 3 may have a hole transport layer 32/hole buffer layer (not shown) structure, wherein constituent layers are sequentially stacked from the first electrode 2 in the stated order. For example, the hole transport region 3 may have a hole injection layer 31/hole transport layer 32/electron-blocking layer 33 structure, wherein constituent layers are sequentially stacked from the first electrode 2 in the stated order. However, the structure of the hole transport region 3 is not limited to the above configurations.

Layers forming the hole injection layer 31 and other layers included in the hole transport region 3 are not particularly limited, and a known hole injection material and/or a hole transport material may be included.

Non-limiting examples of the hole injection material may include at least one of a phthalocyanine compound such as copper phthalocyanine, N,N′-diphenyl-N, N′-bis-[4-phenyl-m-tolyl-amino)-phenyl]-biphenyl-4,4′-diamine (DNTPD), (4,4′,4″-tris(3-methylphenylphenylamino)triphenylamine) (m-MTDATA), 4,4′,4″-tris(N,N-diphenylamino)triphenylamine (TDATA), 4,4′,4″-tris{N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), polyetherketone including triphenylamine (TPAPEK), 4-isopropyl-4′-methyldiphenyliodonium tetrakis(pentafluorophenyl)borate, dipyrazino[2,3-f:2′,3′-h]quinoxaline-2,3,6,7,10,11-hexacarbonitrile (HAT-CN), or 1,3,4,5,7,8-hexafluorotetracyano-2,6-naphthoquinodimethane (F6-TCNNQ), but embodiments are not limited thereto.

Non-limiting examples of the hole transport material may include at least one of N-phenylcarbazole, a carbazole derivative such as polyvinyl carbazole, a fluorene derivative, N,N′-bis(3-methylphenyl)-N,N′-diphenyl-[1,1-biphenyl]-4,4′-diamine (TPD), a triphenylamine derivative such as 4,4′,4″-tris(N-carbazolyl)triphenylamine (TCTA), N,N′-di(naphthalen-1-yl)-N,N′-diphenyl-benzidine (NPB), 4,4′-cyclohexylidenebis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP), Compound H1, Compound H2, or Compound HT3, but embodiments are not limited thereto.

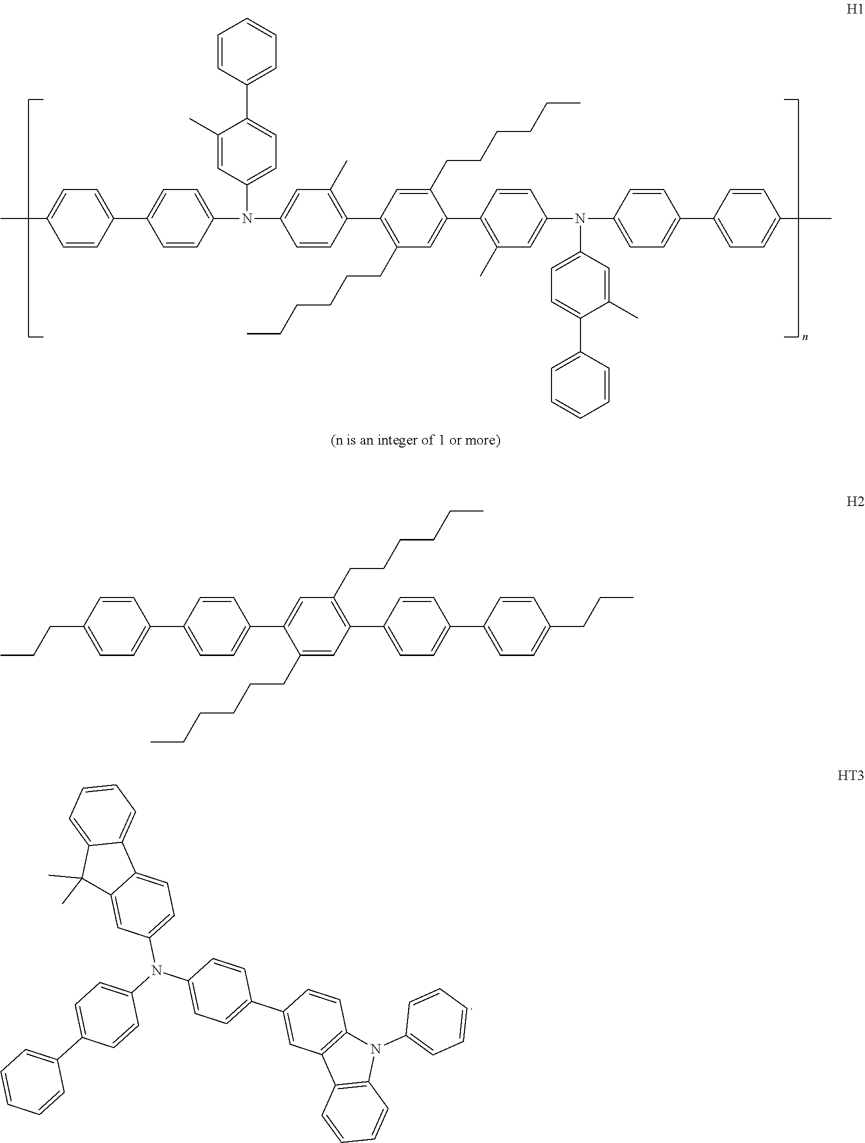

The hole transport region 3 may include, in addition to the materials described above, a charge-generating material to improve conductivity. The charge-generating material may be homogeneously or non-homogeneously dispersed in the hole transport region 3.

The charge-generating material is not particularly limited, but may be, for example, a p-dopant. Examples of the p-dopant may include: a quinone derivative, such as tetracyanoquinodimethane (TCNQ) or 2,3,5,6-tetrafluoro-tetracyano-1,4-benzoquinonedimethane (F4-TCNQ); a metal oxide, such as tungsten oxide or molybdenum oxide; or a cyano group-containing compound, but embodiments are not limited thereto.

The hole buffer layer (not shown) may increase luminescence efficiency by compensating for an optical resonance distance according to the wavelength of light emitted by the emission layer 4. Materials included in the hole buffer layer (not shown) are not particularly limited, and a known hole buffer layer material may be used. For example, the compounds included in the hole transport region 3 may be used.

The electron-blocking layer 33 may prevent injection of electrons from the electron transport region 5 to the hole transport region 3. Materials included in the electron-blocking layer 33 are not particularly limited, and a known electron-blocking layer material may be used. For example, the host materials included in the emission layer and Compounds H-H1 and HT1 as host materials may be included.

The thickness of the hole transport region 3 is not particularly limited, but may be about 1 nm to about 1,000 nm, or for example, about 10 nm to about 500 nm. In addition, the thickness of the hole injection layer 31 is not particularly limited and may be about 3 nm or greater and about 100 nm or lower. The thickness of the hole transport layer 32 is not particularly limited, but may be about 3 nm to about 200 nm, for example, about 3 nm to about 150 nm. The thickness of the electron-blocking layer 33 is not particularly limited, but may be about 1 nm to about 100 nm. In addition, the thickness of the hole buffer layer (not shown) is not particularly limited, as long as the hole buffer layer functions as a hole buffer layer and does not interfere with functions of an organic EL device. When the thickness of the hole transport region 3, the hole injection layer 31, the hole transport layer 32, or the electron-blocking layer 33 is within the above ranges, improved hole transport characteristics may be obtained without a substantial increase in driving voltage.

### Emission Layer 4

The emission layer 4 may be arranged on the hole transport region 3. A detailed description of the emission layer 4 is as provided herein.

### Electron Transport Region 5

The electron transport region 5 may be arranged on the emission layer 4. The electron transport region 5 may include at least one of the hole-blocking layer 53, the electron transport layer 52, or the electron injection layer 51.

The electron transport region 5 may be a single layer including a single material, or a single layer including a plurality of different materials. In one or more embodiments, the electron transport region 5 may have a multi-layer structure including a plurality of layers including a plurality of different materials.

The configuration of the electron transport region 5 is not particularly limited. The electron transport region 5 may be a single layer including a single material, or a single layer including a plurality of different materials. In addition, the electron transport region 5 may have a multi-layer structure including two or more layers including a single material; a multi-layer structure including two or more layers including a plurality of different materials; or a multi-layer structure including one or more layers including a single material and one or more layers including a plurality of different materials. For example, the electron transport region 5 may have a single-layer structure including the electron injection layer 51 or the electron transport layer 52. For example, the electron transport region 5 may have a single-layer structure including an electron injection material and an electron transport material. For example, the electron transport region 5 may have an electron transport layer 52/electron injection layer 51 structure, wherein constituent layers are sequentially stacked in the stated order from the emission layer 4. For example, the electron transport region 5 may have a hole-blocking layer 53/electron transport layer 52/electron injection layer 51 structure, wherein constituent layers are sequentially stacked in the stated order from the emission layer 4. However, the structure of the electron transport region 5 is not limited to the above described examples.

The electron injection layer 51 is not particularly limited, but may include, for example, a known electron injection material. Examples of the electron injection material may include lithium quinolate (LiQ), Li₂O, BaO, a lanthanide metal such as Yb, and a metal halide such as LiF, NaCl, CsF, or RbCl.

In one or more embodiments, the electron injection layer 51 may include an electron transport material and an insulating organic metal salt, which will be described below. The organic metal salt is not particularly limited, but may be, for example, a material having an energy band gap of about 4 eV or more. Examples of the organic metal salt may include a metal acetate salt, a metal benzoate salt, a metal acetoacetate salt, a metal acetylacetonate salt, or a metal stearate salt.

The electron transport layer 52 is not particularly limited, but may include, for example, a known electron transport material. Examples of the electron transport material may include at least one of an anthracene compound, tris(8-hydroxyquinolinolato)aluminum (Alq₃), 1,3,5-tri[(3-pyridyl)-phen-3-yl]benzene, 2,4,6-tris(3′-pyridin-3-yl)biphenyl-3-yl)-1,3,5-triazine, 2-(4-(N-phenylbenzimidazolyl-1-ylphenyl)-9,10-dinaphthylanthracene, 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinoline-10-olato) (Bebq₂), 9,10-di(naphthalen-2-yl)anthracene (ADN), lithium quinolate (LiQ), Compound ET1, or Compound H91, but embodiments are not limited thereto.

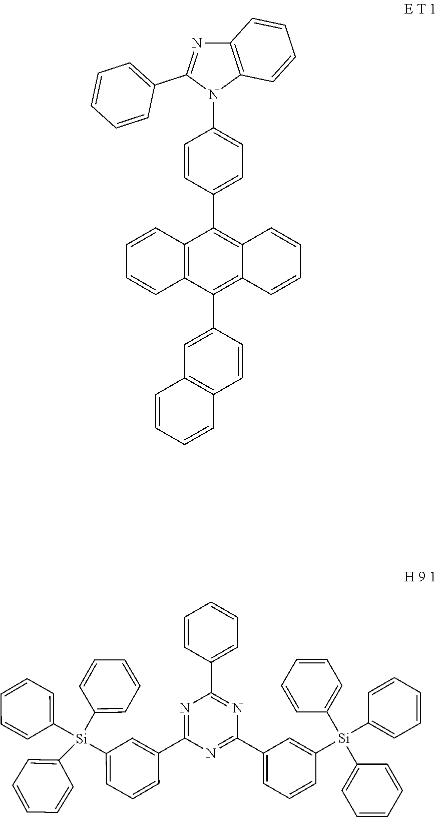 [SMILES: c1ccc(-c2nc3ccccc3n2-c2ccc(-c3c4ccccc4c(-c4ccc5ccccc5c4)c4ccccc34)cc2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

The hole-blocking layer 53 may prevent injection of holes from the hole transport region 3 to the electron transport region 5. Materials included in the hole-blocking layer 53 are not particularly limited, and a known hole-blocking material may be used. The hole blocking layer 53 may include, for example, at least one of 2,9-dimethyl-4,7-diphenyl-1,10-phenanthroline (BCP) or 4,7-diphenyl-1,10-phenanthroline (Bphen). In addition, examples of the hole-blocking material may include the host materials included in the emission layer and Compounds H-E1 and HT2 as host materials.

The thickness of the electron transport region 5 is not particularly limited, but may be about 0.1 nm to about 210 nm, about 30 nm to about 150 nm, or about 30 nm to about 80 nm. The thickness of the electron transport layer 52 is not particularly limited, but may be about 10 nm to about 100 nm, for example, about 15 nm to about 50 nm. The thickness of the hole-blocking layer 53 is not particularly limited, but may be about 5 nm to about 100 nm, for example, about 15 nm to about 50 nm. The thickness of the electron injection layer 51 is not particularly limited, but may be about 0.1 nm to about 10 nm, for example, about 0.3 nm to about 9 nm. When the thickness of the electron injection layer 51 is within the above ranges, improved electron injection characteristics may be obtained without a substantial increase in driving voltage. In addition, when the thickness of the electron transport region 5, the electron injection layer 51, the electron transport layer 52, or the hole-blocking layer 53 is within the above ranges, improved electron transport characteristics may be obtained without a substantial increase in driving voltage.

### Second Electrode 6

The second electrode 6 may be arranged on the electron transport region 5. The second electrode 6 may have good conductivity. The second electrode 6 may be a cathode, and include a material with a relatively low work function selected from a metal, an alloy, or a conductive compound, for facilitating electron injection. In the organic EL device according to one or more embodiments, the second electrode 6 may be a common electrode. In addition, the second electrode 6 may be a transmissive electrode, a transflective electrode, or a reflective electrode. The second electrode 6 may have a single-layer structure or a multi-layer structure including two or more layers.

A material for forming the second electrode 6 is not particularly limited, but may be, for example, a metal, a metal alloy, or a conductive compound. When the second electrode 6 is a transmissive electrode, the second electrode 6 may include a transparent metal oxide, for example, ITO, IZO, ZnO, or ITZO. When the second electrode 6 is a transflective electrode or a reflective electrode, the second electrode 6 may include Ag, Mg, Cu, Al, Pt, Pd, Au, Ni, Nd, Ir, Cr, Li, Ca, LiF/Ca, LiF/Al, Mo, Ti, or a compound or combination thereof (for example, a combination of Ag and Mg).

The second electrode 6 may be a single layer including a single material, or a single layer including a plurality of different materials. In an embodiment, the second electrode 6 may have a multi-layer structure including a plurality of layers including various different materials.

The thickness of the second electrode 6 is not particularly limited, but may be about 10 nm to about 1,000 nm.

The second electrode 6 may be further connected to an auxiliary electrode (not shown). When the second electrode 6 is connected to the auxiliary electrode, the resistance of the second electrode 6 may be further reduced.

A capping layer (not shown) may be further arranged on the second electrode 6. The capping layer (not shown) is not particularly limited, but may include, for example, α-NPD, NPB, TPD, m-MTDATA, Alq₃, CuPc, N4,N4,N4′,N4′-tetra(phenyl-4-yl)biphenyl-4,4′-diamine (TPD15), TCTA, or N,N′-bis(naphthalen-1-yl), but embodiments are not limited thereto.

In addition, each layer of the organic EL device 10 may be formed as a single layer or as a multi-layer.

A method of manufacturing each layer of the organic EL device 10 according to one or more embodiments is not particularly limited. For example, each layer may be manufactured by various methods such as vacuum deposition, solution coating, laser printing, Langmuir-Blodgett (LB) deposition, laser-induced thermal imaging (LITI), or the like, but embodiments are not limited thereto.

The solution coating may include spin coating, casting, micro-gravure coating, gravure coating, bar coating, roll coating, wire bar coating, dip coating, spray coating, screen printing, flexographic printing, offset printing, ink-jet printing, or the like, but embodiments are not limited thereto.

The vacuum deposition may be performed at a deposition temperature of about 100° C. to about 500° C., at a vacuum degree of about 10⁻⁸ torr to about 10⁻³ torr, and at a deposition rate of about 0.01 nanometers per second (nm/sec) to about 10 nm/sec, though the conditions may vary depending on a compound that is used and the structure and thermal characteristics of a desired layer.

In an embodiment, the first electrode 2 may be an anode, and the second electrode 6 may be a cathode. For example, the first electrode 2 may be an anode, the second electrode 6 may be a cathode, and an organic layer may include the emission layer 4 between the first electrode 2 and the second electrode 6 and may further include the hole transport region 3 between the first electrode 2 and the emission layer 4 and the electron transport region 5 between the emission layer 4 and the second electrode 6, wherein the hole transport region 3 may include at least one selected from the hole injection layer 31, the hole transport layer 32, a hole buffer layer, and the electron-blocking layer 33, and the electron transport region 5 may include at least of the hole-blocking layer 53, the electron transport layer 52, or the electron injection layer 51.

In one or more embodiments, the first electrode 2 may be a cathode, and the second electrode 6 may be an anode.

In the organic EL device 10 of FIGS. 1 to 3, when a voltage is applied to each of the first electrode 2 and the second electrode 6, holes provided from the first electrode 2 may move toward the emission layer 4 through the hole transport region 3, and electrons provided from the second electrode 6 may move toward the emission layer 4 through the electron transport region 5. The holes and the electrons may recombine in the emission layer 4 to produce excitons, and the excitons may transition from an excited state to a ground state to thereby generate light.

In the organic EL device 10 of FIGS. 1 to 3, the composition for an organic EL device may be included in the emission layer 4, or may be included in an organic layer other than the emission layer 4. In addition, the composition for an organic EL device may be included in the emission layer 4 and an organic layer other than the emission layer 4. In the organic EL device 10 of FIGS. 1 to 3, the boron compound represented by Formula 1 and the phosphorescent material described herein may be included in the emission layer 4, may be included in a layer other than the emission layer 4, or may be included in both the emission layer 4 and a layer other than the emission layer 4.

Hereinbefore, the organic EL device 10 has been described with reference to FIGS. 1 to 3, but embodiments are not limited thereto.

### Electronic Apparatus

The organic EL device may be included in various electronic apparatuses.

The electronic apparatus may further include a thin-film transistor, in addition to the organic EL device as described herein. The thin-film transistor may include a source electrode, a drain electrode, and an active layer, wherein any one of the source electrode or the drain electrode may be electrically connected to any one of the first electrode and the second electrode of the organic EL device.

Hereinafter, a compound and an organic EL device according to one or more embodiments are described in further detail with reference to Synthesis Examples and Examples. However, embodiments are not limited thereto. The expression “B′ was used instead of ‘A”’ used in the Synthesis Examples means that the amount of ‘B’ used was identical to the amount of ‘A’ used, on a molar equivalent basis.

### EXAMPLES

### Synthesis Example 1: Synthesis of Compound 1

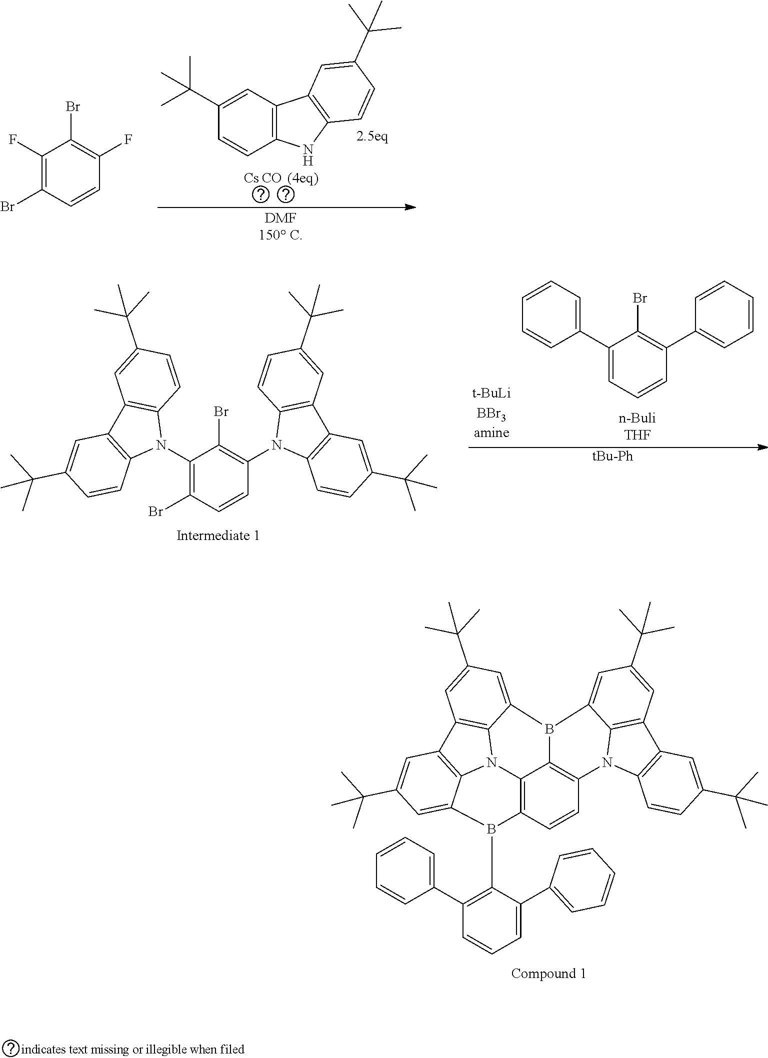

### Synthesis of Intermediate 1

1,3-dibromo-2,4-difluorobenzene (18.0 grams (g), 66.2 millimoles (mmol)), 3,6-di-tert-butylcarbazole (40.7 g, 145 mmol), and cesium carbonate (86.3 g, 264 mmol) were placed in a 500 milliliter (mL) recovery flask, and then dissolved in N,N-dimethylformamide (DMF) (130 mL). The obtained reaction solution was heated and stirred at 150° C. for 8 hours, and then cooled to room temperature. The obtained reaction solution was added to water (200 mL), and the precipitated solid was separated by filtration. The precipitated solid was recrystallized using toluene to thereby obtain 39.8 g of Intermediate 1.

### Synthesis of Compound 1

Intermediate 1 (2.40 g, 3.04 mmol) was placed in a 300 mL recovery flask, and then dissolved in t-butylbenzene (120 mL). After the obtained reaction solution was cooled to 0° C., t-butyllithium (1.6 M hexane solution, 7.96 mL, 12.7 mmol) was added dropwise thereto, and then, the mixed solution was stirred at room temperature for 1 hour. After the obtained reaction solution was cooled to −30° C., boron tribromide (0.70 mL, 7.28 mmol) was added thereto, and then, the mixed solution was stirred at room temperature for 1 hour. The obtained reaction solution was cooled to 0° C. After the obtained reaction solution was cooled, diisopropylethylamine (1.11 mL, 6.37 mmol) was added thereto, and then, the mixed solution was heated under reflux for 3 hours. The obtained reaction solution was cooled to room temperature, and then stirred overnight. Afterwards, the obtained reaction solution was cooled to −30° C. to thereby obtain Solution A. In addition, 2′-bromo-1,1′,3′,1″-diphenylbenzene (3.75 g, 12.1 mmol) was placed in a 100 ml recovery flask, and then dissolved in tetrahydrofuran (THF) (24 mL). The obtained reaction solution was cooled to −78° C. After the obtained reaction solution was cooled, n-butyllithium (2.6 M hexane solution, 4.78 mL, 12.4 mmol) was added dropwise thereto, and then, the mixed solution was stirred at room temperature for 1 hour to thereby obtain Solution B. The obtained reaction solution (Solution B) was slowly added to the above reaction solution (Solution A). The mixed solution was stirred for 1 hour, and then stirred at room temperature overnight. Water and dichloromethane were added to the obtained reaction solution to separate an aqueous layer therefrom, and then, the aqueous layer was subjected to an extraction process using dichloromethane. The obtained organic layer was dried using anhydrous magnesium sulfate, the solvent was removed therefrom under reduced pressure, and then, the resulting product was purified by silica gel column chromatography to thereby obtain Compound 1 (amount: 1.0 g, yield: 37%).

Structural identification of Compound 1 was performed using LC-MS. In detail, the sample (obtained Compound 1) was dissolved in tetrahydrofuran at a concentration of 0.1 wt %, and then, mass spectrometry was performed thereon using an LC-MS measuring device 1260 Infinity-Quadrupole 6100 MS (manufactured by Agilent Technologies Co., Ltd.). The obtained results are shown below:

LC-MS (APCI): 879 ([M+H]⁺).

### Synthesis Example 2: Synthesis of Compound 2

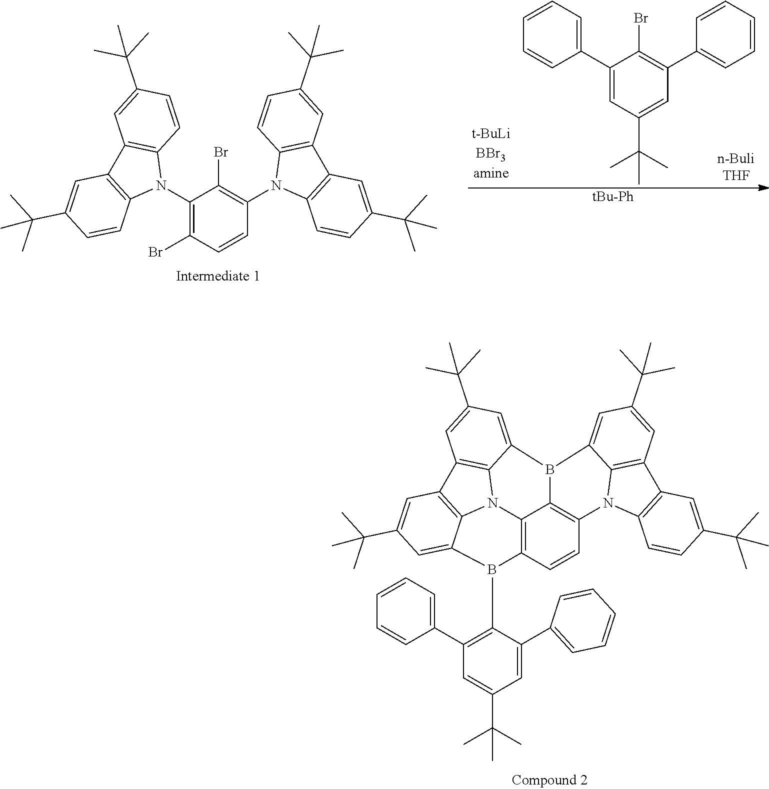

Compound 2 was synthesized in the same manner as in the synthesis of Compound 1, except that 2′-bromo-5′-(tert-butyl)-1,1′,3′,1″-diphenylbenzene was used instead of 2′-bromo-1,1′,3′,1″-diphenylbenzene (amount: 0.55 g, yield: 19%).

Structural identification of Compound 2 was performed in the same manner as that of Compound 1. The obtained results are shown below:

LC-MS: 935 ([M+H]⁺).

### Measurement of Peak Wavelength of Fluorescence Emission (Solution)

For a toluene solution of a compound to be evaluated at a concentration of 1×10⁻⁷ M, measurements were performed at room temperature with an excitation wavelength of 320 nm by using a spectrofluorophotometer F-7000 manufactured by Hitachi High-Tech Co., Ltd., thereby evaluating the peak wavelength (λ_{PL}) (unit: nm) of fluorescence emission in PL and the spectral width of fluorescence emission (FWHM of the emission peak) (unit: nm). The unit of concentration, M, represents mol/dm³ (=mol/L). In the evaluation, Compound 1, Compound 2, and Comparative Compound C1 were each used as the compound to be evaluated. The evaluation results are shown in Table 1.

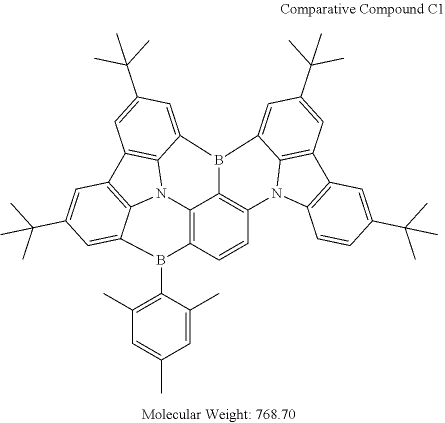 [SMILES: Cc1cc(C)c(B2c3ccc4c5c3-n3c6c2cc(C(C)(C)C)cc6c2cc(C(C)(C)C)cc(c23)B5c2cc(C(C)(C)C)cc3c5cc(C(C)(C)C)ccc5n-4c23)c(C)c1]

TABLE 1

| Compound | λ^{PL} (nm) | FWHM (nm) |
|---|---|---|
| Compound 1 | 456 | 17 |
| Compound 2 | 457 | 18 |
| Comparative Compound C1 | 453 | 16 |

The emission wavelengths of the solution of Compound 1 and the solution of Compound 2 were 456 nm and 457 nm, respectively, and the solutions exhibited blue luminescence. In addition, the FWHMs of the emission spectra of the solution of Compound 1 and the solution of Compound 2 were 17 nm and 18 nm, respectively. The emission wavelength of the solution of Comparative Compound C1 was 453 nm, the solution exhibited blue luminescence, and the FWHM of the emission spectrum of the solution of Comparative Compound C1 was 16 nm. From the above results, it was confirmed that in a toluene solution, all of Compound 1, Compound 2, and Comparative Compound C1 exhibited high-purity blue luminescence with a narrow FWHM of the emission peak.

### Evaluation of Compound

### Method of Preparing Thin Film

A 50 nm-thickness thin film was prepared by co-depositing, at a vacuum degree of 10⁻⁵ Pa, a compound to be evaluated and 1,3-bis(N-carbazolyl)benzene (mCP) as a host compound on a quartz substrate at a weight ratio of 1 part by weight of the compound to be evaluated to the total weight of 100 parts by weight of mCP and the compound to be evaluated.

### Measurement of PL

The thin film (host dispersion film) prepared above was cut into a strip shape having a width of 6 mm, and PL measurement was performed thereon at room temperature by using a spectrofluorometer F-7000 manufactured by Hitachi High-Tech Co., Ltd. The measurement was performed in a laminated state of the quartz substrate and the thin film. From the obtained emission spectrum, the peak wavelength (λ^{PL}) and the wavelength width at which the emission intensity was reduced to half (FWHM of the emission peak) were evaluated. The evaluation results are shown in Table 2.

### Measurement of PLQY

For the thin film (host dispersion film) prepared above, the PLQY was measured using a Quantaurus-QY absolute PLQY measuring device C11347-01 manufactured by Hamamatsu Photonics Co., Ltd. The measurement was performed in a laminated state of the quartz substrate and the thin film. In the measurement, the excitation wavelength was scanned at intervals of 10 nm from 280 nm to 350 nm, and the excitation wavelength region in which the absorption value of the compound showed an excitation light intensity ratio of 20% or more was adopted. The value of PLQY was taken as the highest value in the adopted excitation wavelength region. The evaluation results are shown in Table 2.

TABLE 2

| Compound | λ^{PL} (nm) | FWHM (nm) | PLQY (%) |
|---|---|---|---|
| Compound 1 | 458 | 20 | 95 |
| Compound 2 | 459 | 21 | 92 |
| Comparative Compound C1 | 453 | 24 | 90 |

The emission wavelengths of the thin film including Compound 1 and the thin film including Compound 2 were 458 nm and 459 nm, respectively, and the thin films exhibited blue luminescence, similar to that of the solutions including Compounds 1 and 2, respectively. In addition, the FWHMs of the emission spectra of the thin film including Compound 1 and the thin film including Compound 2 were 20 nm and 21 nm, respectively, and the thin films exhibited luminescence with a narrow spectral width, similar to that of the solutions including Compounds 1 and 2, respectively. The PLQYs of the thin film including Compound 1 and the thin film including Compound 2 showed high values of 95% and 92%, respectively. Meanwhile, for the thin film including Comparative Compound C1, the emission wavelength was 453 nm, the FWHM of the emission spectrum was 24 nm, and the PLQY was 90%. From the above evaluation results, it was confirmed that the thin film including Compound 1 and the thin film including Compound 2 exhibited excellent blue luminescence, and that the thin film including Compound 1 and the thin film including Compound 2 had a superior FWHM of the emission spectrum and a superior PLQY, compared to those of the thin film including Comparative Compound C1.

### Manufacture of Organic EL Device

### Organic EL Device 1

An ITO glass substrate on which an electrode pattern was formed was cut to a size of 50 mm×50 mm×0.7 mm, ultrasonically cleaned using acetone, isopropyl alcohol, and deionized (DI) water, in the stated order for 15 minutes each, and then cleaned by exposure to ultraviolet (UV) ozone for 30 minutes. The following layers were deposited on the ITO electrode (anode) on the glass substrate by using a vacuum deposition apparatus.

First, HAT-CN was deposited on the ITO electrode to form a hole injection layer having a thickness of 10 nm. Next, Compound HT3 was deposited on the hole injection layer to form a hole transport layer having a thickness of 140 nm. Then, Compound HT1 was deposited on the hole transport layer to form an electron-blocking layer having a thickness of 5 nm. As a result, a hole transport region was formed.

Compound HT1, Compound HT2, Phosphorescent Complex Pt1, and Compound 1 obtained above were co-deposited on the hole transport region to form an emission layer having a thickness of 40 nm. In this regard, the formation of the emission layer was performed such that the weight ratio of Compound HT1, Compound HT2, and Phosphorescent Complex Pt1 in the emission layer was Compound HT1:Compound HT2:Phosphorescent Complex Pt1=60:40:13. In addition, the formation of the emission layer was performed such that the concentration of Compound 1 was 1.5 wt % based on the total weight of Compound HT1, Compound HT2, Phosphorescent Complex Pt1, and Compound 1 (that is, the total weight of the emission layer). In addition, Compound HT1 and Compound HT2 were host materials.

Compound HT2 was vacuum-deposited on the emission layer to form a hole-blocking layer having a thickness of 5 nm. Next, Compound H91 and lithium quinolate (LiQ) were co-deposited on the hole-blocking layer at a weight ratio of Compound H91:LiQ=5:5 (unit: parts by weight) to form an electron transport layer having a thickness of 30 nm. Then, LiQ was deposited on the electron transport layer to form an electron injection layer having a thickness of 1 nm. As a result, an electron transport region was formed.

Al (cathode) was deposited on the electron injection layer to a thickness of 100 nm to thereby manufacture Organic EL Device 1.

Thereafter, in a glove box of a nitrogen atmosphere with a water concentration of 1 ppm or less and an oxygen concentration of 1 ppm or less, a glass sealing tube with a desiccating agent attached thereto and an UV-curable resin (manufactured by MORESCO Co., Ltd., product name: WB90US) were used to seal Organic EL Device 1 manufactured above. As a result, Organic EL Device 1 was completed.

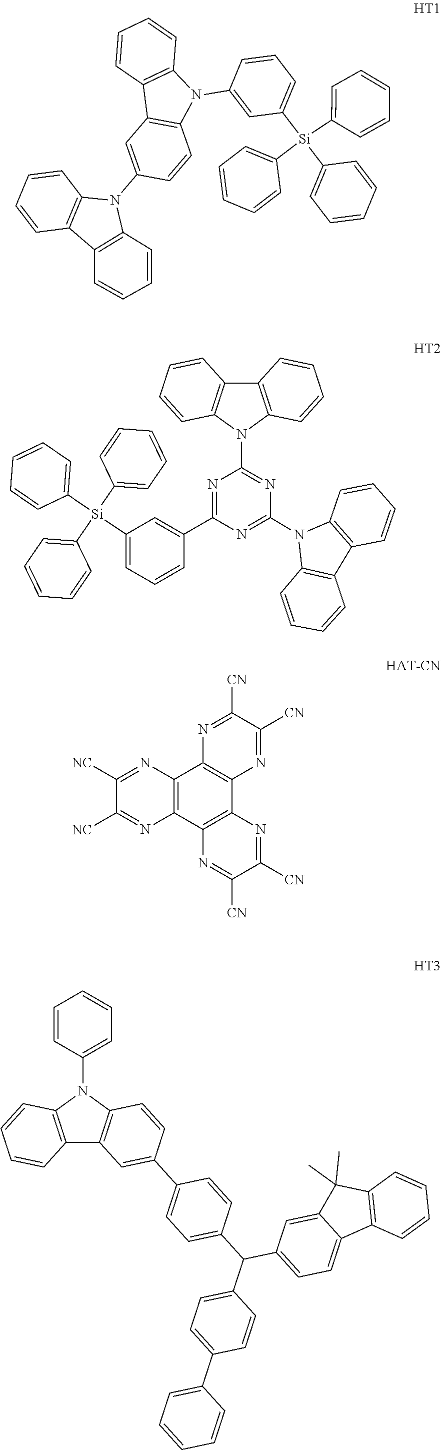 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; N#Cc1nc2c3nc(C#N)c(C#N)nc3c3nc(C#N)c(C#N)nc3c2nc1C#N ; CC1(C)c2ccccc2-c2ccc(C(c3ccc(-c4ccccc4)cc3)c3ccc(-c4ccc5c(c4)c4ccccc4n5-c4ccccc4)cc3)cc21]

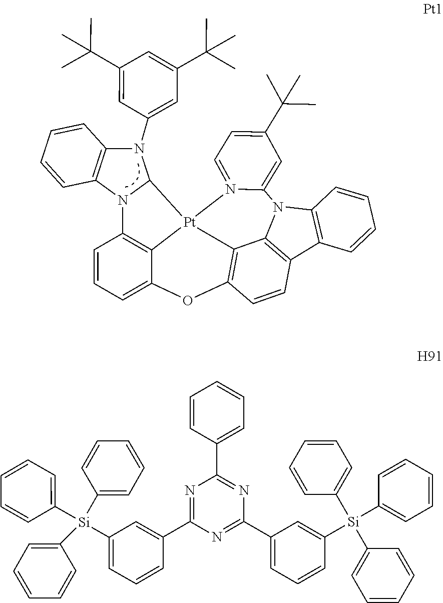

### Organic EL Device 2

Organic EL Device 2 was completed by manufacturing and sealing an organic EL device in the same manner as in the manufacture of Organic EL Device 1, except that, in the formation of an emission layer, Compound 1 was changed to Compound 2 obtained above.

### Manufacture of Comparative Organic EL Device 1

Comparative Organic EL Device 1 was completed by manufacturing and sealing an organic EL device in the same manner as in the manufacture of Organic EL Device 1, except that, in the formation of an emission layer, Compound 1 was changed to Comparative Compound C1.

### Evaluation of Organic EL Device

### Luminance, External Quantum Efficiency, and Device Lifespan

The peak wavelength of emission, spectral width of emission, external quantum efficiency, and device lifespan at a luminance of 1,000 cd/m² were evaluated according to the following method, and the results are shown in Table 3.

An organic EL device was allowed to emit light while the voltage applied thereto was changed using a DC constant voltage power supply (source meter 2400 manufactured by KEITHLEY), and the luminance, emission spectrum, and luminescence amount at this time were measured using a luminance measuring device (SR-3 manufactured by Topcon).

In this regard, the external quantum efficiency was calculated from the emission spectrum, luminance, and current value at the time of measurement. The external quantum efficiency at the luminance of 1,000 cd/m² was defined as EQE [%]. The external quantum efficiency in Table 3 is expressed as a relative value with respect to the EQE [%] of Comparative Device Example 1 defined as 1.

In addition, the device lifespan (durability) was defined as LT70, which is the time required for the emission luminance, decreasing with time, to reach 70% of the initial luminance when the device was continuously driven at a current value having an initial luminance of 1,000 cd/m². In addition, the LT70 in Table 3 is expressed as a relative value with respect to the LT70 (unit: hours (hr)) of Comparative Organic EL Device 1 defined as 1.

### Peak Wavelength of Emission and Spectral Width of Emission (FWHM)

The peak wavelength of emission and the spectral width of emission were read from the results of measuring the emission spectrum. The wavelength representing the maximum value of the emission spectrum was defined as the peak wavelength of emission, and the FWHM, which is the wavelength width corresponding to half of the maximum value, was defined as the spectral width of emission.

In the evaluation, the peak wavelength of emission is not particularly limited, but may be 455 nm to 475 nm within the blue emission region.

In the evaluation, a smaller spectral width of emission (FWHM of the emission peak) was considered more desirable and indicative of improved color purity.

Referring to the results in Table 3, it was confirmed that Organic EL Device 1 using Compound 1, which is a boron compound represented by Formula 1, exhibited higher external quantum efficiency than Comparative Organic EL Device 1 using Comparative Compound C1, and thus, Organic EL Device 1 using Compound 1 had improved luminescence efficiency and improved device lifespan.

TABLE 3

| | | External | | Peak | |
|---|---|---|---|---|---|
| | | quantum | Device | wavelength | |
| | | efficiency | lifespan | of emission | FWHM |
| | Compound | (*) | (*) | (nm) | (nm) |
| Device | Compound 1 | 1.17 | 2.59 | 458 | 20 |
| Example 1 | | | | | |
| Device | Compound 2 | 1.16 | 1.43 | 460 | 20 |
| Example 2 | | | | | |
| Comparative | Comparative | 1 | 1 | 455 | 22 |
| Device | Compound | | | | |
| Example 1 | C1 | | | | |

(* External quantum yield and device lifespan are relative values with respect to values of Comparative Device Example 1 defined as 1, respectively)

It was confirmed that Organic EL Device 1 (Device Example 1), which used materials including Compound 1 and a phosphorescent material as materials for an emission layer, and Organic EL Device 2 (Device Example 2), which used materials including Compound 2 and a phosphorescent material as materials for an emission layer, had higher external quantum efficiency and longer device lifespan than Comparative Organic EL Device 1 (Comparative Device Example 1), which was manufactured using materials including Comparative Compound C1 and a phosphorescent material as materials for an emission layer. In addition, it was confirmed that, in Device Example 1, a narrow FWHM of the emission peak and high color purity were realized by using Compound 1. In addition, it was confirmed that, in Device Example 2, a narrow FWHM of the emission peak and high color purity were realized by using Compound 2. Accordingly, it was confirmed that excellent characteristics of an organic EL device were realized by using a composition for an organic EL device within the scope of the disclosure.

As described above, a composition for an organic electroluminescent device according to an embodiment may have improved efficiency, lifespan, and/or color purity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A composition for an organic electroluminescent device, the composition comprising a boron compound represented by Formula 1 and a phosphorescent material: 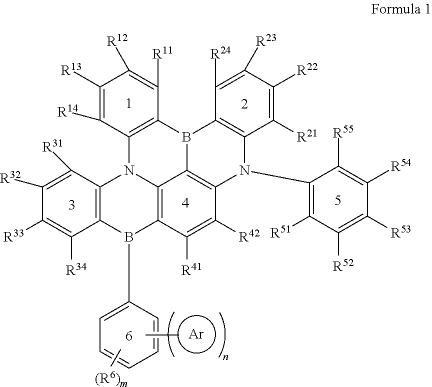
wherein, in Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino a group, substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally comprises a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.

2. The composition of claim 1, wherein Ar is a benzene ring, a pyridine ring, a pyrazine ring, a pyridazine ring, a pyrimidine ring, a triazine ring, a furan ring, a thiophene ring, a thiazine ring, a pyrrole ring, an imidazole ring, a pyrazole ring, an imidazoline ring, a triazole ring, a tetrazole ring, an oxazole ring, an isoxazole ring, a thiazole ring, or an isothiazole ring.

3. The composition of claim 1, wherein m is an integer from 1 to 4, n is an integer from 1 to 4, and the sum of m and n is 5.

4. The composition of claim 1, wherein a combination of ring 1 and ring 3 and a combination of ring 2 and ring 5 are each independently bonded together via the linker, and
ring 5 and ring 6 are not bonded together via the linker, and ring 5 and Ar are not bonded together via the linker.

5. The composition of claim 1, wherein m is 3, n is 2, and each R⁶ is independently a hydrogen atom or an alkyl group.

6. The composition of claim 1, wherein the boron compound represented by Formula 1 is a boron compound represented by Formula 2: 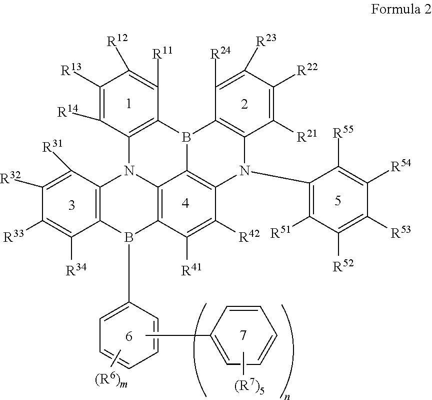
wherein, in Formula 2,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, R⁶, m, and n are each as defined in Formula 1,
each R⁷ is independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
the linker is a single bond or a linking group, and
ring 3 and ring 6 are not bonded together via the linker, ring 3 and ring 7 are not bonded together via the linker, ring 4 and ring 6 are not bonded together via the linker, and ring 4 and ring 7 are not bonded together via the linker.

7. The composition of claim 6, wherein m is 3, n is 2, and each R⁶ is independently a hydrogen atom or an alkyl group.

8. The composition of claim 1, wherein the boron compound represented by Formula 1 is a boron compound represented by Formula 3: 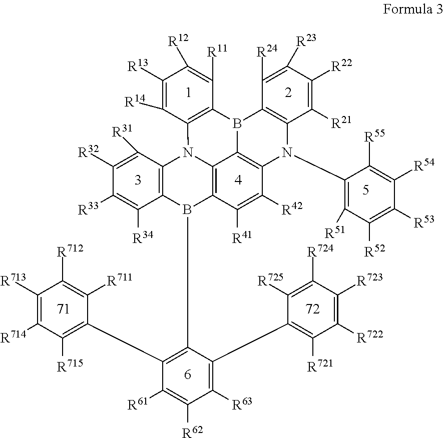
wherein, in Formula 3,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, and R⁵⁵ are each as defined in Formula 1,
R⁶¹, R⁶², R⁶³, R⁷¹¹, R⁷¹², R⁷¹³, R⁷¹⁴, R⁷¹⁵, R⁷²¹, R⁷²², R⁷²³, R⁷²⁴, and R⁷²⁵ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
the linker is a single bond or a linking group, and
ring 3 and ring 6 are not bonded together via the linker, ring 3 and ring 71 are not bonded together via the linker, ring 3 and ring 72 are not bonded together via the linker, ring 4 and ring 6 are not bonded together via the linker, ring 4 and ring 71 are not bonded together via the linker, and ring 4 and ring 72 are not bonded together via the linker.

9. The composition of claim 1, wherein the boron compound represented by Formula 1 is a compound from Group I:

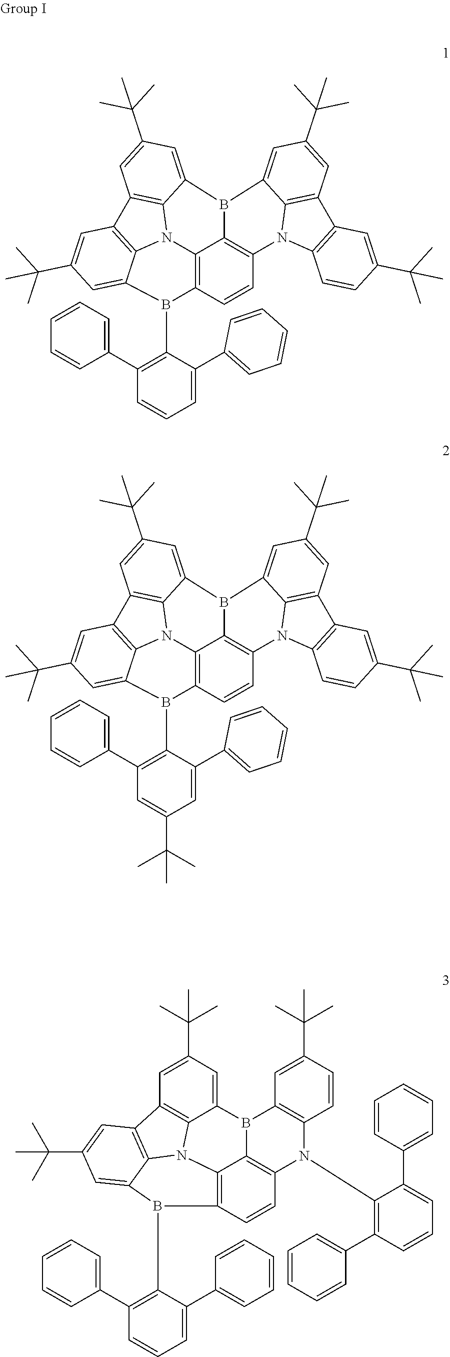

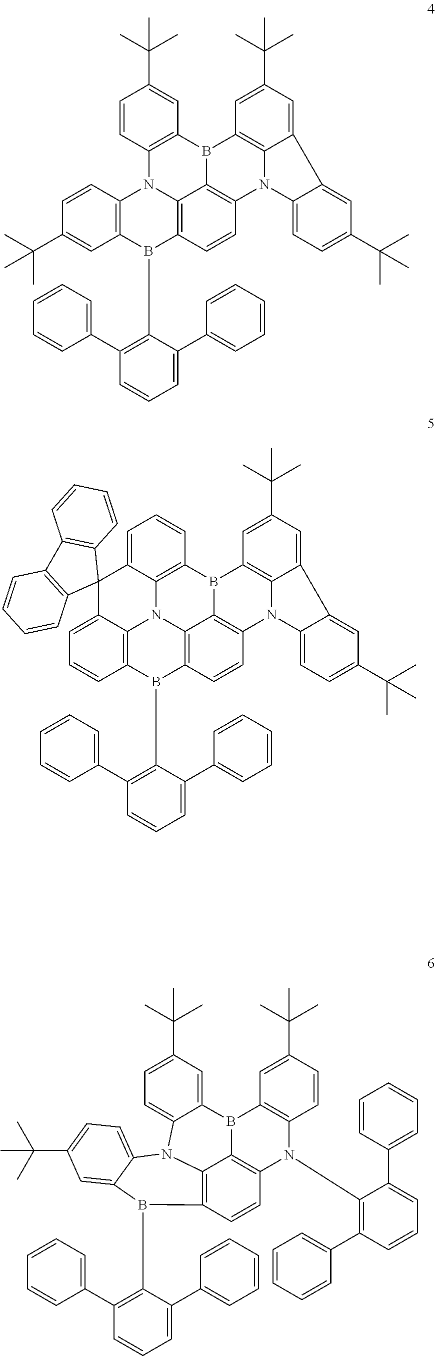

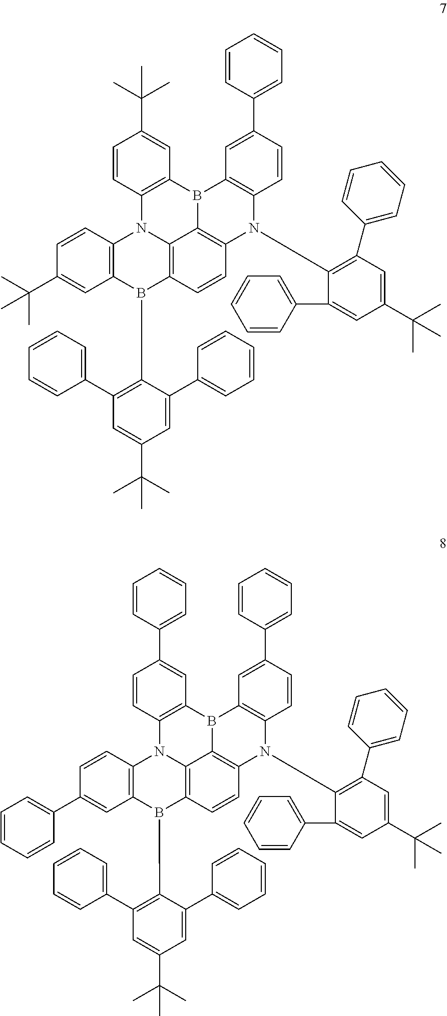 [SMILES: CC(C)(C)c1ccc2c(c1)B(CCc1c(-c3ccccc3)cc(C(C)(C)C)cc1-c1ccccc1)c1ccc3c4c1N2c1ccc(C(C)(C)C)cc1B4c1cc(-c2ccccc2)ccc1N3c1c(-c2ccccc2)cc(C(C)(C)C)cc1-c1ccccc1 ; CC(C)(C)c1cc(-c2ccccc2)c(CCB2c3cc(-c4ccccc4)ccc3N3c4ccc(-c5ccccc5)cc4B4c5cc(-c6ccccc6)ccc5N(c5c(-c6ccccc6)cc(C(C)(C)C)cc5-c5ccccc5)c5ccc2c3c54)c(-c2ccccc2)c1]

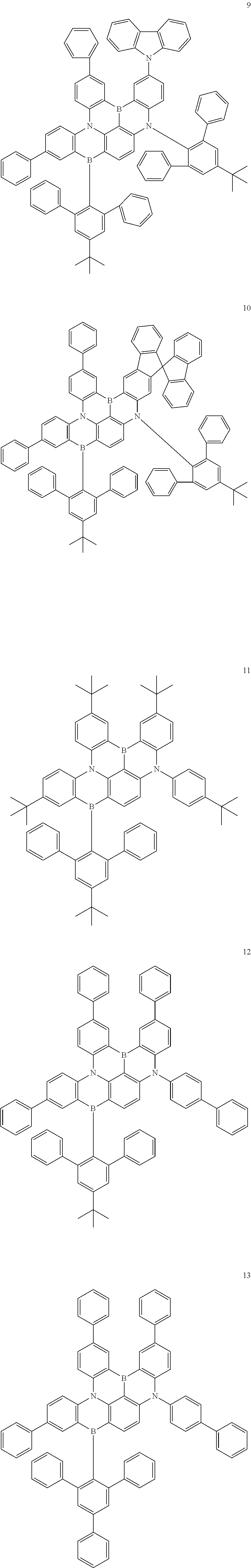

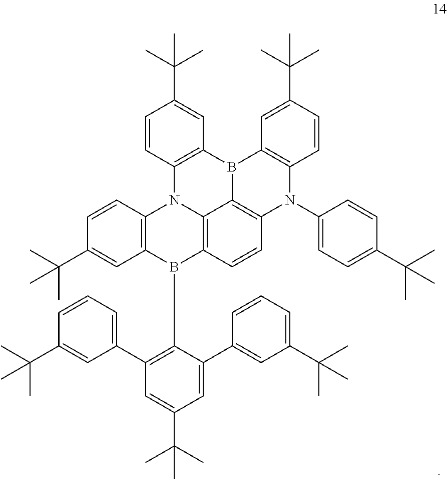 [SMILES: CC(C)(C)c1ccc(N2c3ccc(C(C)(C)C)cc3B3c4cc(C(C)(C)C)ccc4N4c5ccc(C(C)(C)C)cc5B(CCc5c(-c6cccc(C(C)(C)C)c6)cc(C(C)(C)C)cc5-c5cccc(C(C)(C)C)c5)c5ccc2c3c54)cc1]

10. The composition of claim 1, wherein the phosphorescent material comprises an iridium complex or a platinum complex.

11. The composition of claim 1, wherein an amount of the phosphorescent material is about 100 parts by weight to about 10,000 parts by weight, based on 100 parts by weight of the boron compound represented by Formula 1.

12. A boron compound represented by Formula 1: 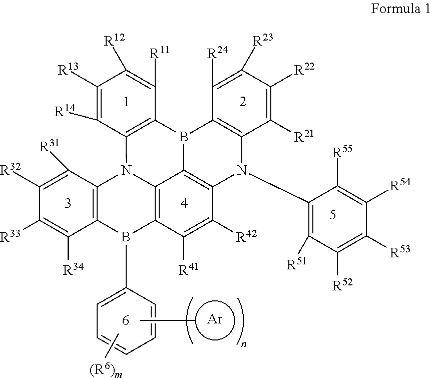
wherein, in Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally comprises a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.

13. An organic electroluminescent device comprising:
a first electrode;
a second electrode;
an organic layer arranged between the first electrode and the second electrode,
wherein the organic layer comprises an emission layer; and
wherein the organic layer further comprises a composition, the composition comprising a boron compound represented by Formula 1 and a phosphorescent material, 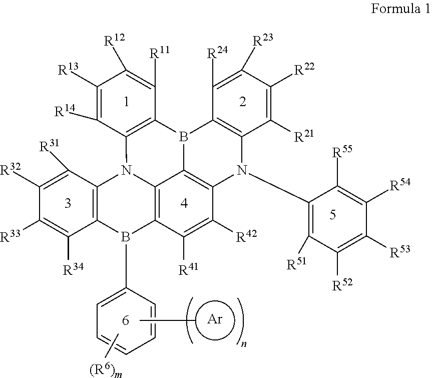
wherein, in Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally comprises a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.

14. The organic electroluminescent device of claim 13, wherein
the organic electroluminescent device emits light having a peak in a wavelength range of about 360 nanometers to about 515 nanometers, and
a full width at half maximum of an emission spectrum of the organic electroluminescent device is about 30 nanometers or less.

15. The organic electroluminescent device of claim 13, wherein the emission layer comprises the composition.

16. The organic electroluminescent device of claim 15, wherein
the emission layer further comprises a host,
the host and the boron compound represented by Formula 1 are different from each other,
the host and the phosphorescent material are different from each other, and
the emission layer consists of the host, the boron compound represented by Formula 1, and the phosphorescent material.

17. The organic electroluminescent device of claim 16, wherein the host does not emit light, and the boron compound represented by Formula 1 emits light.

18. The organic electroluminescent device of claim 15, wherein an amount of the boron compound represented by Formula 1 in the emission layer is about 0.1 wt % to about 10.0 wt %, based on a total weight of the emission layer.

19. The organic electroluminescent device of claim 15, wherein an amount of the phosphorescent material in the emission layer is about 1.0 wt % to about 50.0 wt %, based on a total weight of the emission layer.

20. An electronic apparatus comprising an organic electroluminescent device, the organic electroluminescent device comprising:
a first electrode;
a second electrode;
an organic layer arranged between the first electrode and the second electrode,
wherein the organic layer comprises an emission layer; and
wherein the organic layer further comprises a composition, the composition comprising a boron compound represented by Formula 1 and a phosphorescent material, 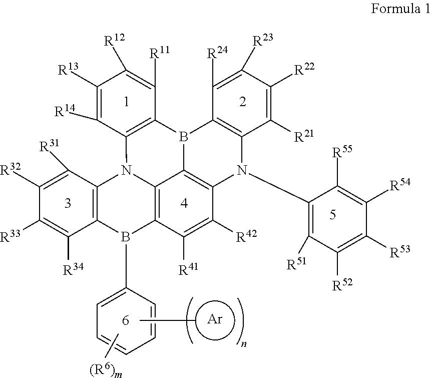
wherein, in Formula 1,
R¹¹, R¹², R¹³, R¹⁴, R²¹, R²², R²³, R²⁴, R³¹, R³², R³³, R³⁴, R⁴¹, R⁴², R⁵¹, R⁵², R⁵³, R⁵⁴, R⁵⁵, and R⁶ are each independently a hydrogen atom, a cyano group, a halogen atom, a deuterium atom, a substituted or unsubstituted aryl group, a substituted or unsubstituted heteroaryl group, a substituted or unsubstituted diarylamino group, a substituted or unsubstituted diheteroarylamino group, a substituted or unsubstituted arylheteroarylamino group, a substituted or unsubstituted alkyl group, a substituted or unsubstituted aryloxy group, a substituted or unsubstituted heteroaryloxy group, a substituted or unsubstituted arylthio group, a substituted or unsubstituted heteroarylthio group, or a linker,
each Ar is independently a substituted or unsubstituted benzene ring, or a substituted or unsubstituted heteroaromatic ring having 5 or 6 ring-forming atoms, wherein Ar optionally comprises a linker,
m is an integer from 0 to 4, n is an integer from 1 to 5, and a sum of m and n is 5,
the linker is a single bond or a linking group, and
ring 3 and ring 6 are not bonded together via the linker, ring 3 and Ar are not bonded together via the linker, ring 4 and ring 6 are not bonded together via the linker, and ring 4 and Ar are not bonded together via the linker.
